(19) United States
(12) Patent Application Publication
(10) Pub. No.: US 2016/0306278 A1
(43) Pub. Date: Oct. 20, 2016

(54) CHEMICAL FOR PHOTOLITHOGRAPHY WITH IMPROVED LIQUID TRANSFER PROPERTY AND RESIST COMPOSITION COMPRISING THE SAME

(71) Applicant: TOKYO OHKA KOGYO CO., LTD., Kawasaki-shi (JP)

(72) Inventors: Koji YONEMURA, Incheon (KR); Yasuo SOMEYA, Incheon (KR); Deuk Young YOON, Incheon (KR)

(21) Appl. No.: 15/087,637

(22) Filed: Mar. 31, 2016

(30) Foreign Application Priority Data
Apr. 20, 2015 (KR) 10-2015-0055166

(51) Int. Cl. G03F 7/039; G03F 7/16

(52) U.S. Cl. CPC G03F 7/039; G03F 7/162

(57) ABSTRACT

A chemical for photolithography to uniformly form a thick film to a desired thickness while enhancing a liquid transfer property by lowering the viscosity of a composition for photolithography, and a resist composition including the same. The chemical includes a solvent having a saturated vapor pressure and viscosity within predetermined ranges, and a resin is formed as a film having a thickness of 5 μm or more through spin coating.

### CROSS-REFERENCE TO RELATED APPLICATION

This application claims priority to Korean Patent Application No. 2015-0055166, filed on Apr. 20, 2015, the disclosure of which is incorporated herein by reference in its entirety.

### BACKGROUND

1. Field of the Invention

The present invention relates to a chemical for photolithography with an improved liquid transfer property and a resist composition including the same.

2. Discussion of Related Art

Photolithography technology is characterized by, for example, forming a resist film composed of a resist material on a substrate, performing selective exposure of the resist film to light or radiation such as electron beams through a mask with a predetermined pattern, and developing the exposed resist film, to form a predetermined resist pattern on the resist film.

A positive-type resist material has a characteristic wherein, upon exposure, properties of an exposed part thereof are changed so as to be soluble in a developer. A negative-type resist material is a material having a characteristic wherein, upon exposure, properties of an exposed part are changed so as not to be soluble in a developer.

Recently, in manufacturing semiconductor devices or liquid crystal displays, refinement of patterns is actively underway due to development of lithography technology.

Refinement is generally performed at a shorter wavelength (higher energy) of an exposure light source. In particular, ultraviolet rays represented by g rays and i rays have been conventionally used, but, presently, lasers such as KrF excimer lasers or ArF excimer lasers have been used in mass production of semiconductor devices. In addition, use of electron beams, EUV (extreme ultraviolet rays), X-rays, etc. having shorter wavelength (higher energy) than these excimer lasers is under consideration.

In addition, a chemically amplified resist composition, as a resist material satisfying a high-resolution condition to reproduce fine patterns, which is prepared by dissolving a base resin and an acid generator for generating an acid upon exposure in an organic solvent, and alkaline solubility of which is changed by an acid occurring from the acid generator, is known.

Examples of base resin ingredients of such a chemically amplified resist include polyhydroxystyrene (PHS), which has high transparency at KrF excimer laser wavelength (248 nm), etc., PHS based resins, portions of hydroxyl groups of which are protected by an acid-dissociative dissolution inhibiting group, copolymers derived from a (meth)acrylic ester, etc. In addition, as the acid generator, an onium salt-based acid generator such as an iodonium salt or sulfonium salt is most generally used.

As the organic solvent, propylene glycol monomethyl ether acetate (hereinafter, referred to as PGMEA), ethyl lactate (hereinafter, referred to as EL), methyl amyl ketone (hereinafter, referred to as MAK), propylene glycol monomethyl ether (hereinafter, referred to as PGME), etc. are used alone or in a combination. However, when these solvents are individually used, a base resin may be easily aggregated in a resist composition. Accordingly, use of a solvent mixture of PGME and a solvent having a higher boiling point than PGME is under consideration (Patent Document 1). However, the aforementioned patent document does not examine problems related to a liquid transfer property due to increased viscosity, and difficulties such as decreased productivity caused by the problems, with regard to a resist composition for a thick film.

### RELATED DOCUMENT

### Patent Document

(Patent Document 1) Japanese Patent Laid-Open Publication No. 2005-283991

### SUMMARY OF THE INVENTION

Recently, there is a need for technology of forming films to various thicknesses, e.g., a thin or thick film depending upon uses of photosensitive resin compositions. In the case of a thick film, the viscosity of a composition is increased using a method of increasing a solid content in a photosensitive resin composition, etc. However, when a thick film is formed by increasing the viscosity of the photosensitive resin composition, a load applied upon transfer of the composition in a photoresist process becomes excessive. In addition, in the case of a film formed through spin coating on a substrate, when the viscosity of a chemical for photolithography or a photoresist composition is high, it is difficult to uniformly diffuse the chemical or the composition on the substrate, and thus, it may be difficult to form the film to a uniform thickness. Accordingly, existing equipment cannot be used and thus specific equipment is required. Alternatively, disadvantages such as a pressure load upon liquid transfer or a longer liquid transfer time may occur. In addition, enhancements to form the film to a uniform thickness are required.

Meanwhile, when the viscosity of the chemical or the composition is lowered by adjusting a solid concentration so as to enhance a liquid transfer property and form a film to a uniform thickness, it may be difficult to form the film to a desired thickness.

Therefore, the present invention has been made in consideration of the above problems, and it is an object of the present invention to provide a chemical for photolithography to uniformly form a thick film to a desired thickness while enhancing a liquid transfer property by lowering the viscosity of a composition for photolithography, and a resist composition including the same.

The present inventors set out to address the above objects and confirmed that, by using a chemical for photolithography including a resin ingredient having a low molecular weight and an organic solvent having a predetermined saturated vapor pressure and viscosity, final viscosities of the chemical for photolithography and the resist composition including the same are decreased, enhancing a liquid transfer property, and since a portion of a coated chemical or composition is vaporized by spinning a substrate when the chemical or the resist composition is spin coated on the substrate, upon use of a solvent having a predetermined saturated vapor pressure or higher, the viscosity of a chemical coated increases during spinning, and accordingly, a required thick film having a sufficient thickness can be obtained, thus completing the present invention.

More particularly, the present invention includes the following constitution.

That is, according to an aspect of the present invention, there is provided a chemical for photolithography including a resin ingredient A having a mass-average molecular weight (Mw) of 2000 to 50000 and an organic solvent S having a saturated vapor pressure of 1 kPa or more (1 atm, 20° C.) and a viscosity of 1.1 cP (1 atm, 20° C.) or less.

According to another aspect of the present invention, there is provided a resist composition including a resin ingredient A having a mass-average molecular weight (Mw) of 2000 to 50000, an organic solvent S having a saturated vapor pressure of 1 kPa or more (1 atm, 20° C.) and a viscosity of 1.1 cP (1 atm, 20° C.) or less, and an acid generator.

### DETAILED DESCRIPTION OF PREFERRED EMBODIMENTS

The term “aliphatic” used in description and claims of the present invention is a concept relative to “aromatic” and means groups, compounds, etc. not having aromatic properties.

The term “alkyl group” includes straight chain, branched and cyclic monovalent saturated hydrocarbon groups, unless specified otherwise. An alkyl group of an alkoxy group also has the same meaning.

The term “alkylene group” includes straight chain, branched and cyclic bivalent saturated hydrocarbon groups, unless specified otherwise.

The term “halogenated alkyl group” refers to an alkyl group, a portion or all of hydrogen atoms of which are substituted with a halogen atom. Examples of the halogen atom include a fluorine atom, a chlorine atom, a bromine atom, and an iodine atom.

The term “fluorinated alkyl group” or “fluorinated alkylene group” refers to an alkyl group or alkylene group, a portion or all of hydrogen atoms of which is substituted with a fluorine atom.

The term “constituent unit” means a monomer unit constituting a polymer compound (resin, polymer, copolymer).

The term “constituent unit derived from acrylic ester” means a constituent unit formed by cleavage of an ethylenic double bond of acrylic ester.

The term “acrylic ester” is a compound wherein a hydrogen atom at a terminal of a carboxyl group of acrylic acid (CH₂═CH—COOH) is substituted with an organic group.

An acrylic ester may be a compound wherein a hydrogen atom bonded to a carbon atom at an α position is substituted with a substituent. Substituent R^{α0} substituted for the hydrogen atom bonded to the carbon atom at the α position is an atom, except for a hydrogen atom, or a group. For example, the substituent R^{α0} may be a C₁ to C₅ alkyl group, a C₁ to C₅ halogenated alkyl group, etc. In addition, acrylic ester includes itaconic acid diester wherein a substituent R^{α0} is substituted with a substituent having an ester bond, or a hydroxyacrylester wherein a substituent R^{α0} is substituted with a hydroxyalkyl group or a group modifying the hydroxyl group. In addition, the carbon atom at the α position of acrylic ester is bonded to a carbonyl group of acrylic acid, unless specified otherwise.

The acrylic ester, the hydrogen atom bonded to the carbon atom at an α position of which is substituted with a substituent, is also called α-substituted acrylic ester. In addition, the term “(α-substituted) acrylic ester” means both acrylic ester and α-substituted acrylic ester in some cases.

The term “constituent unit derived from hydroxystyrene or hydroxystyrene derivative” refers to a constituent unit formed by cleavage of an ethylenic double bond of hydroxystyrene or a hydroxystyrene derivative.

The term “hydroxystyrene derivative” includes hydroxystyrene, a hydrogen atom at an α position of which is substituted with a different substituent such as an alkyl group or a halogenated alkyl group, and derivatives thereof. Examples of these derivatives include hydroxystyrene wherein a hydrogen atom at a hydroxyl group of the hydroxystyrene, a hydrogen atom at an α position of which may be substituted with a substituent, is substituted with an organic group; hydroxystyrene wherein a benzene ring of the hydroxystyrene, a hydrogen atom at an α position of which may be substituted with a substituent, is substituted with a substituent excluding a hydroxyl group; etc. In addition, the α position (carbon atom at a position) of hydroxystyrene is a carbon atom bonded to a benzene ring, unless specified otherwise.

Examples of a substituent substituted for the hydrogen atom at the α position of hydroxystyrene may be the same as the examples of the substituent for the α position of the α-substituted acrylic ester.

The term “constituent unit derived from vinylbenzoic acid or vinylbenzoic acid derivative” refers to a constituent unit formed by cleavage of an ethylenic double bond of vinylbenzoic acid or a vinylbenzoic acid derivative.

The term “vinylbenzoic acid derivative” includes vinylbenzoic acid, a hydrogen atom at an α position of which is substituted with a different substituent such as an alkyl group or a halogenated alkyl group, and derivatives thereof. Examples of these derivatives include vinylbenzoic acid wherein a hydrogen atom at a carboxyl group of the vinylbenzoic acid, a hydrogen atom at an α position of which may be substituted with a substituent, is substituted with an organic group; vinylbenzoic acid wherein a benzene ring of the vinylbenzoic acid, a hydrogen atom at an α position of which may be substituted with a substituent, is substituted with a substituent excluding hydroxyl and carboxyl groups; etc. In addition, the α position (carbon atom at a position) of vinylbenzoic acid refers to a carbon atom bonded to a benzene ring, unless specified otherwise.

The term “styrene derivative” refers to a compound wherein a hydrogen atom at an α position of styrene is substituted with a different substituent such as an alkyl group or a halogenated alkyl group.

The terms “constituent unit derived from styrene” and “constituent unit derived from styrene derivative” refer to a constituent unit formed by cleavage of an ethylenic double bond of styrene or a styrene derivative.

The alkyl group, as a substituent of the α position, is preferably a straight chain or branched alkyl group. Particularly, the alkyl group may be a C₁ to C₅ alkyl group (methyl group, ethyl group, propyl group, isopropyl group, n-butyl group, isobutyl group, tert-butyl group, pentyl group, isopentyl group, or neopentyl group), etc.

In addition, the halogenated alkyl group, as a substituent of the α position, may be particularly a group formed by substituting a portion or all of hydrogen atoms at “the alkyl group as a substituent of the α position” with a halogen atom. The halogen atom may be a fluorine atom, a chlorine atom, a bromine atom, an iodine atom, etc. Preferably, the halogen atom is a fluorine atom.

In addition, the hydroxyalkyl group, as a substituent of the α position, may be particularly a group formed by substituting a portion or all of hydrogen atoms at “the alkyl group as a substituent of the α position” with a hydroxyl group. The hydroxyalkyl group has preferably one to five hydroxyl groups, most preferably one hydroxyl group.

When the term “substituent may be included” is used, a hydrogen atom (—H) may be substituted with a monovalent group and a methylene group (—CH₂—) may be substituted with a divalent group.

The term “exposure” is used as a concept including an entire process of irradiation.

### MODE FOR INVENTION

### Chemical for Photolithography

A chemical for photolithography, as an aspect of the present invention, may be used in a photolithography process and includes a resin ingredient A having a mass-average molecular weight (Mw) of 2000 to 50000 and an organic solvent S having a saturated vapor pressure of 1 kPa or more (1 atm, 20° C.) and a viscosity of 1.1 cP (1 atm, 20° C.) or less. In particular, the chemical for photolithography of the present invention may be used to form a coating through spin coating. Hereinafter, the resin ingredient A and the organic solvent S, included in the chemical for photolithography of the present invention, will be described in detail.

<Resin Ingredient: Ingredient A>

The resin ingredient A (hereinafter, referred to as “ingredient A”) included in the chemical for photolithography of the present invention is not specifically limited so long as it has a mass-average molecular weight (Mw) of 2000 to 50000, is soluble in the solvent (S) described below, and may be used in a photolithography process. In particular, the resin ingredient A is preferably a resin solubility of which in a developer may change due to the action of an acid. If the resin solubility of which may change in a developer due to the action of an acid is included along with a photoacid generator described below in the chemical for photolithography, when the formed film is selectively exposed, an exposed portion of the film may be solublized by an alkali. In this case, by bringing the selectively exposed film into contact with an alkaline developer and thus removing the exposed portion, it is possible to form a pattern having a desired shape. The resin solubility of which in an alkali may be changed due to the action of an acid might not be used with the photoacid generator. When the resin has alkaline solubility, coating may be accomplished only using a solvent and the resin ingredient.

The chemical for photolithography according to the present invention preferably includes at least one resin selected from the group consisting of a novolac resin, a polyhydroxystyrene resin, and an acrylic resin which have a mass-average molecular weight (Mw) of 2000 to 50000.

[Novolac Resin]

The novolac resin is not specifically limited and may be randomly selected from those generally used in existing chemicals for photolithography. Preferably, the novolac resin is obtained by condensing an aromatic hydroxy compound with aldehydes and/or ketones.

Examples of the aromatic hydroxy compound used in synthesizing the novolac resin include phenols; cresols such as m-cresol, p-cresol, and o-cresol; xylenols such as 2,3-xylenol, 2,5-xylenol, 3,5-xylenol, and 3,4-xylenol; alkyl phenols such as m-ethylphenol, p-ethylphenol, o-ethylphenol, 2,3,5-trimethylphenol, 2,3,5-triethylphenol, 4-tert-butylphenol, 3-tert-butylphenol, 2-tert-butylphenol, 2-tert-butyl-4-methylphenol, and 2-tert-butyl-5-methylphenol; alkoxyphenols such as p-methoxyphenol, m-methoxyphenol, p-ethoxyphenol, m-ethoxyphenol, p-propoxyphenol, and m-propoxyphenol; isopropenylphenols such as o-isopropenylphenol, p-isopropenylphenol, 2-methyl-4-isopropenylphenol, and 2-ethyl-4-isopropenylphenol; arylphenols such as phenylphenol; and polyhydroxy phenols such as 4,4′-dihydroxybiphenyl, bisphenol A, resorcinol, hydroquinone, and pyrogallol. These compounds may be used alone or in a combination of two or more thereof.

Examples of aldehydes used in synthesizing the novolac resin include formaldehyde, paraformaldehyde, trioxane, acetaldehyde, propionaldehyde, butyraldehyde, trimethylacetaldehyde, acrolein, crotonaldehyde, cyclohexanealdehyde, furfural, furylacrolein, benzaldehyde, terephthalaldehyde, phenylacetaldehyde, α-phenylpropylaldehyde, β-phenylpropylaldehyde, o-hydroxybenzaldehyde, m-hydroxybenzaldehyde, p-hydroxybenzaldehyde, o-methylbenzaldehyde, m-methylbenzaldehyde, p-methylbenzaldehyde, o-chlorobenzaldehyde, m-chlorobenzaldehyde, p-chlorobenzaldehyde, cinnamic acid aldehyde, etc. These compounds may be used alone or in a combination of two or more thereof.

Among these aldehydes, formaldehyde is preferred with regard to easy obtainability thereof. In particular, a combination of formaldehyde and hydroxybenzaldehyde such as o-hydroxybenzaldehyde, m-hydroxybenzaldehyde, or p-hydroxybenzaldehyde is preferred in terms of satisfactory heat resistance.

Examples of the ketones used in synthesizing the novolac resin include acetone, methylethylketone, diethylketone, diphenylketone, etc. These compounds may be used alone or in a combination of two or more thereof.

In addition, the aldehydes and the ketones may be suitably mixed to be used. The novolac resin may be prepared by condensing the aromatic hydroxy compound with the aldehydes and/or the ketones in the presence of an acid catalyst according to a publicly known method. Examples of this acid catalyst include hydrochloric acid, sulfuric acid, formic acid, oxalic acid, p-toluene sulfonic acid, etc.

The mass-average molecular weight (Mw) of the novolac resin (calibrated with polystyrene through gel permeation chromatography (GPC)), i.e., the Mw of ingredient A before being protected by an acid-dissociative dissolution inhibiting group, is preferably 2000 to 50000, more preferably 3000 to 20000, most preferably 4000 to 15000. When the Mw is 2000 or more, satisfactory coatability is provided when the resin solubilized in the organic solvent is coated on a substrate. When the Mw is 50000 or less, satisfactory resolution is exhibited.

The novolac resin according to the present invention is preferably subjected to treatment to separate and remove low-molecular-weight materials so that heat resistance is further improved.

Here, the low-molecular-weight materials of the present specification may include, for example, unreacted residual monomers among monomers from the aromatic hydroxy compound, the aldehydes, the ketones, etc. used in synthesizing the novolac resin, dimers formed by binding between two monomers of the residual monomers, and trimmers formed by binding among three monomers of the residual monomers (monomers, dimeric to trimeric forms, etc.), etc.

The treatment to separate and remove the low-molecular-weight materials is not specifically limited and may be, for example, a method of purification using an ion exchange resin. Alternatively, a publicly known separation method using a good solvent (alcohol, etc.) and a bad solvent (water, etc.) for the resin may be used. When the former method is used, acidic ingredients or metallic ingredients may be removed along with the low-molecular-weight materials.

In such a treatment to separate and remove low-molecular-weight materials, a yield is preferably 50 to 95% by mass.

When the yield is 50% by mass or more, a dissolution rate difference between an exposed portion and an unexposed portion increases and satisfactory shapability is provided. In addition, when the yield is 95% by mass or less, sufficient effects of the treatment may be provided.

In addition, the content of low-molecular-weight materials having a Mw of 500 or less is 15% or less, preferably 12% or less, on a GPC chart. When the content is 15% or less, heat resistance of a resist pattern is improved and, at the same time, the amount of a sublimate generated upon heating is decreased.

[Polyhydroxystyrene Resin]

The polyhydroxystyrene resin is preferably a resin having a constituent unit derived from hydroxy styrene (hereinafter also referred to as polyhydroxystyrene (PHS)-based resin). When such a resin is used, a high-resolution pattern may be formed. In addition, also in the case of a thick film, minute processing is possible and thus a high aspect ratio pattern may be formed. In addition, resistance against dry etching, etc. improves.

In particular, the ingredient A which is preferably used with a KrF excimer laser is preferably a copolymer including constituent unit (a1)′ derived from hydroxy styrene and constituent unit (a2)′ having an acid-dissociative dissolution inhibiting group so as to provide effects of the present invention. More preferably, the ingredient A includes resin (A1)′ having constituent units (a1)′ and (a2)′, and constituent unit (a3)′ derived from styrene. Resin (A1)′ is preferably a copolymer.

Constituent Unit (a1)′

Constituent unit (a1)′ is a constituent unit derived from hydroxystyrene.

With regard to constituent unit (a1)′, the term “constituent unit derived from hydroxystyrene” includes a constituent unit formed by cleavage of an ethylenic double bond of hydroxystyrene and a hydroxystyrene derivative (monomer), as described above.

Here, the hydroxystyrene derivative includes at least a benzene ring and a hydroxyl group bonded to the ring as described above. Examples of the hydroxystyrene derivative include hydroxystyrene, a hydrogen atom bonded to an α position of which is substituted with a different substituent such as a halogen atom, a C₁ to C₅ lower alkyl group, a halogenated alkyl group, etc., hydroxystyrene, a C₁ to C₅ lower alkyl group is bonded to a benzene ring, including a hydroxyl group bonded thereto, of which, hydroxystyrene, one or two hydroxyl groups are additionally bonded to a benzene ring, including a hydroxyl group bonded thereto (in this case, the total number of hydroxyl groups is two to three), of which, etc.

The halogen atom may be a chlorine atom, a fluorine atom, a bromine atom, etc. Preferably, the halogen atom is a fluorine atom.

In addition, the term “a position of hydroxystyrene” refers to a carbon atom to which a benzene ring is bonded, unless specified otherwise.

Constituent unit (a11)′ is included in constituent unit (a1)′ and may be preferably represented by Formula (a1-1)′ below:

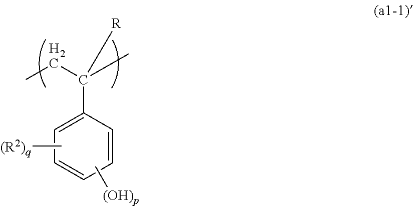

wherein R represents a hydrogen atom, an alkyl group, a halogen atom, or a halogenated alkyl group; R² represents a C₁ to C₅ lower alkyl group; p represents an integer of 1 to 3; and q represents an integer of 0, 1, or 2.

The alkyl group of R is preferably a lower alkyl group and a C₁ to C₅ alkyl group. In addition, the alkyl group is preferably a straight chain or branched alkyl group, and may be a methyl group, an ethyl group, a propyl group, an isopropyl group, an n-butyl group, an isobutyl group, a tert-butyl group, a pentyl group, an isopentyl group, a neopentyl group, etc. Thereamong, the methyl group is industrially preferred.

The halogen atom may be a fluorine atom, a chlorine atom, a bromine atom, an iodine atom, etc. In particular, the fluorine atom is preferred.

The halogenated alkyl group is preferably a halogenated lower alkyl group and the aforementioned C₁ to C₅ lower alkyl group a portion or all of hydrogen atoms of which are substituted with halogen atoms. Thereamong, all of the hydrogen atoms are preferably fluorinated.

The halogenated lower alkyl group is preferably a straight chain or branched fluorinated lower alkyl group, more preferably a trifluoromethyl group, a hexafluoroethyl group, a heptafluoropropyl group, a nonafluorobutyl group, etc., most preferably a trifluoromethyl group (—CF₃).

R is preferably a hydrogen atom or a methyl group, more preferably a hydrogen atom.

The C₁ to C₅ lower alkyl group of R² may be the same as the lower alkyl group of R.

q is an integer of 0, 1, or 2. Preferably, q is 0 or 1. In particular, q is preferably 0, industrially.

A substitution site of R² may be any one of an o-position, an m-position, and a p-position, when q is 1. In addition, when q is 2, randomly selected substitution sites may be used in a combination.

p is an integer of 1 to 3, preferably 1.

A substitution site of the hydroxyl group may be any one of an o-position, an m-position, and a p-position when p is 1. Preferably, the substitution site is a p-position which is easily obtained and cheap. In addition, when p is 2 or 3, randomly selected substitution sites may be used in a combination.

Constituent unit (a1)′ may be one type or a combination of two or more types.

A proportion of constituent unit (a1)′ in resin (A1)′ is preferably 20 to 80 mol %, more preferably 25 to 70 mol %, even more preferably 30 to 65 mol %, most preferably 45 to 65 mol %, based on total constituent units constituting resin (A1)′. When constituent unit (a1)′ is included in a resist composition within this range, proper alkaline solubility is provided and, at the same time, constituent unit (a1)′ has satisfactory balance with other constituent units.

Constituent Unit (a2)′

Constituent unit (a2)′ is a constituent unit having an acid-dissociative dissolution inhibiting group.

Constituent units (a21)′ and (a22)′ are included in constituent unit (a2)′. Constituent unit (a21)′ may be preferably represented by Formula (a2-1)′ below and constituent unit (a22)′ may be preferably represented by Formula (a2-2)′ below:

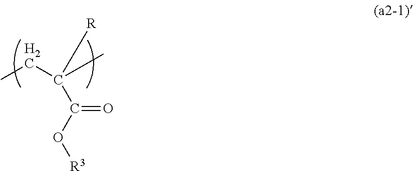

wherein R represents a hydrogen atom, an alkyl group, a halogen atom, or a halogenated alkyl group; and R³ represents an acid-dissociative dissolution inhibiting group.

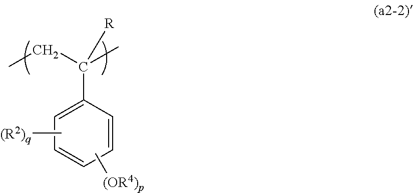

wherein R represents a hydrogen atom, an alkyl group, a halogen atom, or a halogenated alkyl group; R² represents a C₁ to C₅ lower alkyl group; p represents an integer of 1 to 3; q represents an integer of 0, 1, or 2; and R⁴ represents an acid-dissociative dissolution inhibiting group.

In Formulas (a2-1)′ and (a2-2)′, R³ and R⁴ respectively represent an acid-dissociative dissolution inhibiting group.

The acid-dissociative dissolution inhibiting group may be properly selected from those generally suggested for resins of resist compositions used with KrF excimer lasers, ArF excimer lasers, etc. Preferred examples of the acid-dissociative dissolution inhibiting group include a chain-type tertiary alkoxycarbonyl group, a chain-type tertiary alkoxycarbonylalkyl group, and a chain or cyclic tertiary alkyl group.

The chain-type tertiary alkoxycarbonyl group has a carbon number of preferably 4 to 10, more preferably 4 to 8. The chain-type tertiary alkoxycarbonyl group may be particularly a tert-butoxy carbonyl group, a tert-amyloxy carbonyl group, etc.

The chain-type tertiary alkoxycarbonylalkyl group has a carbon number of preferably 4 to 10, more preferably 4 to 8. The chain-type tertiary alkoxycarbonylalkyl group may be particularly a tert-butoxycarbonyl methyl group, a tert-amyloxycarbonyl methyl group, etc.

The chain-type tertiary alkyl group has a carbon number of preferably 4 to 10, more preferably 4 to 8. The chain-type tertiary alkyl group may be particularly a tert-butyl group, a tert-amyl group, etc.

The cyclic tertiary alkyl group is a monocyclic or polycyclic monovalent saturated hydrocarbon group including a tertiary carbon atom on a ring thereof The cyclic tertiary alkyl group may be particularly a 1-methyl-cyclopentyl group, a 1-ethyl-cyclopentyl group, a 1-methyl-cyclohexyl group, a 1-ethyl-cyclohexyl group, a 2-methyl-2-adamantyl group, a 2-ethyl-2-adamantyl group, etc.

When the chain-type tertiary alkoxycarbonyl group, the chain-type tertiary alkoxycarbonylalkyl group, or the chain or cyclic tertiary alkyl group is included as the acid-dissociative dissolution inhibiting group, heat resistance improves.

Among these acid-dissociative dissolution inhibiting groups, particularly the chain-type tertiary alkyl group is preferred in terms of resolution. Thereamong, the tert-butyl group is more preferred.

In the present invention, the acid-dissociative dissolution inhibiting group may be preferably represented by Formula (I)′ below:

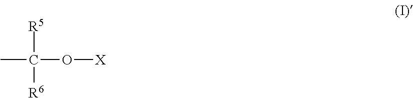

wherein X represents an alicyclic group, an aromatic cyclic hydrocarbon group, or a lower alkyl group; and R⁵ represents a hydrogen atom or a lower alkyl group, or X and R⁵ are each independently a C₁ to C₅ alkylene group and a terminal of X and a terminal of R⁵ may be coupled; and R⁶ represents a hydrogen atom or a lower alkyl group.

In the present specification and the accompanying claims, the term “aliphatic” is a relative concept as described above and refers to non-aromatic groups, compounds, etc.

The term “alicyclic group” refers to a non-aromatic monocyclic or polycyclic group and may be saturated or unsaturated. Generally, a saturated alicyclic group is preferred.

The alicyclic group of X is a monovalent alicyclic group. The alicyclic group may be suitably selected from those generally used in existing KrF resists and ArF resists.

Specific examples of the alicyclic group include an aliphatic monocyclic group having a carbon number of 5 to 7, an aliphatic polycyclic group having a carbon number of 7 to 16, etc.

The aliphatic monocyclic group having a carbon number of 5 to 7 may be, for example, a group formed by removing one hydrogen atom from monocycloalkane, particularly a group formed by removing one hydrogen atom from cyclopentane, cyclohexane, etc.

The aliphatic polycyclic group having a carbon number of 7 to 16 may be, for example, a group formed by removing one hydrogen atom from bicycloalkane, tricycloalkane, tetracycloalkane, etc., particularly a group formed by removing one hydrogen atom from polycycloalkane such as adamantane, norbornane, isobornane, tricyclodecane, and tetracyclododecane. Thereamong, an adamantyl group, a norbornyl group, and a tetracyclododecyl group are industrially preferred. In particular, the adamantyl group is preferred.

The aromatic cyclic hydrocarbon group of X may be an aromatic polycyclic group having a carbon number of 10 to 16, etc. Particularly, the aromatic cyclic hydrocarbon group may be, for example, a group formed by removing one hydrogen atom from naphthalene, anthracene, phenanthrene, pyrene, etc., more particularly a 1-naphthyl group, a 2-naphthyl group, a 1-anthracenyl group, a 2-anthracenyl group, a 1-phenanthryl group, a 2-phenanthryl group, a 3-phenanthryl group, a 1-pyrenyl group, etc. In particular, the 2-naphthyl group is industrially preferred.

The lower alkyl group of X may be the same as the lower alkyl group of R of Formula (a1-1)′.

X is preferably a lower alkyl group, more preferably a methyl group or an ethyl group, most preferably an ethyl group.

The lower alkyl group of R⁵ may be the same as the lower alkyl group of R of Formula (a1-1)′. Industrially, the lower alkyl group is preferably a methyl group or an ethyl group. In particular, the methyl group is preferred.

R⁶ represents a lower alkyl group or a hydrogen atom. The lower alkyl group of R⁶ may be the same as the lower alkyl group of R⁵. Industrially, R⁶ is preferably a hydrogen atom.

In addition, in Formula (I)′, X and R⁵ are each independently a C₁ to C₅ alkylene group, and a terminal of X and a terminal of R⁵ may be coupled.

In this case, in Formula (I)′, a cyclic group is formed by R⁵, X, an oxygen atom bonded to X, and a carbon atom to which the oxygen atom and R⁵ are bonded.

The cyclic group is preferably a ring composed of four to seven atoms, more preferably a ring composed of four to six atoms. Specific examples of the cyclic group include a tetrahydropyranyl group, a tetrahydrofuranyl group, etc.

In the acid-dissociative dissolution inhibiting group (I)′, when R⁶ is particularly a hydrogen atom, superior effects according to the present invention are provided. Accordingly, R⁶ is preferably a hydrogen atom.

The specific examples thereof, when X is an alkyl group, include a 1-alkoxyalkyl group such as a 1-methoxy ethyl group, a 1-ethoxyethyl group, a 1-iso-propoxyethyl group, a 1-n-butoxyethyl group, a 1-tert-butoxyethyl group, a methoxymethyl group, an ethoxymethyl group, an iso-propoxymethyl group, an n-butoxymethyl group, and a tert-butoxymethyl group.

In addition, the examples thereof, when X is an alicyclic group, include a 1-cyclohexyloxy ethyl group, a (2-adamantyl)oxymethyl group, and a 1-(1-adamantyl)oxyethyl group represented by Formula (II-a) below.

Further, the examples thereof, when X is an aromatic cyclic hydrocarbon group, include a 1-(2-naphthyl)oxyethyl group represented by Formula (II-b) below, etc.

Thereamong, the 1-ethoxyethyl group is particularly preferred.

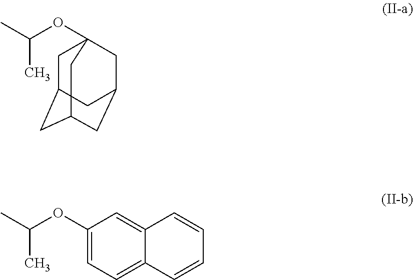

The acid-dissociative dissolution inhibiting group of the present invention is preferably at least one selected from the group consisting of a chain-type tertiary alkoxycarbonyl group, a chain-type tertiary alkoxycarbonylalkyl group, a chain or cyclic tertiary alkyl group, and the compound represented by Formula (I)′.

Thereamong, the compound represented by Formula (I)′ is more preferable. Most preferably, the compound represented by Formula (I)′ is included as a main ingredient.

Here, the term “included as a main ingredient” means that, in the acid-dissociative dissolution inhibiting group included in resin (A1)′, the ingredient is included in an amount of 50 mol % or more, preferably 70 mol % or more, more preferably 80 mol % or more.

In addition, R of constituent units (a21)′ and (a22)′ may be the same as R of Formula (a1-1)′.

R² of constituent unit (a22)′ may be the same as R² of Formula (a1-1)′.

In addition, p and q of constituent unit (a22)′ may be respectively the same as p and q of Formula (a1-1)′.

Constituent unit (a2)′ may be one type or a combination of two or more types.

A proportion of constituent unit (a2)′ in resin (A1)′ is preferably 5 to 70 mol %, more preferably 5 to 65 mol % based on total constituent units constituting resin (A1)′. The proportion is more preferably 5 to 60 mol %, most preferably 5 to 55 mol %. When constituent unit (a2)′ is included in the lowest ratio or more to prepare a resist composition, a satisfactory resist pattern may be obtained. When constituent unit (a2)′ is included at the highest proportion or less, it has satisfactory balance with other constituent units.

In addition, when constituent unit (a2)′ is constituent unit (a21)′, constituent unit (a21)′ is included in an amount of preferably 5 to 70 mol %, more preferably 5 to 50 mol %, even more preferably 10 to 45 mol %, most preferably 10 to 35 mol %, based on total constituent units constituting resin (A1)′. When constituent unit (a21)′ is included in the lowest amount or more to prepare a resist composition, a satisfactory resist pattern may be obtained. When constituent unit (a21)′ is included in the highest amount or less, it has satisfactory balance with other constituent units.

In addition, when constituent unit (a2)′ is constituent unit (a22)′, constituent unit (a22)′ is included in an amount of preferably 5 to 70 mol %, more preferably 10 to 65 mol %, even more preferably 20 to 60 mol %, most preferably 30 to 55 mol %, based on total constituent units constituting resin (A1)′. When constituent unit (a22)′ is included in the lowest amount or more to prepare a resist composition, a satisfactory resist pattern may be obtained. When constituent unit (a22)′ is included in the highest amount or less, it has satisfactory balance with other constituent units.

Constituent Unit (a3)′

Resin (A1)′ may additionally have constituent unit (a3)′ derived from styrene. Although constituent unit (a3)′ is not an essential unit, heat resistance may improve when constituent unit (a3)′ is included to prepare a resist composition.

With regard to constituent unit (a3)′, the term “constituent unit derived from styrene” includes constituent units formed by cleavage of ethylenic double bonds of styrene and styrene derivatives (but hydroxystyrene is not included).

The term “styrene derivative” includes a compound wherein a hydrogen atom bonded to an α position of styrene is substituted with a different substituent such as a halogen atom, an alkyl group, or a halogenated alkyl group, a compound wherein a hydrogen atom at a phenyl group of styrene is substituted with a substituent such as a C₁ to C₅ lower alkyl group, and the like.

The halogen atom may be a chlorine atom, a fluorine atom, a bromine atom, etc. Preferably, the halogen atom is a fluorine atom.

In addition, the term “α position of styrene” refers to a carbon atom to which a benzene ring is bonded, unless specified otherwise.

Constituent unit (a31)′ is included in constituent unit (a3)′ and may be preferably represented by Formula (a3-1)′ below:

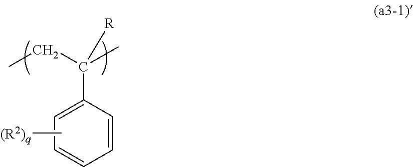

wherein R represents a hydrogen atom, an alkyl group, a halogen atom, or a halogenated alkyl group; R² represents a C₁ to C₅ lower alkyl group; and q represents an integer of 0, 1, or 2.

R and R² may be respectively the same as R and R² of Formula (a1-1)′.

q is an integer of 0, 1, or 2. Preferably, q is 0 or 1. In particular, q is preferably 0, industrially.

A substitution site of R² may be any one of an o-position, an m-position, and a p-position, when q is 1. In addition, when q is 2, randomly selected substitution sites may be used in a combination.

Constituent unit (a3)′ may be one type or a combination of two or more types.

When resin (A1)′ includes constituent unit (a3)′, a mole fraction of constituent unit (a3)′ is preferably 1 to 25 mol %, more preferably 5 to 25 mol %, most preferably 5 to 20 mol %, based on total constituent units constituting resin (A1)′. When constituent unit (a3)′ is included within this range to prepare a resist composition, heat resistance effect improves and, at the same time, satisfactory balance with other constituent units is provided.

Resin (A1)′ may include other constituent units, other than essential constituent units (a1)′ and (a2)′ and preferably included constituent unit (a3)′, within a range in which effects of the present invention are not impaired.

The constituent units that may be included are not specifically limited so long as they are not included in the aforementioned essential constituent units (a1)′ to (a2)′ and in the preferably included constituent unit (a3)′, and may be a plurality of conventionally known units used in resins for resists of KrF positive excimer lasers, ArF excimer lasers, etc.

Resin (A1)′ is preferably copolymer A11-1-1 having a combination of the following constituent units:

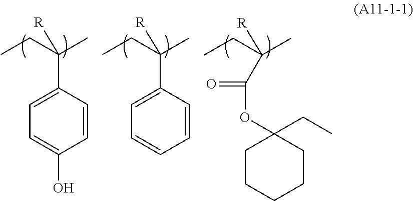

wherein R is the same as R of Formula (a1-1)′.

Resin (A1)′ may be obtained by polymerizing, e.g., publicly known radical-polymerizing, etc., a monomer from which every constituent unit are derived with a radical polymerization initiator such as, for example, azobisisobutyronitrile (AIBN).

In addition, a —C (CF₃)₂—OH group may be introduced to a terminal of resin (A1)′ by combining a chain-transfer agent, such as, for example, HS—CH₂—CH₂—CH₂—C(CF₃)₂—OH, with the radical polymerization initiator upon polymerization. As such, a copolymer including a hydroxyalkyl group some hydrogen atoms at an alkyl group of which are substituted with fluorine atoms is effective in lowering defective development or LER (line edge roughness: non-uniform roughness on side walls of line).

The mass-average molecular weight (Mw) (calibrated with polystyrene through gel permeation chromatography) of resin (A1)′ is not specifically limited, but preferably 2000 to 50000, more preferably 3000 to 30000, most preferably 4000 to 20000. When the Mw of resin (A1)′ is less than the highest value, solubility of resin (A1)′ in a resist solvent is sufficient for use as a resist and the viscosity of a composition may be lowered. When the Mw of resin (A1)′ is greater than the lowest value, satisfactory dry etching resistance is provided or a cross-section shape of a resist pattern is satisfactory.

In addition, a dispersion degree (Mw/Mn) is preferably 1.0 to 5.0, more preferably 1.0 to 3.0, most preferably 1.2 to 2.5.

Resin (A1)′ included in ingredient A may be one type or a combination of two or more types.

In addition, ingredient A may include resin ingredients other than resin (A1)′.

The amount of resin (A1)′ included in ingredient A is preferably 70% by mass or more, more preferably 80% by mass or more, most preferably 100% by mass.

[Acrylic Resin]

An acrylic resin preferably includes unit (a1)″, the polarity of which increases due to the action of an acid and which includes an acid-dissociative group, unit (a2)″ that includes a cyclic group containing lactone, a cyclic group containing carbonate, or a cyclic group containing —SO₂— (except for those corresponding to the aforementioned unit (a1)″), unit (a3)″ that includes an aliphatic hydrocarbon group containing a polar group (except for those corresponding to the aforementioned units (a1)″ and (a2)″), unit (a4)″ that includes an acid-non-dissociative cyclic group, etc.

Constituent Unit (a1)″

Constituent unit (a1)″ may be a resin including a constituent unit represented by Formula (a1-1)″ or (a1-2)″ below:

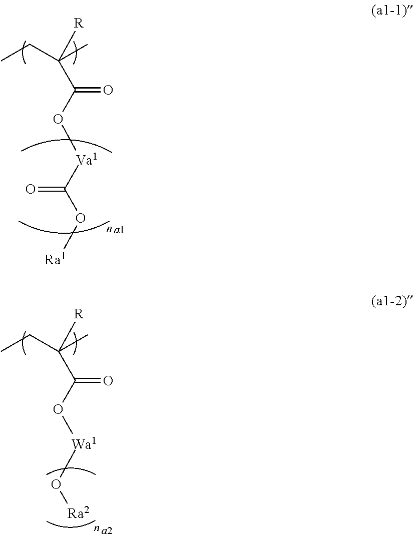

wherein R is a hydrogen atom, a C₁ to C₅ alkyl group, or a C₁ to C₅ halogenated alkyl group. Va¹ is a divalent hydrocarbon group that may have an ether linkage, an urethane linkage, or an amide linkage, nₐ₁ is 0 to 2, and Ra¹ is an acid-dissociative group represented by Formula (a1-r-1)″ or (a1-r-2)″ below. Wa¹ is a (nₐ₂+1)-valent hydrocarbon group, nₐ₂ is 1 to 3, and Ra² is an acid-dissociative group represented by Formula (a1-r-1)″ or (a1-r-3)″ below.

The C₁ to C₅ alkyl group of Formula (a1-1)″ is preferably a straight chain or branched alkyl group, particularly may be a methyl group, an ethyl group, a propyl group, an isopropyl group, an n-butyl group, an isobutyl group, a tert-butyl group, a pentyl group, an isopentyl group, a neopentyl group, etc. The C₁ to C₅ halogenated alkyl group of Formula (a1-1)″ is a group formed by substituting a portion or all of hydrogen atoms of the C₁ to C₅ alkyl group with halogen atoms. The halogen atom may be a fluorine atom, a chlorine atom, a bromine atom, an iodine atom, etc. In particular, the halogen atom is preferably a fluorine atom.

R is preferably a hydrogen atom, a C₁ to C₅ alkyl group, or a C₁ to C₅ fluorinated alkyl group, more preferably a hydrogen atom or a methyl group due to easy industrial obtainability thereof.

The divalent hydrocarbon group of Va¹ may be an aliphatic or aromatic hydrocarbon group. The aliphatic hydrocarbon group is a non-aromatic hydrocarbon group. The aliphatic hydrocarbon group, as a divalent hydrocarbon group of Va¹, may be saturated or unsaturated. In general, the saturated aliphatic hydrocarbon group is preferred.

The aliphatic hydrocarbon group may be more particularly a straight chain or branched aliphatic hydrocarbon group, an aliphatic hydrocarbon group including a ring in a structure thereof, or the like.

In addition, bonding of the divalent hydrocarbon group of Va¹ may be an ether linkage, a urethane linkage, or an amide linkage.

The straight chain or branched aliphatic hydrocarbon group has a carbon number of preferably 1 to 10, more preferably 1 to 6, even more preferably 1 to 4, most preferably 1 to 3.

The straight chain aliphatic hydrocarbon group is preferably a straight chain alkylene group, and may be particularly a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], or the like.

The branched aliphatic hydrocarbon group is preferably a branched chain alkylene group, and may be particularly an alkylalkylene group such as an alkyl methylene group, such as —CH(CH₃)—, —CH(CH₂CH₃)—, —C(CH₃)₂—, —C(CH₃) (CH₂CH₃)—, —C(CH₃)(CH₂CH₂CH₃)—, or —C(CH₂CH₃)₂—; an alkylethylene group such as —CH(CH₃)CH₂—, —CH(CH₃)CH(CH₃)—, —C(CH₃)₂CH₂—, —CH(CH₂CH₃)CH₂—, or —C (CH₂CH₃)₂—CH₂—; an alkyltrimethylene group, such as —CH(CH₃)CH₂CH₂— or —CH₂CH(CH₃)CH₂—; or an alkyltetramethylene group, such as —CH (CH₃)CH₂CH₂CH₂— or —CH₂CH(CH₃)CH₂CH₂—, etc. An alkyl group of the alkylalkylene group is preferably a straight chain C₁ to C₅ alkyl group.

Examples of the straight chain or branched aliphatic hydrocarbon group may be the same as those described above.

The aliphatic hydrocarbon group including a ring in a structure thereof may be an alicyclic hydrocarbon group (a group formed by removing two hydrogen atoms from an aliphatic hydrocarbon ring), a straight chain or branched aliphatic hydrocarbon group including an alicyclic hydrocarbon group bonded to a terminal thereof, a straight chain or branched aliphatic hydrocarbon group including an alicyclic hydrocarbon group inserted in the middle of the structure, or the like. The straight chain or branched aliphatic hydrocarbon group may be the same as those described above.

The alicyclic hydrocarbon group has a carbon number of preferably 3 to 20, more preferably 3 to 12.

The alicyclic hydrocarbon group may be polycyclic or monocyclic. The monocyclic alicyclic hydrocarbon group is preferably a group formed by removing two hydrogen atoms from monocycloalkane. The monocycloalkane has a carbon number of preferably 3 to 6, and may be particularly cyclopentane, cyclohexane, or the like. The polycyclic alicyclic hydrocarbon group is preferably a group formed by removing two hydrogen atoms from polycycloalkane. The polycycloalkane has a carbon number of preferably 7 to 10, and may be particularly adamantane, norbornane, isobornane, tricyclodecane, or the like.

The aromatic hydrocarbon group is a hydrocarbon group having an aromatic ring.

The aromatic hydrocarbon group as the divalent hydrocarbon group of Va¹ has a carbon number of preferably 3 to 30, more preferably of 5 to 30, more preferably 5 to 20, even more preferably 6 to 15, most preferably 6 to 10. However, the carbon number does not include a carbon number of a substituent.

The aromatic ring included in the aromatic hydrocarbon group may be particularly an aromatic hydrocarbon ring such as benzene or naphthalene; a heterocyclic aromatic ring formed by substituting a portion of the carbon atoms constituting the aromatic hydrocarbon ring with a heteroatom; or the like. The heteroatom of the heterocyclic aromatic ring may be an oxygen atom, a sulfur atom, a nitrogen atom, or the like.

The aromatic hydrocarbon group may be particularly a group formed by removing two hydrogen atoms from the aromatic hydrocarbon ring (arylene group); a group formed by substituting one hydrogen atom of a group (aryl group) which is formed by removing a hydrogen atom from the aromatic hydrocarbon ring, with an alkylene group (e.g., a group formed by additionally removing a hydrogen atom from an aryl group of an arylalkyl group such as a benzyl group, a phenethyl group, a 1-naphthylmethyl group, a 2-naphthylmethyl group, a 1-naphthylethyl group, or a 2-naphthylethyl group); a group formed by removing two hydrogen atoms from an aromatic compound including two or more aromatic rings (e.g., biphenyl, fluorene, etc.), or the like. The alkylene group (alkyl chain of arylalkyl group) has a carbon number of preferably 1 to 4, more preferably 1 to 2, even more preferably 1.

In Wa¹ of Formula (a1−2)″, the (nₐ₂+1)-valent hydrocarbon group may be an aliphatic or aromatic hydrocarbon group. The aliphatic hydrocarbon group is a non-aromatic hydrocarbon group and may be saturated or unsaturated. Generally, the aliphatic hydrocarbon group is preferably saturated. The aliphatic hydrocarbon group may be a straight chain or branched aliphatic hydrocarbon group, an aliphatic hydrocarbon group including a ring in a structure thereof, or a group formed by combining the straight chain or branched aliphatic hydrocarbon group with the aliphatic hydrocarbon group including a ring in a structure thereof. Particularly, examples of the aliphatic hydrocarbon group may be the same as those of Va¹ of Formula (a1−1)″ described above.

The nₐ₂+1 is preferably divalent to tetravalent, more preferably divalent or trivalent.

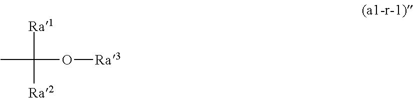

wherein Ra^{′1} and Ra^{′2} are a hydrogen atom or an alkyl group, Ra^{′3} is a hydrocarbon group, and Ra^{′3} may form a ring by combining with Ra^{′1} or Ra^{′2}. An acid-dissociative group represented by Formula (a1-r-1)″ may be referred to as “acetal-type acid-dissociative group” for convenience.

Examples of the alkyl groups of Ra^{′1} and Ra^{′2} of Formula (a1-r-1)″ may be the same as the examples of the alkyl group as the substituent that may be bonded to the carbon atom of the α position of the α-substituted acrylic acid ester described above. The alkyl groups of Ra^{′1} and Ra^{′2} of Formula (a1-r-1)″ are preferably a methyl group or an ethyl group, most preferably a methyl group.

The hydrocarbon group of Ra^{′3} is preferably a C₁ to C₂₀ alkyl group, more preferably C₁ to C₁₀ alkyl group, most preferably a straight chain or branched alkyl group. Particularly, the hydrocarbon group of Ra^{′3} may be a methyl group, an ethyl group, a propyl group, an isopropyl group, an n-butyl group, an isobutyl group, a tert-butyl group, a pentyl group, an isopentyl group, a neopentyl group, a 1,1-dimethyl ethyl group, a 1,1-diethylpropyl group, a 2,2-dimethylpropyl group, a 2,2-dimethylbutyl group, etc.

When Ra^{′3} is a cyclic hydrocarbon group, the cyclic hydrocarbon group may be aliphatic or aromatic, and polycyclic or monocyclic. The monocyclic alicyclic hydrocarbon group is preferably a group formed by removing one hydrogen atom from monocycloalkane. The monocycloalkane has a carbon number of preferably 3 to 8, and may be particularly cyclopentane, cyclohexane, cyclooctane, etc. The polycyclic alicyclic hydrocarbon group is preferably a group formed by removing one hydrogen atom from a polycycloalkane. The polycycloalkane has a carbon number of preferably 7 to 12 and may be particularly adamantane, norbornane, isobornane, tricyclodecane, tetracyclododecane, etc.

When Ra^{′3} is an aromatic hydrocarbon group, an included aromatic ring may be particularly an aromatic hydrocarbon ring such as benzene, biphenyl, fluorene, naphthalene, anthracene, or phenanthrene; a heterocyclic aromatic ring formed by substituting a portion of the carbon atoms constituting the aromatic hydrocarbon ring with a heteroatom; or the like. The heteroatom of the heterocyclic aromatic ring may be an oxygen atom, sulfur atom, nitrogen atom, etc.

The aromatic hydrocarbon group may be particularly a group formed by removing one hydrogen atom from the aromatic hydrocarbon ring (aryl group); a group formed by substituting one hydrogen atom of the aryl group with an alkylene group (e.g., an arylalkyl group such as a benzyl group, a phenethyl group, a 1-naphthylmethyl group, a 2-naphthylmethyl group, a 1-naphthylethyl group, or a 2-naphthylethyl group, or the like); or the like. The alkylene group (alkyl chain of arylalkyl group) has a carbon number of preferably 1 to 4, more preferably 1 to 2, particularly preferably 1.

When Ra^{′3} forms a ring by coupling with Ra^{′1} or Ra^{′2}, a formed cyclic group has preferably 4 to 7 atoms, more preferably 4 to 6 atoms. Specific examples of the cyclic group include a tetrahydropyranyl group, a tetrahydrofuranyl group, etc.

An acid-dissociative group protecting a carboxyl group among the polar groups may be, for example, an acid-dissociative group represented by Formula (a1-r-2)″ below (a group constituted of an alkyl group, among acid-dissociative groups represented by Formula (a1-r-2)″ below, may hereinafter be referred to as “tertiary alkylester acid-dissociative group” for convenience).

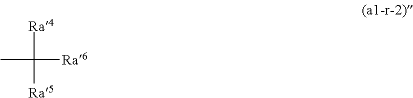

wherein Ra^{′4} to Ra^{′6} are each a hydrocarbon group, and Ra^{′5} and Ra^{′6} may be coupled to form a ring.

The hydrocarbon group of each of Ra^{′4} to Ra^{′6} may be the same as the hydrocarbon group of Ra^{′3}. Ra^{′4} is preferably a C₁ to C₅ alkyl group. When Ra^{′5} and Ra^{′6} are coupled to form a ring, a group represented by Formula (a1-r2-1)″ below may be formed.

Meanwhile, when Ra^{′4} to Ra^{′6} do not bond together and are present as a independent hydrocarbon groups, the acid-dissociative group may be represented by Formula (a1-r2-2)″ below.

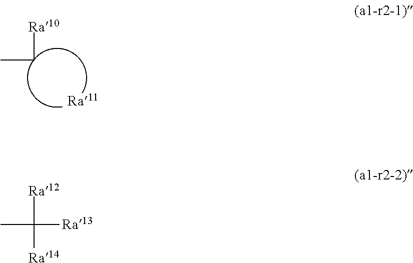

wherein Ra^{′10} is a C₁ to C₁₀ alkyl group, and Ra^{′11} forms an alicyclic group with a carbon atom to which Ra^{′10} is bonded. Ra^{′12} to Ra^{′14} each independently represent a hydrocarbon group.

Examples of the C₁ to C₁₀ alkyl group of Ra^{′10} of Formula (a1-r2-1)″ are preferably the same as the examples of the straight chain or branched alkyl group of Ra^{′3} of Formula (a1-r-1)″. Examples of the alicyclic group constituting Ra^{′11} of Formula (a1-r2-1)″ are preferably the same as the examples of the cyclic alkyl group of Ra^{′3} of Formula (a1-r-1)″.

Ra^{′12} and Ra^{′14} of Formula (a1-r2-2)″ are each independently, preferably a C₁ to C₁₀ alkyl group. Examples of the alkyl group are more preferably the same as the examples of the straight chain or branched alkyl group of Ra^{′3} of Formula (a1-r-1)″. The alkyl group is even more preferably a C₁ to C₅ straight chain alkyl group, particularly preferably a methyl group or an ethyl group.

Ra^{′13} of Formula (a1-r2-2)″ is preferably the straight chain or branched alkyl group, or the monocyclic or polycyclic alicyclic hydrocarbon group which are exemplified as the hydrocarbon group of Ra^{′3} of Formula (a1-r-1)″. Thereamong, the examples of the cyclic alkyl group of Ra^{′3} are more preferred.

Specific examples of groups represented by Formula (a1-r2-1)″ are as follows. In the following formulas, the symbol ┌*┘ represents a dangling bond:

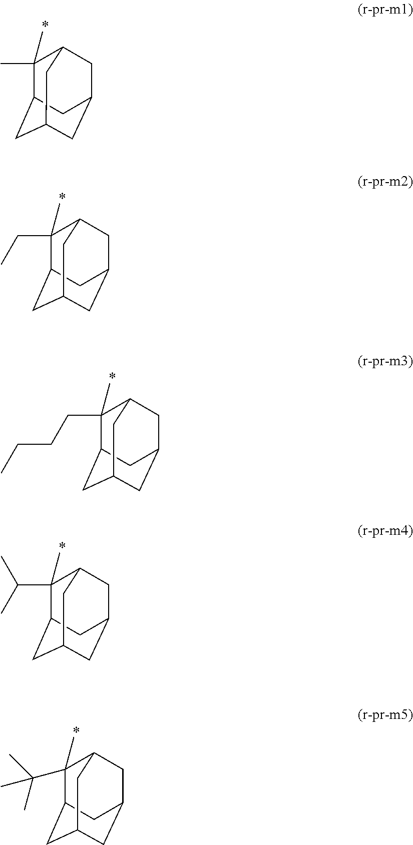

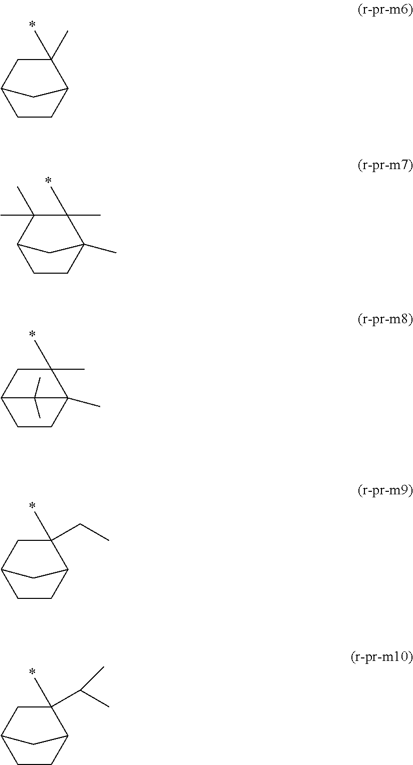

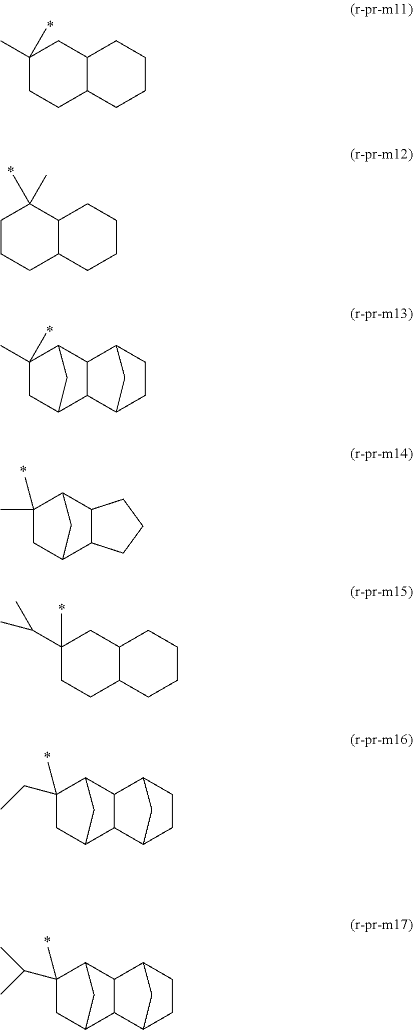

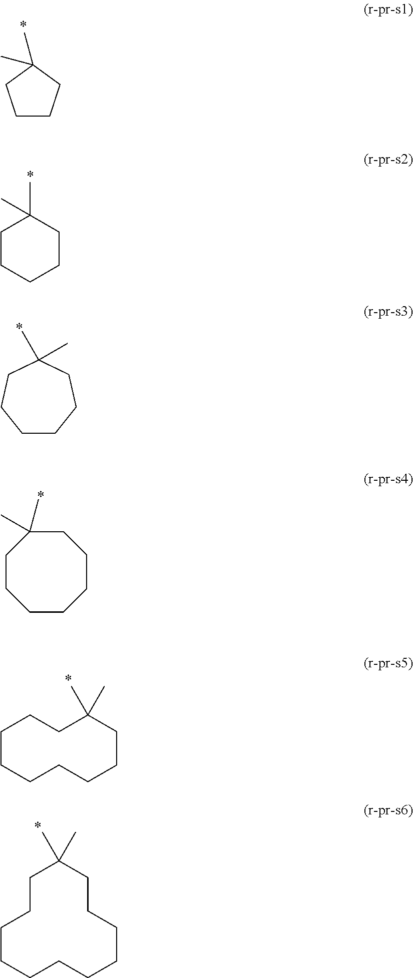

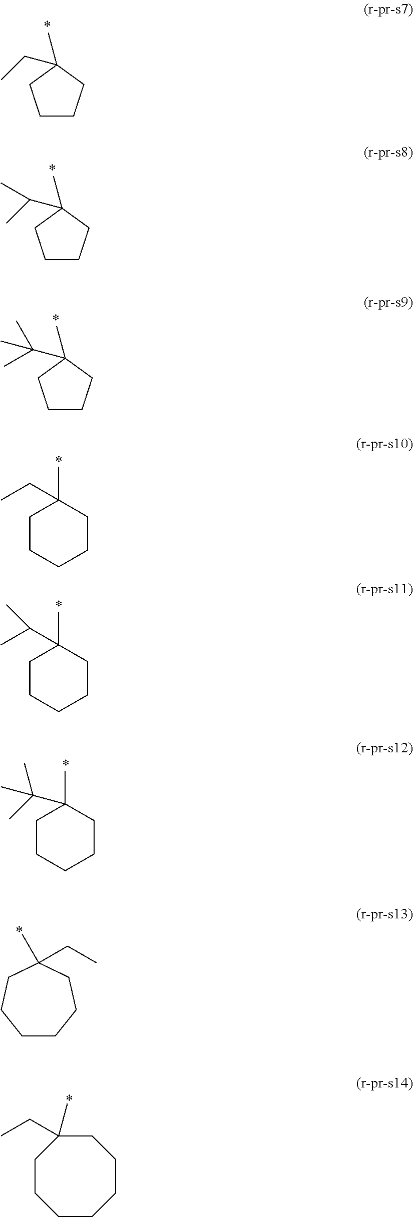

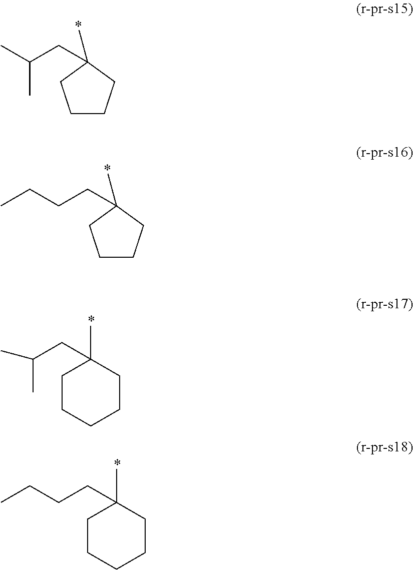

Specific examples of Formula (a1-r2-2)′ are as follows:

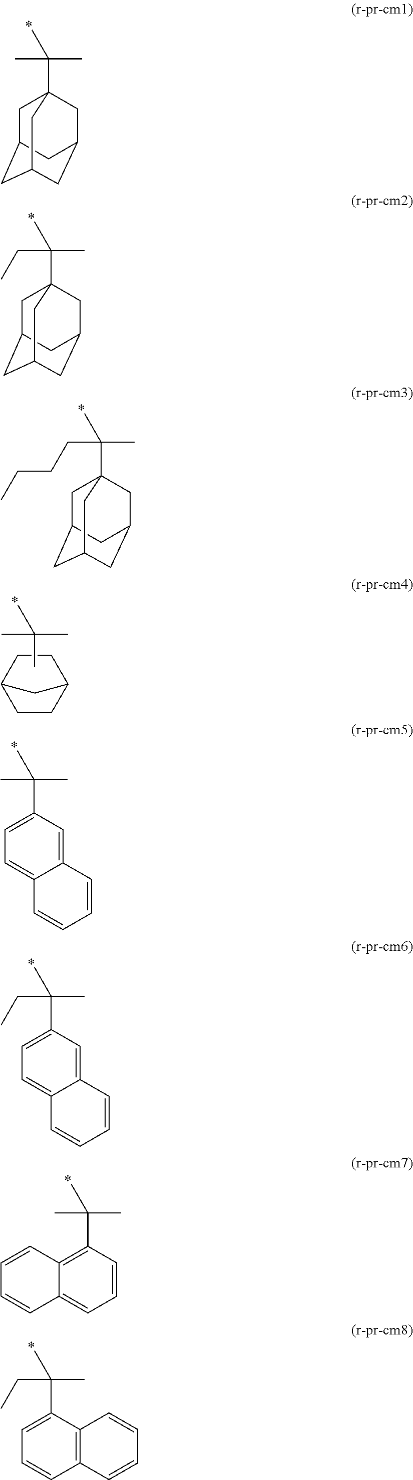

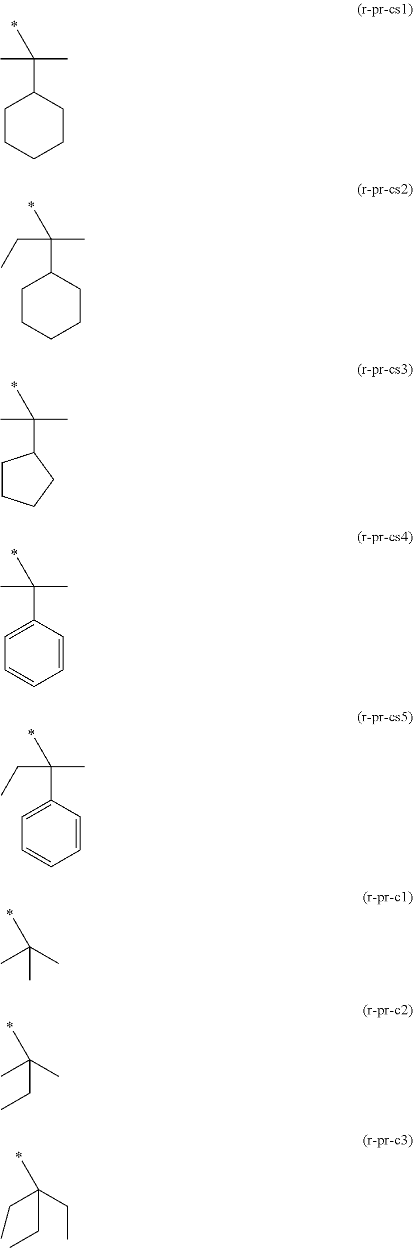

In addition, an acid-dissociative group protecting a hydroxyl group among the polar groups may be, for example, an acid-dissociative group (hereinafter, referred to as “tertiary alkyl oxycarbonyl acid-dissociative group” for convenience) represented by Formula (a1-r-3)″ below:

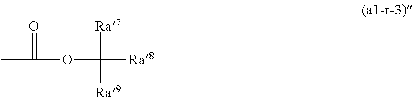

wherein Ra^{′7} to Ra^{′9} represent an alkyl group.

Ra^{′7} to Ra^{′9} of Formula (a1-r-3)″ is preferably a C₁ to C₅ alkyl group, more preferably a C₁ to C₃ alkyl group.

In addition, a total carbon number of each of the alkyl groups is preferably 3 to 7, more preferably 3 to 5, most preferably 3 to 4.

Formula (a1-2)″ is particularly preferably a constituent unit represented by Formula (a1-2-01)″ below.

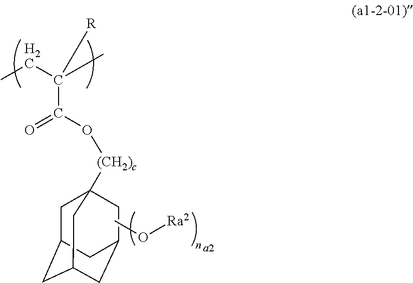

Ra² of Formula (a1-2-01)″ is an acid-dissociative group represented by Formula (a1-r-1)″ or (a1-r-3)″. nₐ₂ is an integer of 1 to 3, preferably 1 or 2, more preferably 1. c is an integer of 0 to 3, preferably 0 or 1, more preferably 1. R is the same as R of Formula (a1-1)″.

Hereinafter, specific examples of Formula (a1-1)″ are described. R^{α} of each of the following formulas is a hydrogen atom, a methyl group or a trifluoromethyl group.

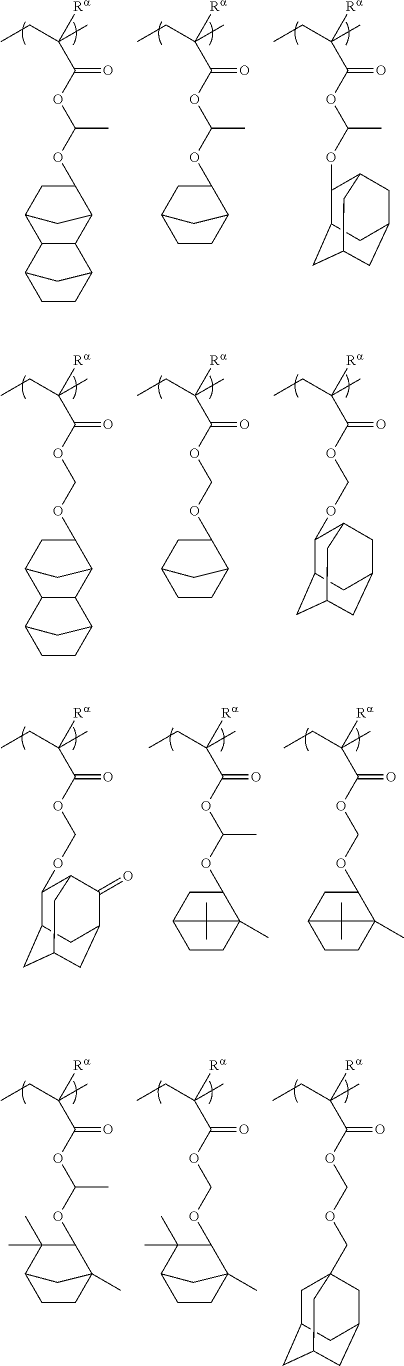

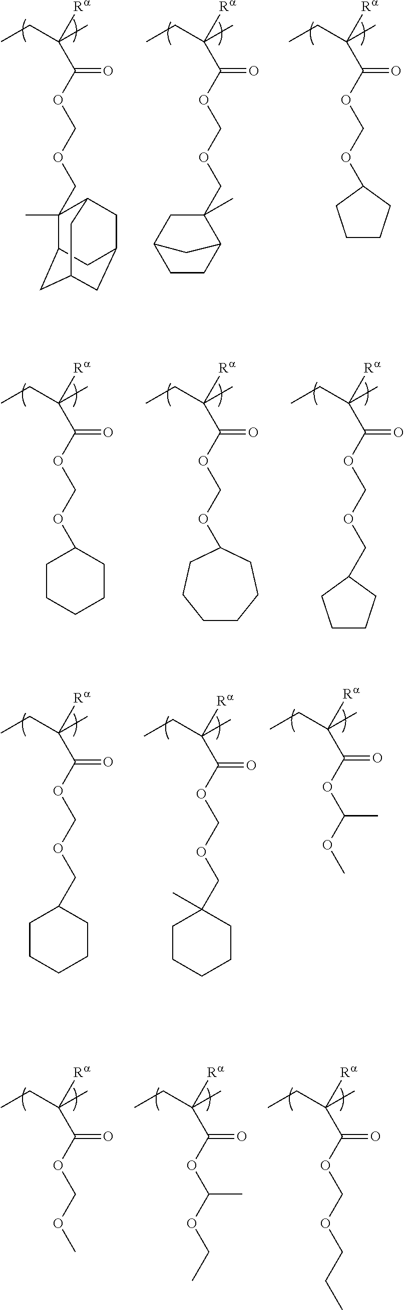

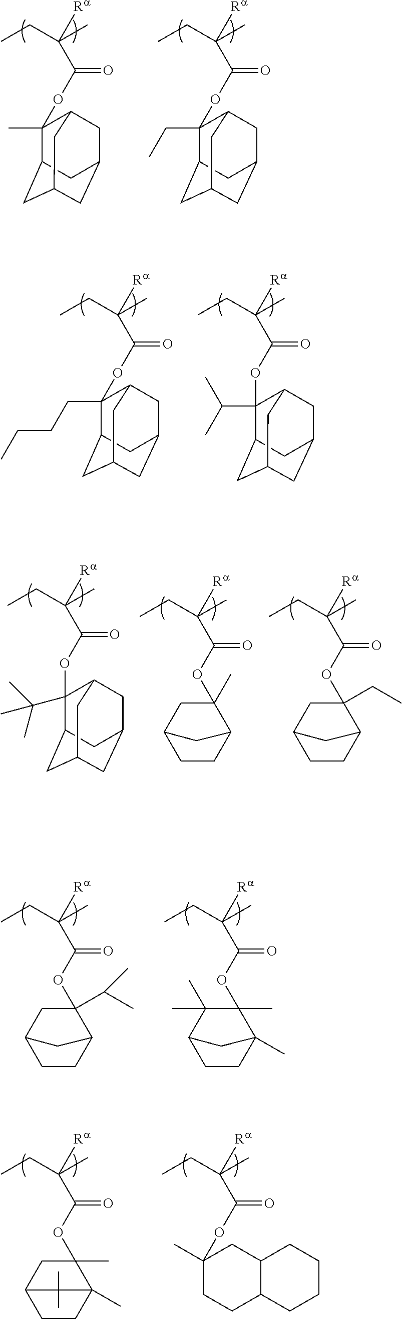

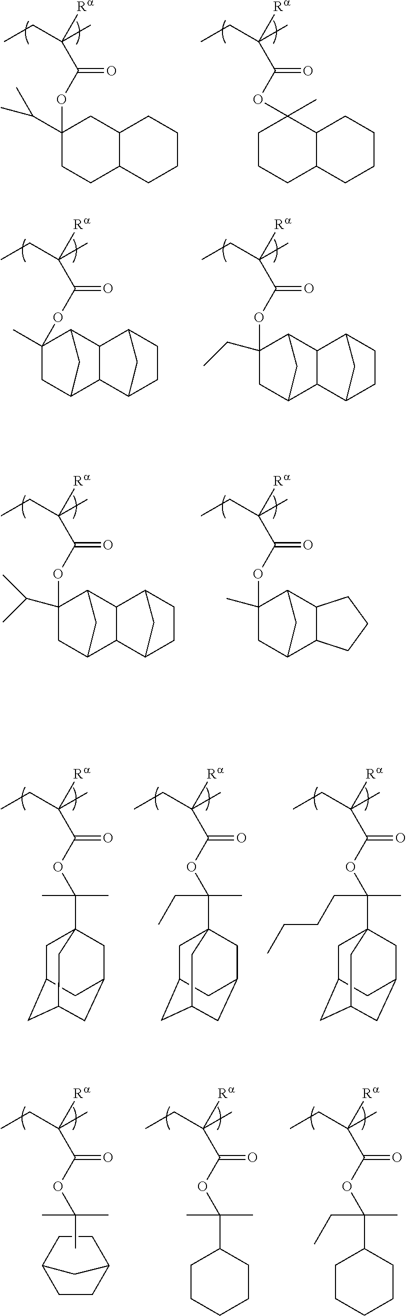

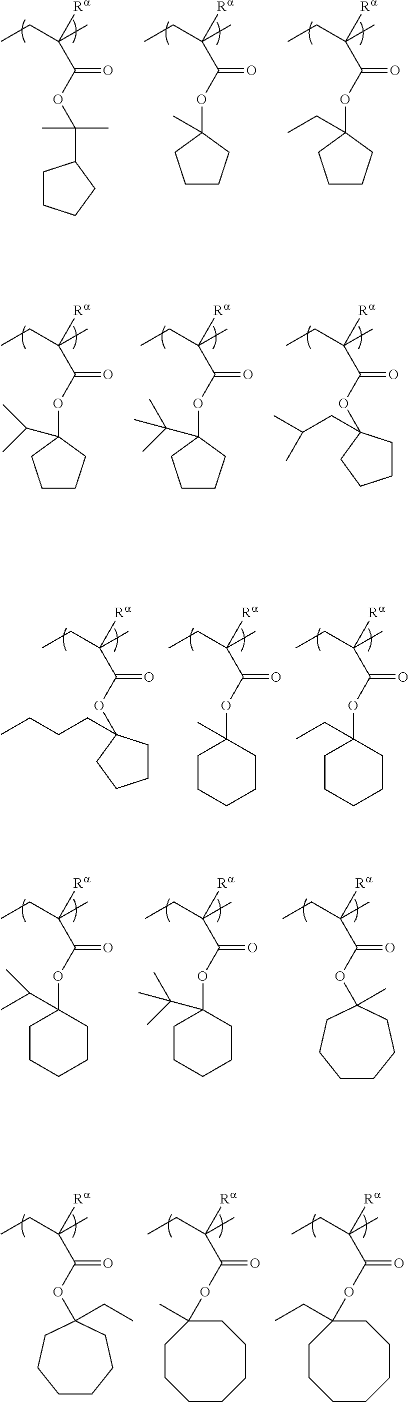

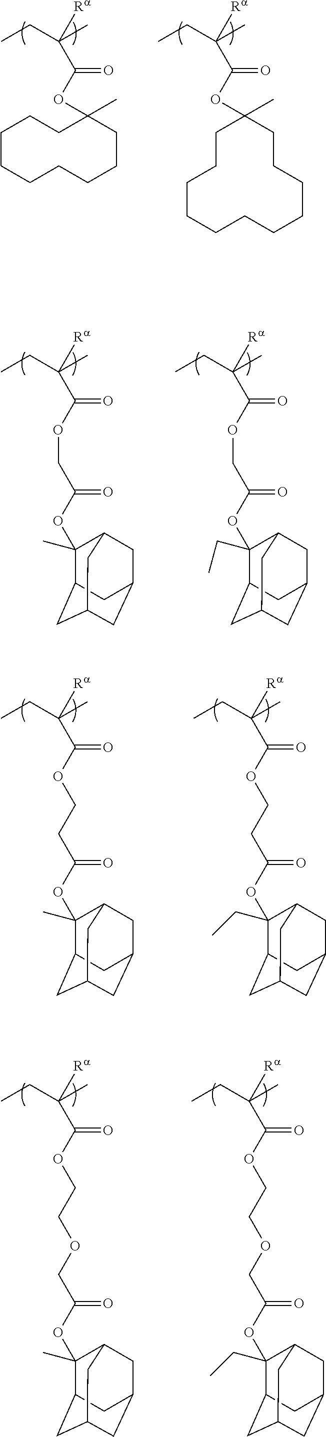

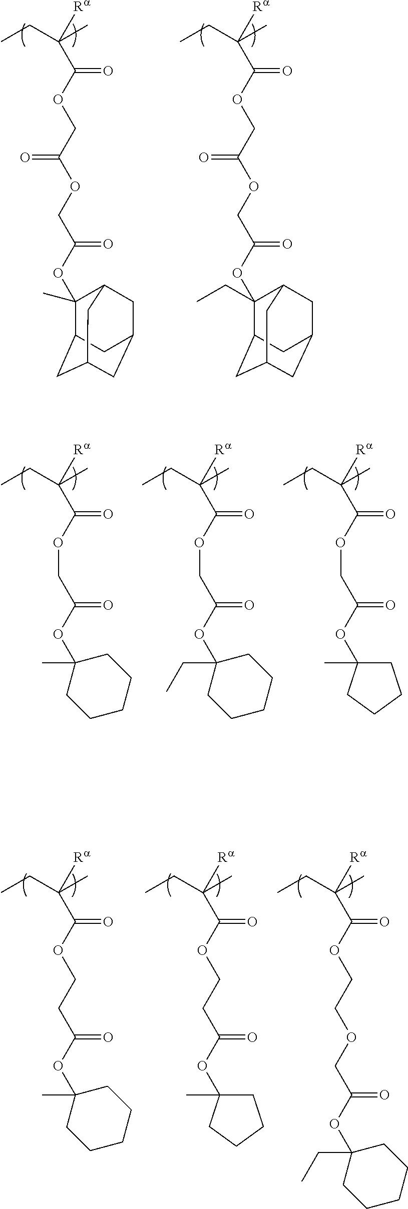

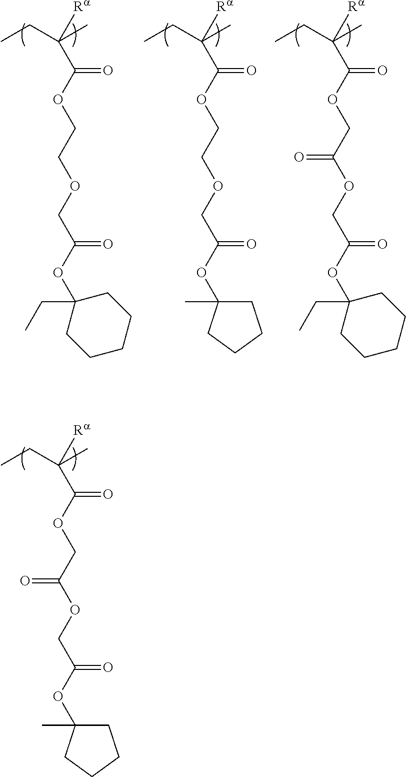

Hereinafter, specific examples of Formula (a1-2)″ are described.

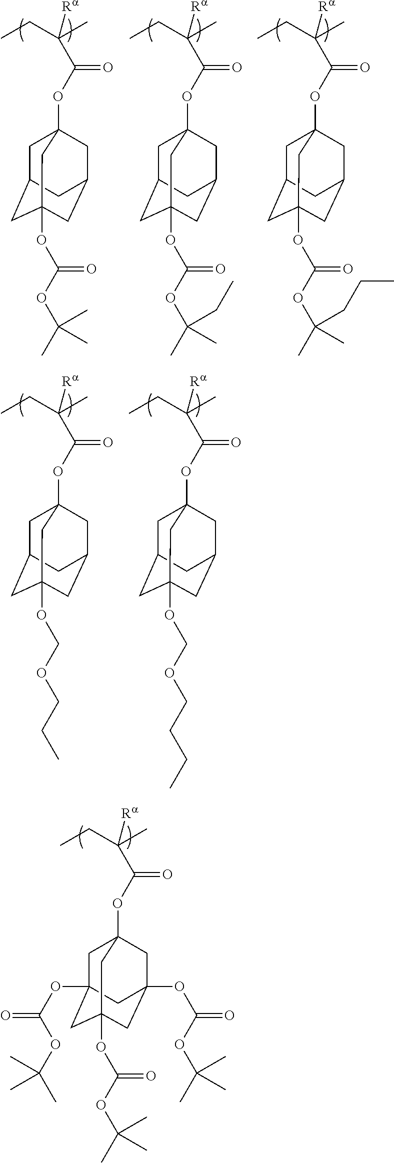

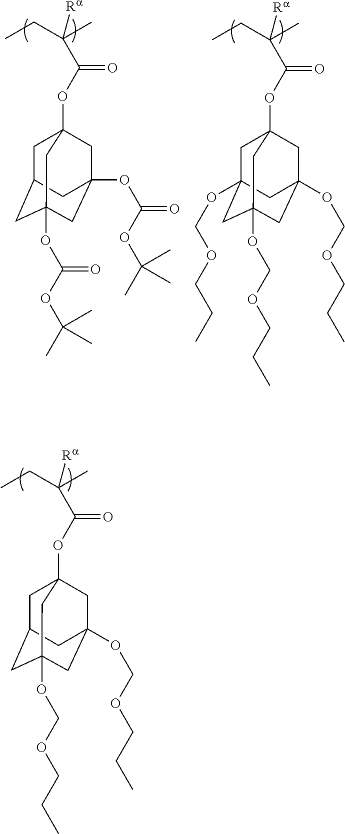

A proportion of constituent unit (a1)″ of ingredient (A2)″ is preferably 20 to 80 mol %, more preferably 20 to 75 mol %, most preferably 25 to 70 mol %, based on total constituent units constituting ingredient (A2)″. When constituent unit (a1)″ is included in the lowest proportion or more, lithographic characteristics such as sensitivity, resolution, and LWR are enhanced. In addition, when constituent unit (a1)″ is included at the highest proportion or less, balance with other constituent units may be provided.

Constituent Unit (a2)″

Constituent unit (a2)″ is a constituent unit that includes a cyclic group containing —SO₂—, a cyclic group containing carbonate, or a cyclic group containing —SO₂—.

When ingredient (A2)″ constituted of the —SO₂— containing cyclic group of constituent unit (a2)″ is used in forming a resist film, adhesion of the resist film to a substrate effectively increases.

In the present invention, ingredient (A2)″ preferably has constituent unit (a2)″.

In addition, when constituent unit (a1)″ includes the —SO₂— containing cyclic group in a structure thereof, a resultant constituent unit is considered as corresponding to constituent unit (a1)″, but not to constituent unit (a2)″, although the resultant unit corresponds to constituent unit (a2)″.

Constituent unit (a2)″ is preferably a constituent unit represented by Formula (a2-1)″ below:

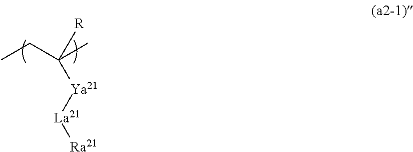

wherein R is a hydrogen atom, a C₁ to C₅ alkyl group, or a C₁ to C₅ halogenated alkyl group, Ya²¹ is a monovalent or divalent linking group, La²¹ is —O—, —COO—, —CON(R′)—, —OOO—, —CONHCO—, or —CONHCS—, and R′ represents a hydrogen atom or a methyl group. However, when La²¹ is —O—, Ya²¹ is not —CO—. Ra²¹ is a —SO₂— containing polycyclic group, a lactone-containing polycyclic group, or a carbonate-containing polycyclic group.

The divalent linking group of Ya²¹ is not specifically limited and is preferably a divalent hydrocarbon group that may include a substituent, a divalent linking group including a heteroatom, or the like.

(Divalent Hydrocarbon Group that May Include Substituent)

The hydrocarbon group as a divalent linking group may be an aliphatic hydrocarbon group or an aromatic hydrocarbon group.

The aliphatic hydrocarbon group is a non-aromatic hydrocarbon group. The aliphatic hydrocarbon group may be saturated or unsaturated. Generally, the aliphatic hydrocarbon group is preferably saturated.

The aliphatic hydrocarbon group may be a straight chain or branched aliphatic hydrocarbon group, an aliphatic hydrocarbon group including a ring in a structure thereof, or the like. Particularly, the aliphatic hydrocarbon group may be the exemplified group of Va¹ of the aforementioned Formula (a1-1)″.

The straight chain or branched aliphatic hydrocarbon group may or might not include a substituent. The substituent may be a fluorine atom, a C₁ to C₅ fluorinated alkyl group substituted with the fluorine atom, a carbonyl group, or the like.

The aliphatic hydrocarbon group including a ring in a structure thereof may include a substituent including a heteroatom in a ring structure thereof and may be a cyclic aliphatic hydrocarbon group (a group formed by removing two hydrogen atoms from an aliphatic hydrocarbon ring), a group formed by combining the cyclic aliphatic hydrocarbon group with a terminal of a straight chain or branched aliphatic hydrocarbon group, a group formed by inserting the cyclic aliphatic hydrocarbon group in the middle of a straight chain or branched aliphatic hydrocarbon group, or the like. Examples of the straight chain or branched aliphatic hydrocarbon group may be the same as the aforementioned examples.

The cyclic aliphatic hydrocarbon group has a carbon number of preferably 3 to 20, more preferably 3 to 12.

The cyclic aliphatic hydrocarbon group may be particularly the same as the exemplified group of Va¹ of Formula (a1-1)″ described above.

The cyclic aliphatic hydrocarbon group may or might not have a substituent. The substituent may be an alkyl group, an alkoxy group, a halogen atom, a halogenated alkyl group, a hydroxyl group, a carbonyl group, etc.

The alkyl group, as the substituent, is preferably a C₁ to C₅ alkyl group, most preferably a methyl group, an ethyl group, a propyl group, an n-butyl group, or a tert-butyl group.

The alkoxy group, as the substituent, is preferably a C₁ to C₅ alkoxy group, more preferably a methoxy group, an ethoxy group, an n-propoxy group, an iso-propoxy group, an n-butoxy group, or a tert-butoxy group, most preferably a methoxy group or an ethoxy group.

The halogen atom of the substituent may be a fluorine atom, a chlorine atom, a bromine atom, an iodine atom, or the like. Preferably, the halogen atom is a fluorine atom.

The halogenated alkyl group, as the substituent, may be a group formed by substituting a portion or all of hydrogen atoms of the alkyl group with the halogen atom.

A portion of the carbon atoms constituting a ring structure of the cyclic aliphatic hydrocarbon group may be substituted with a substituent including a heteroatom. The substituent including a heteroatom is preferably —O—, —C(═O)—O—, —S—, —S(═O)₂—, or —S(═O)₂—O—.

The aromatic hydrocarbon group, as the divalent hydrocarbon group, may be particularly the exemplified group of Va¹ of Formula (a1-1)″ described above.

A hydrogen atom of the aromatic hydrocarbon group may be substituted with a substituent. For example, a hydrogen atom coupled with an aromatic ring of the aromatic hydrocarbon group may be substituted with a substituent. The substituent may be, for example, an alkyl group, an alkoxy group, a halogen atom, a halogenated alkyl group, a hydroxyl group, etc.

The alkyl group, as the substituent, is preferably a C₁ to C₅ alkyl group, most preferably a methyl group, an ethyl group, a propyl group, an n-butyl group, or a tert-butyl group.

Examples of the alkoxy group, the halogen atom, and the halogenated alkyl group, as the substituent, may be the same as the examples of the substituent substituted for the hydrogen atom of the cyclic aliphatic hydrocarbon group.

(Divalent Linking Group Including Heteroatom)

In the divalent linking group including a heteroatom, the heteroatom is an atom other than a carbon atom and a hydrogen atom and may be, for example, an oxygen atom, a nitrogen atom, a sulfur atom, a halogen atom, or the like.

When Ya²¹ is a divalent linking group including a heteroatom, the divalent linking group may be preferably —O—, —C(═O)—O—, —C(═O)—, —O—C(═O)—O—, —C(═O)—NH—, —NH—, —NH—C(═NH)— (H may be substituted with a substituent such as an alkyl group, or an acyl group), —S—, —S(═O)₂—, —S(═O)₂—O—, a group represented by Formula —Y²¹—O—Y²²—, —Y²¹—O—, —Y²¹—C(═O)—O—, —C(═O)—O—Y²¹—, —[Y²¹—C(═O)—O]ₘ—Y²²—, —Y²¹—O—C(═O)—Y²²—, or the like, wherein Y²¹ and Y²² are each independently a divalent hydrocarbon group that may include a substituent, O is an oxygen atom, and m′ is an integer of 0 to 3.

When the divalent linking group including heteroatom is —C(═O)—NH—, —NH—, or —NH—C(═NH)—, H may be substituted with a substituent such as an alkyl group or an acyl group. The substituent (alkyl group, acyl group, etc.) has a carbon number of preferably 1 to 10, more preferably 1 to 8, particularly preferably 1 to 5.

Y²¹ and Y²² of Formula —Y²¹—O—Y²²—, —Y²¹—O—, —Y²¹—C(═O)—O—, —C(═O)—O—Y²¹—, —[Y²¹—C(═O)—O]ₘ—Y²²—, or —Y²¹—O—C(═O)—Y²²— are each independently a divalent hydrocarbon group that may include a substituent. Examples of the divalent hydrocarbon group may be the same as the examples of the “divalent hydrocarbon group that may include substituent” exemplified to describe the divalent linking group.

Y²¹ is preferably a straight chain aliphatic hydrocarbon group, more preferably a straight chain alkylene group, even more preferably a C₁ to C₅ straight chain alkylene group, particularly preferably a methylene group or an ethylene group.

Y²² is preferably a straight chain or branched aliphatic hydrocarbon group, more preferably a methylene group, an ethylene group, or an alkyl methylene group. An alkyl group of the alkyl methylene group is preferably a C₁ to C₅ straight chain alkyl group, more preferably a C₁ to C₃ straight chain alkyl group, most preferably a methyl group.

With regard to a group represented by Formula —[Y²¹—C(═O)—O]ₘ—Y²²—, m′ is an integer of 0 to 3, preferably an integer of 0 to 2, more preferably 0 or 1, particularly preferably 1. In other words, the group represented by Formula —[Y²¹—C (═O)—O]ₘ—Y²²— is particularly preferably a group represented by Formula —Y²¹—C (═O)—O—Y²²—. Thereamong, a group represented by Formula —(CH₂)_{a′}—C(═O)—O—(CH₂)_{b′}— is preferred. Here, a′ is an integer of 1 to 10, preferably 1 to 8, more preferably 1 to 5, even more preferably 1 or 2, most preferably 1. In addition, b′ is an integer of 1 to 10, preferably 1 to 8, more preferably 1 to 5, even more preferably 1 or 2, most preferably 1.

In the present invention, Ya²¹ is preferably a single bond, or an ester bond [—C(═O)—O—], an ether linkage (—O—), a straight chain or branched alkylene group, or a combination thereof.

Ra²¹ of Formula (a2-1)″ is a cyclic group containing —SO₂—.

The term “cyclic group containing —SO₂—” refers to a cyclic group that has a ring including —SO₂— in a structure thereof. Particularly, a sulfur atom (S) in —SO₂— forms a portion of a ring backbone of the cyclic group. When the cyclic group has only the ring including —SO₂— in a backbone thereof, the cyclic group is a monocyclic group. When the cyclic group additionally has another ring structure, the cyclic group is called a polycyclic group, regardless of a structure thereof. The —SO₂— containing cyclic group may be monocyclic or polycyclic.

In particular, the —SO₂— containing cyclic group, as a cyclic hydrocarbon group, of R¹ is preferably a cyclic group including —O—SO₂— in a ring backbone thereof, i.e., a polycyclic group including a sultone ring, —O—S— of —O—SO₂— forms a portion of a ring backbone of which. The —SO₂— containing polycyclic group is more particularly groups represented by Formulas (a5-r-1)″ to (a5-r-4)″ below:

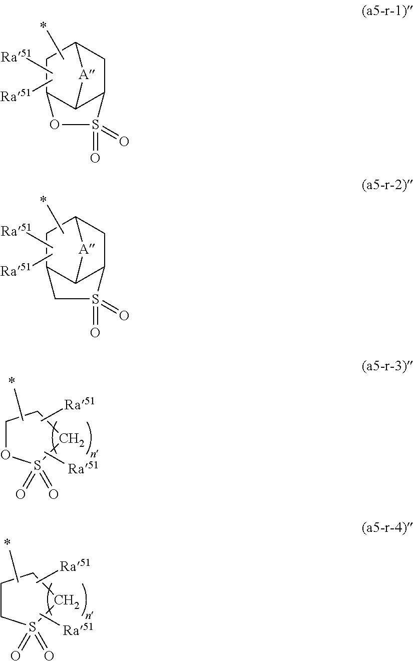

wherein Ra^{′51} is each independently a hydrogen atom, an alkyl group, an alkoxy group, a halogen atom, a halogenated alkyl group, a hydroxyl group, —COOR″, —OC(═O)R″, a hydroxyalkyl group, or a cyano group, R″ is a hydrogen atom or an alkyl group, A″ is a C₁ to C₅ alkylene group that may include an oxygen atom or a sulfur atom, an oxygen atom, or sulfur atom, and n′ is an integer of 0 to 2.

A″ of Formulas (a5-r-1)″ to (a5-r-4)″ is the same as A″ of Formulas (a2-r-1)″ to (a2-r-7)″ described below. Examples of an alkyl group, an alkoxy group, a halogen atom, a halogenated alkyl group, —COOR″, —OC(═O)R″, and a hydroxyalkyl group of Ra^{′51} are the same as the examples of Ra^{′21} of Formulas (a2-r-1)″ to (a2-r-7)″ described below.

Hereinafter, specific examples of groups represented by Formulas (a5-r-1)″ to (a5-r-4)″ are described. In the formulas, the term “Ac” refers to an acetyl group.

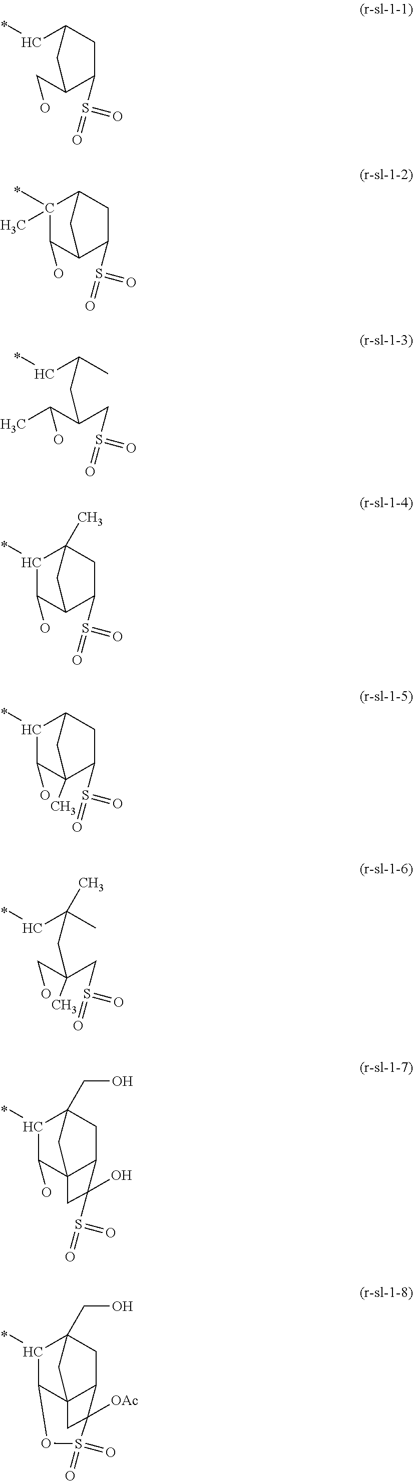

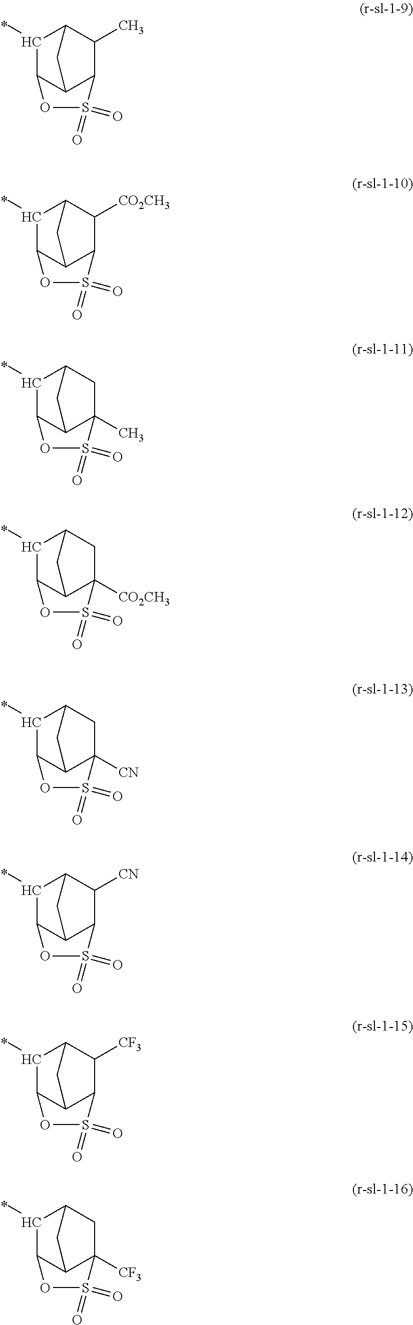

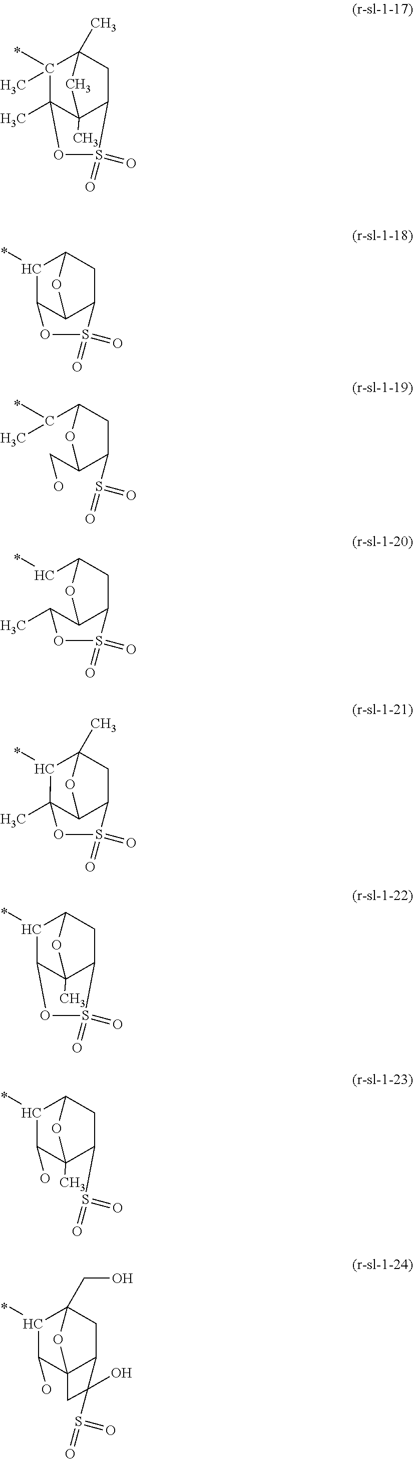

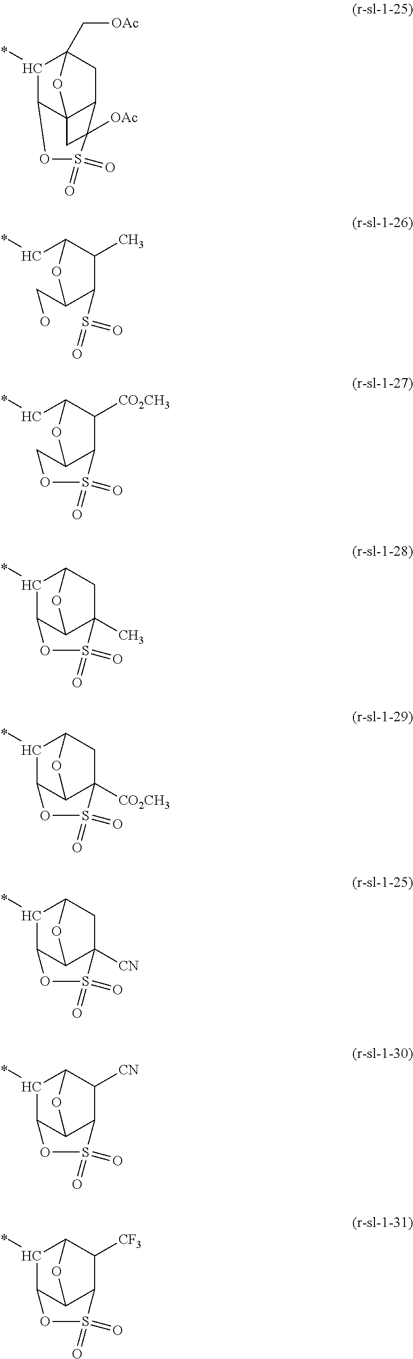

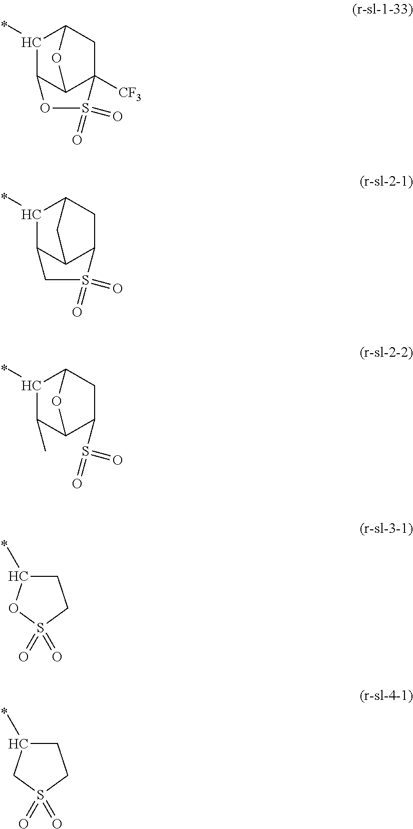

The —SO₂— containing cyclic group is preferably a group represented by Formula (a5-r-1)″, more preferably at least one selected from groups represented by Formulas (r-sl-1-1), (r-sl-1-18), (r-sl-3-1), and (r-sl-4-1), most preferably a group represented by Formula (r-sl-1-1), among the formulas.

The term “lactone-containing cyclic group” refers to a cyclic group that includes a ring (lactone ring) including —O—C(═O)— in a backbone thereof. When the lactone-containing cyclic group includes only lactone ring, it is called a monocyclic group. When the lactone-containing cyclic group additionally includes another ring structure, it is called a polycyclic group, regardless of structure. The lactone-containing cyclic group may be monocyclic or polycyclic.

The lactone-containing cyclic group, as a cyclic hydrocarbon group, of R¹ is not specifically limited and may be randomly selected. Particularly, groups represented by Formulas (a2-r-1)″ to (a2-r-7)″ below may be used. Hereinafter, the symbol ┌*┘ represents a dangling bond.

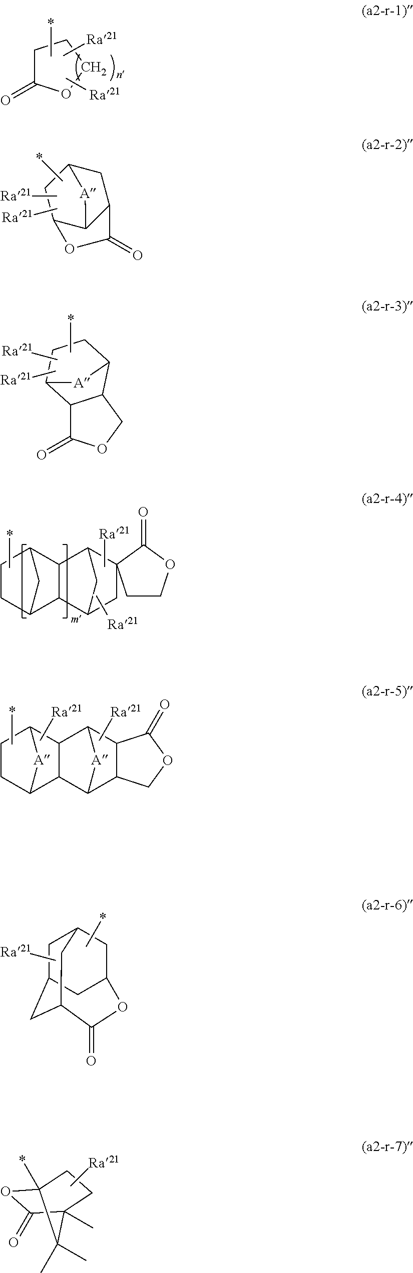

wherein each of a plurality of Ra′²¹ is independently a hydrogen atom, an alkyl group, an alkoxy group, a halogen atom, a halogenated alkyl group, a hydroxyl group, —COOR″, —OC(═O)R″, a hydroxyalkyl group, or a cyano group; R″ is a hydrogen atom or an alkyl group; A″ is a C₁ to C₅ alkylene group that may include an oxygen atom or a sulfur atom, an oxygen atom, or a sulfur atom; and m′ is 0 or 1.

A″ of Formulas (a2-r-1)″ to (a2-r-7)″ is a C₁ to C₅ alkylene group that may include an oxygen atom or a sulfur atom, an oxygen atom, or a sulfur atom. The C₁ to C₅ alkylene group of A″ is preferably a straight chain or branched alkylene group and may be a methylene group, an ethylene group, an n-propylene group, an isopropylene group, or the like. When the alkylene group includes an oxygen atom or a sulfur atom, specific examples of the oxygen or sulfur atom-including alkylene group include a group formed by locating —O— or —S— at a terminal or between carbon atoms of an alkylene group. The oxygen or sulfur atom-including alkylene group may be for example, —O—CH₂—, —CH₂—O—CH₂—, —S—CH₂—, —CH₂—S—CH₂—, or the like. A″ is preferably a C₁ to C₅ alkylene group or —O—, more preferably a C₁ to C₅ alkylene group, most preferably a methylene group. Each of the plurality of Ra′²¹ is independently a hydrogen atom, an alkyl group, an alkoxy group, a halogen atom, a halogenated alkyl group, —COOR″, —OC(═O)R″, a hydroxyalkyl group, or a cyano group.

The alkyl group of Ra^{′21} is preferably a C₁ to C₅ alkyl group.

The alkoxy group Ra^{′21} is preferably a C₁ to C₆ alkoxy group.

The alkoxy group is preferably a straight chain type or a branched chain type. Particularly, the alkoxy group may be a group formed by coupling the alkyl group of Ra^{′21} with an oxygen atom (—O—).

The halogen atom of Ra′²¹ may be a fluorine atom, a chlorine atom, a bromine atom, an iodine atom, or the like. Preferably, the halogen atom is a fluorine atom.

The halogenated alkyl group of Ra′²¹ may be a group formed by substituting a portion or all of hydrogen atoms of the alkyl group of Ra′²¹ with the halogen atom. The halogenated alkyl group is preferably a fluorinated alkyl group, particularly preferably a perfluoroalkyl group.

Hereinafter, specific examples of groups represented by Formulas (a2-r-1)″ to (a2-r-7)″ are shown:

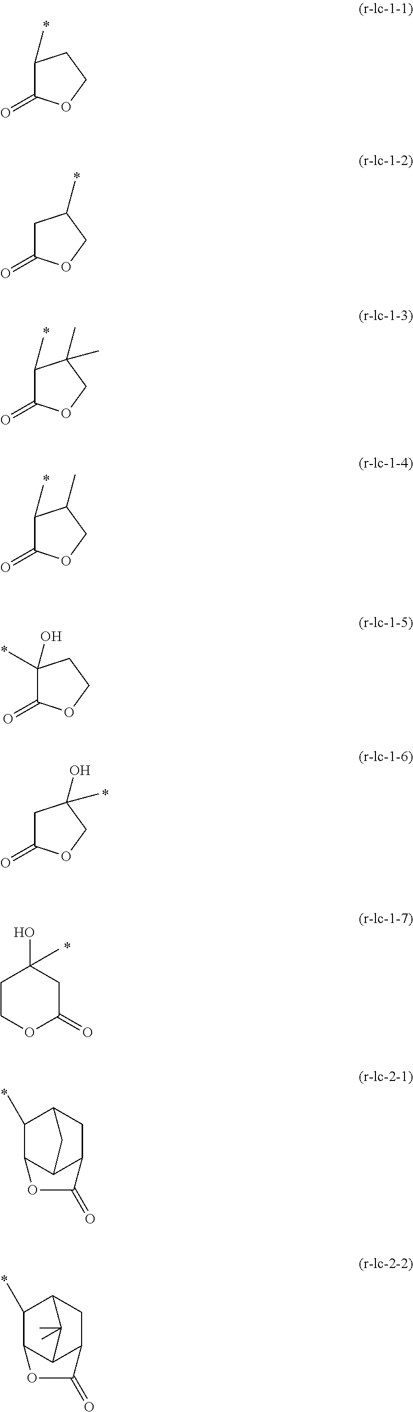

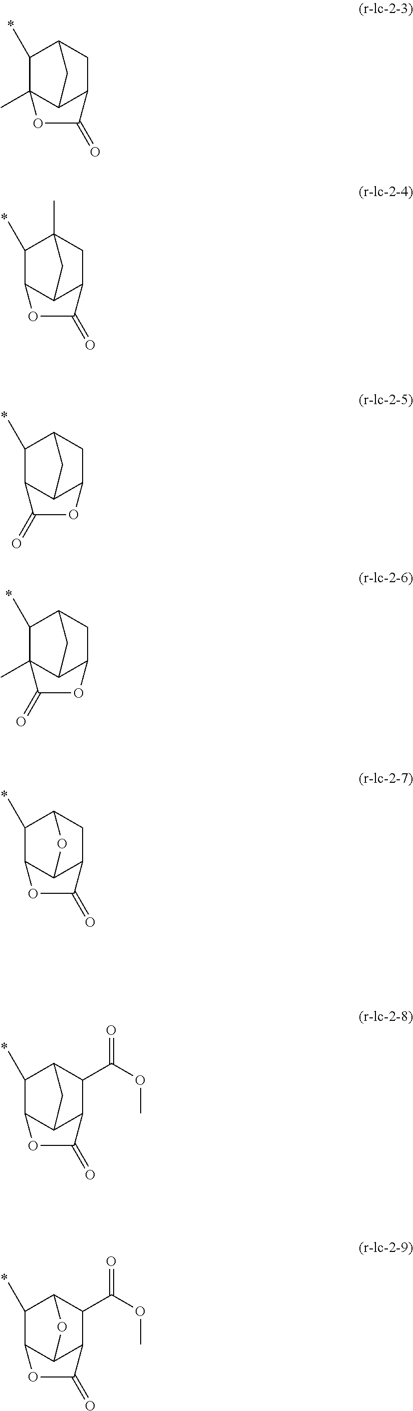

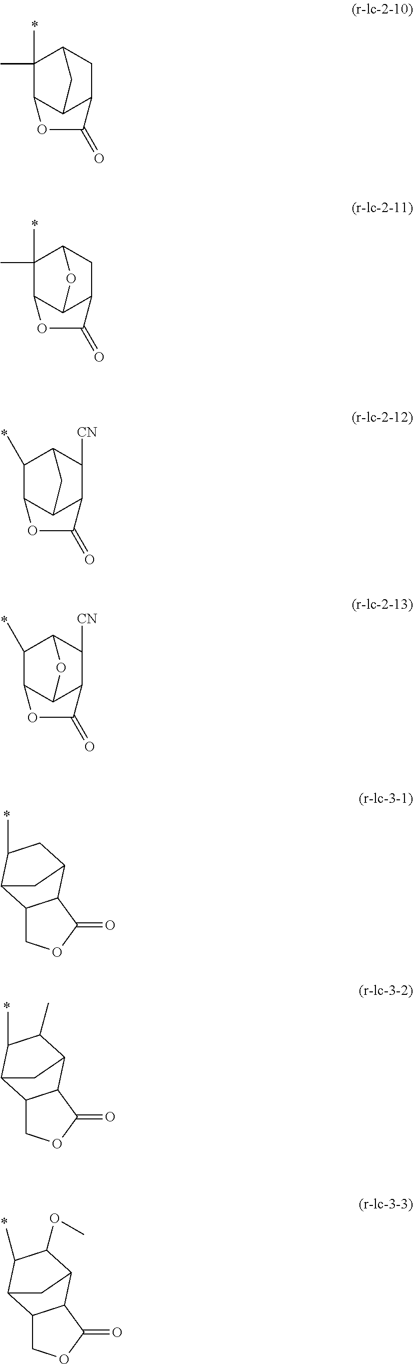

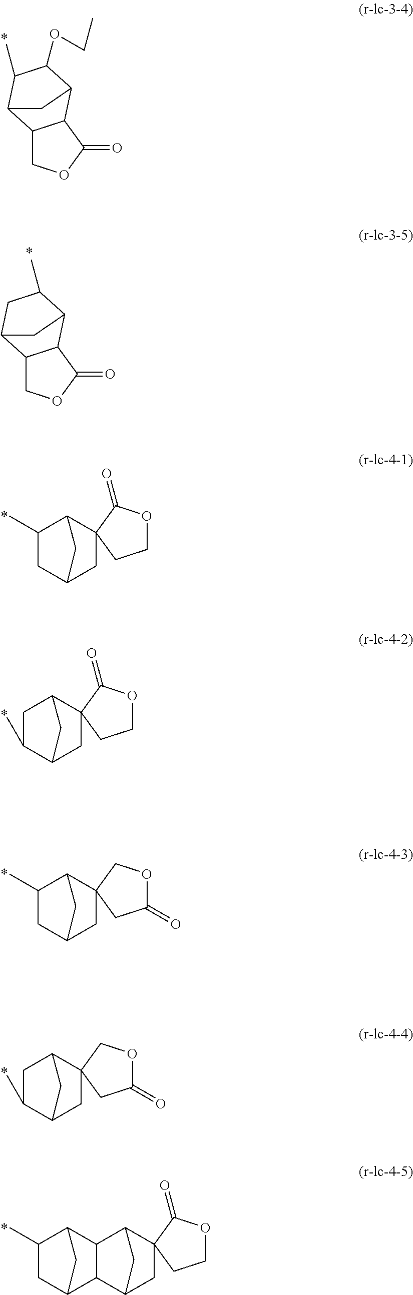

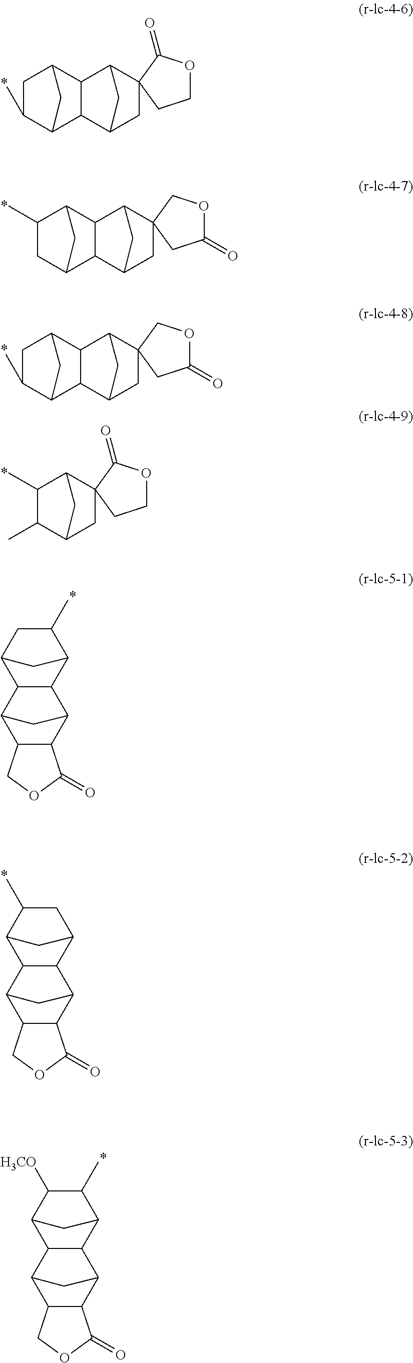

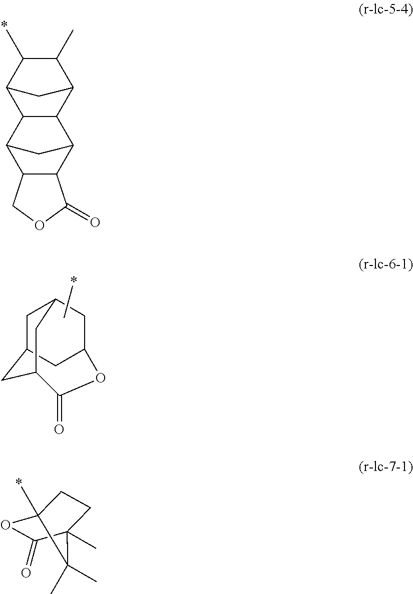

The term “carbonate-containing cyclic group” refers to a cyclic group that includes a ring (carbonate ring) including —O—C(═O)—O— in a backbone thereof. When the carbonate-containing cyclic group includes only the carbonate ring, it is called a monocyclic group. When the carbonate-containing cyclic group additionally includes another ring structure, it is called a polycyclic group, regardless of structure. The carbonate-containing cyclic group may be monocyclic or polycyclic.

The carbonate-containing cyclic group of R¹ is not specifically limited and may be randomly selected. Particularly, groups represented by Formulas (ax3-r-1)″ to (ax3-r-3)″ below may be used.

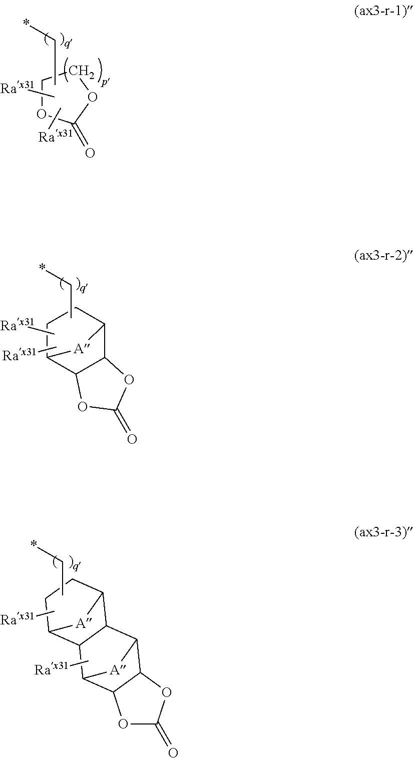

wherein each of a plurality of Ra^{′x31} is independently a hydrogen atom, an alkyl group, an alkoxy group, a halogen atom, a halogenated alkyl group, a hydroxyl group, —COOR″, —OC(═O)R″, a hydroxyalkyl group, or a cyano group; R″ is a hydrogen atom or an alkyl group; A″ is a C₁ to C₅ alkylene group that may include an oxygen atom or a sulfur atom, an oxygen atom, or a sulfur atom; and q′ is 0 or 1.

A″ of Formulas (ax3-r-1)″ to (ax3-r-3)″ is the same as A″ of Formula (a2-r-1)″.

Examples of each of an alkyl group, an alkoxy group, a halogen atom, a halogenated alkyl group, —COOR″, —OC(═O)R″, and a hydroxyalkyl group of Ra′³¹ may be the same as the examples of Ra′²¹ of Formulas (a2-r-1)″ to (a2-r-7)″.

Hereinafter, specific examples of groups represented by Formulas (ax3-r-1)″ to (ax3-r-3)″ are shown.

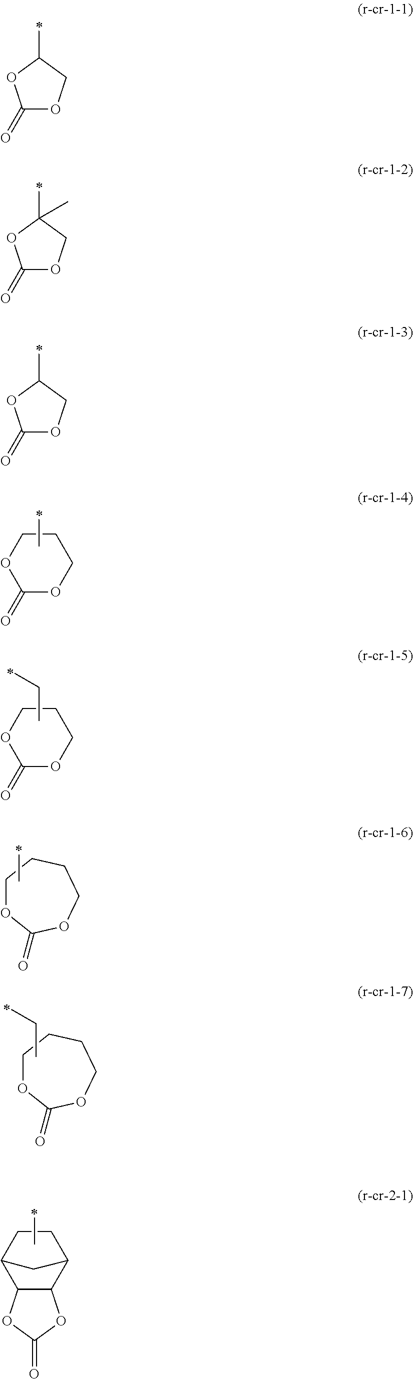

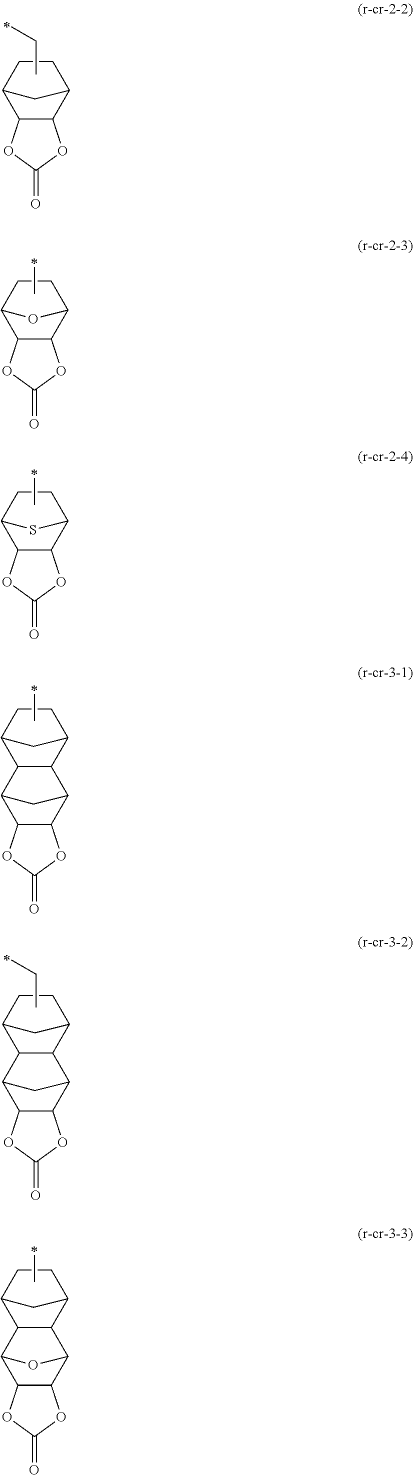

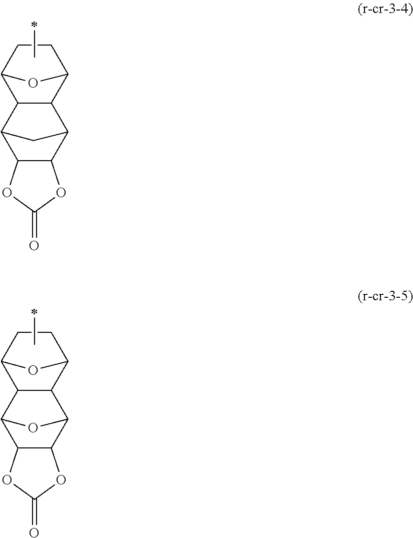

Thereamong, the lactone-containing cyclic group is preferably a group represented by Formula (a2-r-1)″ or (a2-r-2)″, more preferably a group represented by Formula (r-1c-1-1).

Constituent unit (a2)″ of ingredient (A2)″ may be one or more types.

When ingredient (A2)″ has a constituent unit (a2)″, a proportion of constituent unit (a2)″ based on total constituent units constituting ingredient (A2)″ is preferably 1 to 80 mol %, more preferably 5 to 70 mol %, even more preferably 10 to 65 mol %, particularly preferably 0 to 60 mol %. When the ratio is the lowest amount or more, effects due to inclusion of constituent unit (a2)″ may be sufficiently provided. When the ratio is the highest amount or less, balance with other constituent units may be provided and a variety of lithographic characteristics and patterns are satisfactorily accomplished.

Constituent Unit (a3)″

Constituent unit (a3)″ is a constituent unit including a polar group-containing aliphatic hydrocarbon group (excluding those corresponding to the aforementioned constituent units (a1)″ and (a2)″).

When ingredient (A2)″ has constituent unit (a3)″, hydrophilicity of ingredient (A2)″ may increase and resolution may increase.

The polar group may be a hydroxyl group, a cyano group, a carboxyl group, or a hydroxylalkyl group formed by substituting some hydrogen atoms of an alkyl group with fluorine atoms, or the like. In particular, the hydroxyl group is preferred.

The aliphatic hydrocarbon group may be a C₁ to C₁₀ straight chain or branched hydrocarbon group (preferably alkylene group) or a cyclic aliphatic hydrocarbon group (cyclic group). The cyclic group may be monocyclic or polycyclic and may be suitably selected from, for example, groups generally used in resins of resist compositions for ArF excimer lasers. The cyclic group is preferably a polycyclic group, more preferably a polycyclic group having a carbon number of 7 to 30.

Thereamong, a constituent unit derived from an acrylic ester that includes an aliphatic polycyclic group containing a hydroxyl group, a cyano group, a carboxyl group, or a hydroxyalkyl group formed by substituting some hydrogen atoms of an alkyl group with a fluorine atom is more preferred. The polycyclic group may be a group formed by removing two or more hydrogen atoms from bicycloalkane, tricycloalkane, tetracycloalkane, or the like. Particularly, the polycyclic group may be a group formed by removing two or more hydrogen atoms from polycycloalkane such as adamantane, norbomane, isobomane, tricyclodecane, or tetracyclododecane, etc. Among these polycyclic groups, a group formed by removing two or more hydrogen atoms from adamantane, a group formed by removing two or more hydrogen atoms from norbomane, and a group formed by removing two or more hydrogen atoms from tetracyclododecane are industrially preferred.

Constituent unit (a3)″ is not specifically limited so long as it includes a polar group-containing aliphatic hydrocarbon group and may be randomly selected.

Constituent unit (a3)″ is preferably a constituent unit including the polar group-containing aliphatic hydrocarbon group which is a constituent unit derived from acrylic ester, a hydrogen atom coupled with a carbon atom at an α position of which may be substituted with a substituent.

When a hydrocarbon group of the polar group-containing aliphatic hydrocarbon group is a C₁ to C₁₀ straight chain or branched hydrocarbon group, constituent unit (a3)″ is preferably a constituent unit derived from hydroxyethylester of acrylic acid. When the hydrocarbon group is a polycyclic group, constituent unit (a3)″ is preferably a constituent unit represented by Formula (a3-1)″ below, a constituent unit represented by Formula (a3-2)″ below, or a constituent unit represented by Formula (a3-3)″:

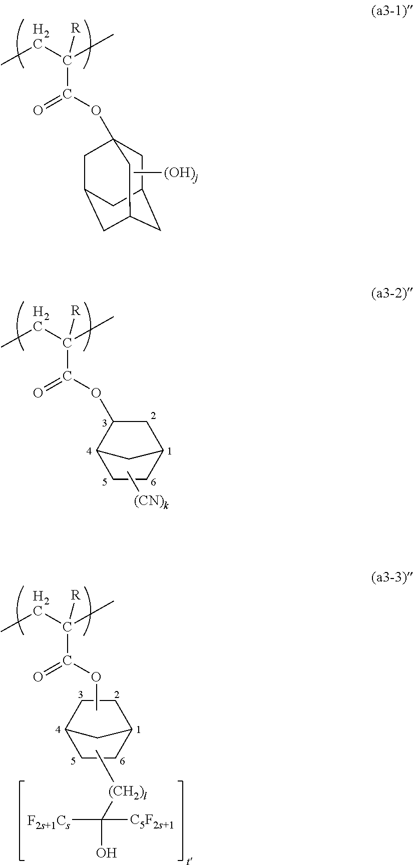

wherein R is the same as that of Formula (a1-1)″, j is an integer of 1 to 3, k is an integer of 1 to 3, t′ is an integer of 1 to 3, 1 is an integer of 1 to 5, and s is an integer of 1 to 3.

j of Formula (a3-1)″ is preferably 1 or 2, more preferably 1. When j is 2, the hydroxyl group is preferably bonded to the C-3 and C-5 positions of the adamantyl group. When j is 1, a hydroxyl group is preferably bonded to the C-3 position of the adamantyl group.

j is preferably 1. Particularly preferably, a hydroxyl group is bonded to the C-3 position of the adamantyl group.

In Formula (a3-2)″, k is preferably 1. The cyano group is preferably bonded to the C-5 and C-6 positions of a norbomyl group.

In Formula (a3-3)″, t′ is preferably 1. 1 is preferably 1. s is preferably 1. 2-norbomyl group or a 3-norbomyl group is preferably bonded to a terminal of a carboxyl group of acrylic acid thereof. A fluorinated alkyl alcohol is preferably bonded to the C-5 or C-6 position of the norbomyl group.

Constituent unit (a3)″ included in ingredient (A2)″ may be one or more types.

When ingredient (A2)″ has constituent unit (a3)″, a ratio of constituent unit (a3)″ based on total constituent units constituting ingredient (A2)″ is preferably 5 to 50 mol %, more preferably 5 to 40 mol %, even more preferably 5 to 25 mol %.

When the proportion of constituent unit (a3)″ is equal to or greater than the lowest amount, effects due to inclusion of constituent unit (a3)″ are sufficient.

When the proportion is equal to or less than the highest amount, balance with other constituent units is easily provided.

Constituent Unit (a4)″

Constituent unit (a4)″ is a constituent unit including an acid-non-dissociative cyclic group. When ingredient (A2)″ has constituent unit (a4)″, dry etching resistance of a formed resist pattern improves. In addition, hydrophobicity of ingredient A increases. Increased hydrophobicity is considered to contribute to the enhancement of resolution, a resist pattern, etc. particularly in a solvent development process.

In constituent unit (a4)″, the term “acid-non-dissociative cyclic group” refers to a cyclic group that is not dissociated despite the action of an acid generated from the following ingredient B by exposure and remains intact in the constituent unit.

Constituent unit (a4)″ is preferably, for example, a constituent unit derived from acrylic ester including the acid-non-dissociative aliphatic cyclic group, or the like. Examples of the cyclic group may be the same as the examples of constituent unit (a1)″. In addition, the cyclic group may be a conventionally known group generally used in a resin ingredient of a resist composition for ArF excimer lasers, KrF excimer lasers, or the like.

In particular, at least one polycyclic group selected among from a tricyclodecyl group, an adamantyl group, a tetracyclododecyl group, an isobornyl group, and a norbomyl group is preferred since they are readily available industrially. The polycyclic groups may have a C₁ to C₅ straight chain or branched alkyl group as a substituent.

Examples of constituent unit (a4)″ particularly include structures represented by Formulas (a4-1)″ to (a4-7)″ below:

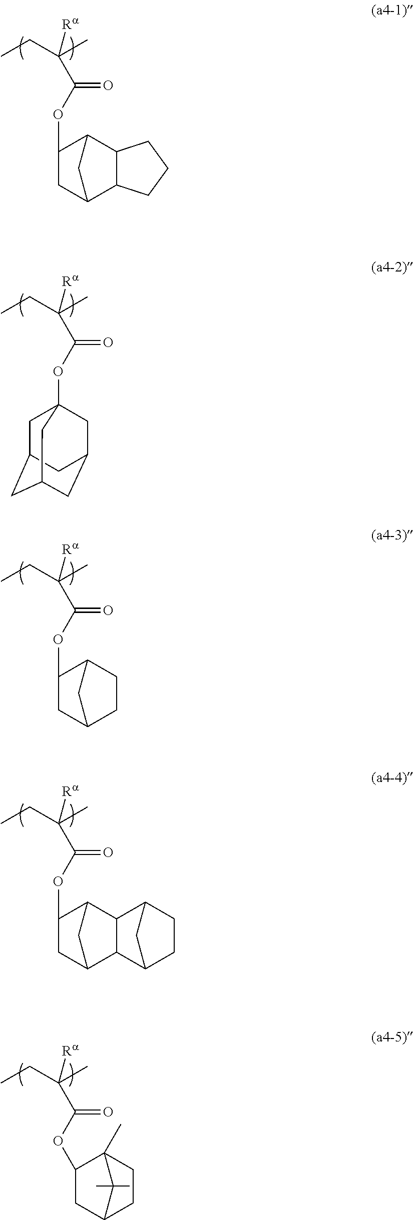

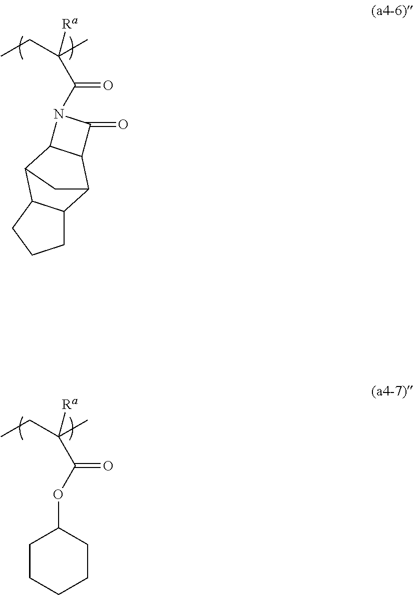

wherein R^{α} represents a hydrogen atom, a methyl group, or a trifluoromethyl group.

Constituent unit (a4)″ included in ingredient (A2)″ may be one or more types.

When constituent unit (a4)″ is included in ingredient (A2)″, a proportion of constituent unit (a4)″ based on the sum of total constituent units constituting ingredient (A2)″ is preferably 1 to 30 mol %, more preferably 10 to 20 mol %.

Ingredient (A2)″ may be a copolymer formed by randomly combining constituent units (a1)″ to (a4)″.

Ingredient (A2)″ may be obtained by polymerizing, e.g., performing a publicly known radical polymerization with a radical polymerization initiator such as azobisisobutyronitrile (AIBN) or dimethyl azobisisobutyrate, monomers from which every constituent unit is derived.

In addition, a —C(CF₃)₂—OH group may be introduced to a terminal of ingredient (A2)″ using a chain-transfer agent such as, for example, HS—CH₂—CH₂—CH₂—C(CF₃)₂—OH along with the radical polymerization initiator during polymerization. As such, a copolymer including a hydroxyalkyl group formed by substituting some hydrogen atoms of an alkyl group with fluorine atoms is effective in reducing defective development or LER (line edge roughness: non-uniform roughness on side walls of lines).

In the present invention, the mass-average molecular weight (Mw) (calibrated with polystyrene through gel permeation chromatography (GPC)) of ingredient (A2)″, which is not specifically limited, is preferably 1000 to 50000, more preferably 1500 to 30000, most preferably 2000 to 20000. When Mw of ingredient (A2)″ is equal to or less than the highest value, it has sufficient solubility in a resist solvent for use as a resist and may lower the viscosity of a composition. When Mw of ingredient (A2)″ is equal to or higher than the lowest value, satisfactory dry etching resistance or a satisfactory cross-section shape of a resist pattern is provided.

Ingredient (A2)″ may be one type or a combination of two or more types.

A proportion of ingredient (A2)″ in substrate ingredient (A) is preferably 25% by mass or more, more preferably 50% by mass or more, even more preferably 75% by mass or more, based on the total mass of substrate ingredient A. Alternatively, the proportion may be 100% by mass. When the proportion is 25% by mass or more, lithographic characteristics are further enhanced.

In the resist composition of the present invention, ingredient A may be only one type or a combination of two or more types.

In the resist composition of the present invention, a resin or the content of ingredient A may be controlled depending upon required characteristics of a resist to be formed. However, the resin is preferably a polyhydroxystyrene resin.

<Organic Solvent: Ingredient S>

The chemical for photolithography of the present invention includes organic solvent S having a saturated vapor pressure of 1 kPa or more (1 atm, 20° C.) and a viscosity of 1.1 cP (1 atm, 20° C.) or less. A saturated vapor pressure of organic solvent S is a saturated vapor pressure of exclusively solvent (S) in the chemical or the composition containing the chemical and refers to a saturated vapor pressure at 1 atm, 20° C. The saturated vapor pressure of organic solvent S may be measured according to a publicly known method and a published value under the same measurement conditions may be used. In addition, when organic solvent S is a mixture of two or more organic solvents, the mixed organic solvent S is applicable if a total saturated vapor pressure of the mixture is 1 kPa or more (1 atm, 20° C.) although a saturated vapor pressure of one ingredient of the mixture is 1 kPa (1 atm, 20° C.) or less. The saturated vapor pressure of the mixed organic solvent S may be measured according to a publicly known method or calculated as a theoretical value according to the Raoult's law, as follows:

Pₜₒₜₐₗ=P_{A0}×X_{A}+P_{B0}×X_{B}+ . . . +P_{N0}×X_{N}

wherein Pₜₒₜₐₗ=saturated vapor pressure of total solvents (1 atm, 20′C); P_{A0}=saturated vapor pressure of organic solvent A (1 atm, 20° C.); P_{B0}=saturated vapor pressure of organic solvent B (1 atm, 20° C.); P_{N0}=saturated vapor pressure of organic solvent N (1 atm, 20° C.); X_{A}=molar fraction of organic solvent A; X_{B}=molar fraction of organic solvent B; and X_{N}=molar fraction of organic solvent N.

The viscosity of organic solvent S is 1.1 cP or less at 1 atm, 20° C. The viscosity of organic solvent S may be measured according to a publicly known measurement device, such as, for example, a Cannon Fenske viscometer, and a publicly known measurement method. In addition, the viscosity of organic solvent S refers to the viscosity of only organic solvent S. When organic solvent S is a mixture of two or more organic solvents, the viscosity thereof refers to the viscosity of the mixed organic solvents. In this case, if the total viscosity of the organic solvent S mixture is 1.1 cP (1 atm, 20° C.) or less although the viscosity of one ingredient of organic solvent S is 1.1 cP (1 atm, 20° C.) or more, the mixture is applicable.

So as to form the chemical for photolithography or the photoresist composition as a thick film having a thickness of 5 μm or more, a solid concentration of the chemical or the composition should be increased. In this case, the viscosity of the chemical or the composition may be easily increased. However, since a load applied during liquid transfer becomes excessive with increasing viscosity of the chemical or the composition, application thereof to existing pressure feed equipment is impossible and thus specific equipment is required. Alternatively, problems in processing such as pressure load during liquid transfer or increased liquid transfer time may occur. In particular, when a film is formed on a substrate through spin coating, it may be difficult to uniformly diffuse the chemical or the composition on a substrate, which impairs the formation of a film with a uniform thickness, if the viscosity of the chemical for photolithography or the photoresist composition is high. When the viscosity of the chemical or the composition is lowered by adjusting a solid concentration in order to prevent this, it may be difficult to form a film to a desired thickness.

However, when organic solvent S included in the chemical for photolithography or the photoresist composition has a saturated vapor pressure of 1 kPa or more (1 atm, 20° C.) and a viscosity of 1.1 cP (1 atm, 20° C.) or less as in the present invention, a thick film having a desired sufficient thickness may be formed even while enhancing liquid transfer property by lowering the overall viscosity of the composition such that the composition may be used in existing equipment. Particularly, by using the chemical for photolithography of the present invention and the resist composition including the same, a thick film having a uniform thickness of 5 μm or more may be formed while lowering the viscosity of the chemical and the resist composition to 130 cP or less.

Without being bound to a specific theory, the present inventors understand that, since a portion of a coated chemical is evaporated during spinning of a substrate when a film is formed on the substrate through spin coating, the viscosity of the coated chemical increases during spinning when a solvent having a high saturated vapor pressure of 1 kPa or more (1 atm, 20° C.) is used, thereby obtaining a thick film.

In the present invention, organic solvent S is not specifically limited so long as it has the aforementioned saturated vapor pressure and viscosity. When the mixed organic solvent S is used, the mixed organic solvent S is not specifically limited so long as a total of the mixed organic solvent S has the aforementioned saturated vapor pressure and viscosity although a portion of organic solvents constituting the mixed organic solvent S does not have the aforementioned saturated vapor pressure and viscosity.

Examples of organic solvent S having the aforementioned saturated vapor pressure and viscosity which may be used in the chemical for photolithography and the resist composition including the same include aromatic solvents such as toluene; halogenated aromatic solvents such as chlorobenzene; ketones such as methylbutylketone; ester based solvents such as butyl acetate and propyl acetate; and the like. Thereamong, ketones and ester based solvents are preferred, and ester based solvents are particularly preferred.

In addition, organic solvent S of the chemical for photolithography of the present invention and the resist composition including the same may be suitably selected from, other than organic solvents having the aforementioned saturated vapor pressure and viscosity, publicly known solvents for chemically amplified resist compositions. A saturated vapor pressure of the selected organic solvent S is controlled to 1 kPa or more (1 atm, 20° C.) and the viscosity thereof is controlled to 1.1 cP (1 atm, 20° C.) or less.

For example, the organic solvent S may be lactone such as γ-butyrolactone; a ketone based solvent such as acetone, methylethylketone, cyclohexanone, methyl-n-pentylketone, methylisopentylketone, or 2-heptanon; polyhydric alcohol such as ethylene glycol, diethylene glycol, propylene glycol, or dipropylene glycol; a derivative of a polyhydric alcohol such as a compound having an ester linkage such as ethylene glycol monoacetate, diethylene glycol monoacetate, propylene glycol monoacetate, or dipropylene glycol monoacetate, or a compound having an ether linkage, such as a monoalkylether, e.g., monomethylether, monoethylether, monopropylether, monobutylether, or the like, or monophenylether, of the polyhydric alcohol or the compound having an ester linkage; cyclic ether such as dioxane or ester such as methyl lactate, ethyl lactate (EL), methyl acetate, ethyl acetate, methyl pyruvate, ethyl pyruvate, methyl methoxypropionate, or ethyl ethoxypropionate; an aromatic organic solvent such as anisole, ethylbenzylether, cresylmethylether, diphenylether, dibenzylether, phenetole, butylphenylether, ethylbenzene, diethylbenzene, pentylbenzene, isopropylbenzene, xylene, cymene, or mesitylene, etc.; dimethylsulfoxide (DMSO); or the like.

The content of organic solvent S in the chemical for photolithography of the present invention and the composition including the same are not specifically limited so long as a film may be formed to a desired thickness, i.e., 5 m or more, through spin coating. Generally, organic solvent S is used such that the concentration of a solid in the chemical or the composition is 1 to 65% by mass, preferably 5 to 60% by mass.

<Composition for Photoresist>

A second aspect of the present invention relates to a resist composition which generates an acid due to exposure and solubility in a developer of which changes due to function of the acid. The resist composition includes a resin ingredient A having a mass-average molecular weight (Mw) of 2000 to 50000, an organic solvent S having a saturated vapor pressure of 1 kPa or more (1 atm, 20° C.) and a viscosity of 1.1 cP (1 atm, 20° C.) or less, and an acid generator B.

The composition for photoresist of the present invention additionally includes acid generator B along with the aforementioned chemical for photolithography. Here, resin ingredient A and organic solvent S are the same as those of the chemical for photolithography.

[Ingredient B: Acid Generator]

In the present aspect, acid generator B of the resist composition is not specifically limited and may be an acid generator which has been suggested for use in chemically amplified resist.

Such an acid generator may be an acid generator based on onium salt such as a iodonium salt or a sulfonium salt; an oxime sulfonate-based acid generator; an acid generator based on diazomethane such as bisalkyl or bisarylsulfonyldiazomethane, or poly(bis-sulfonyl)diazomethane; a nitrobenzylsulfonate-based acid generator; an iminosulfonate-based acid generator; a disulfone-based acid generator, or the like. Thereamong, the onium salt-based acid generator is preferred.

The onium salt-based acid generator may be, for example, a compound represented by Formula (b-1) below (hereinafter also referred to as “ingredient b-1”), a compound represented by Formula (b-2) (hereinafter also referred to as “ingredient b-2”), or a compound represented by Formula (b-3) (hereinafter also referred to as “ingredient b-3”).

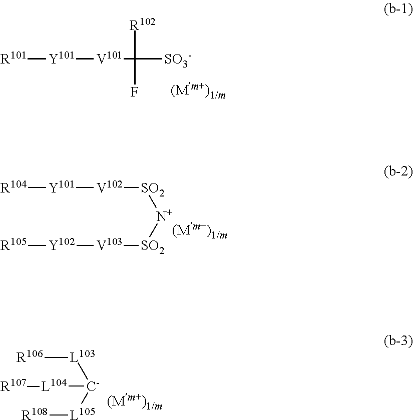

wherein R¹⁰¹ and R¹⁰⁴ to R¹⁰⁸ are each independently a cyclic group that may include a substituent, a chain-type alkyl group that may include a substituent, or a chain-type alkenyl group that may include a substituent. R¹⁰⁴ and R¹⁰⁵ may bond together to form a ring. R¹⁰² is a fluorine atom or a C₁ to C₅ fluorinated alkyl group. Y¹⁰¹ is a single bond or a divalent linking group including an oxygen atom. V¹⁰¹ to V¹⁰³ are each independently a single bond, an alkylene group, or a fluorinated alkylene group. L¹⁰¹ to L¹⁰² are each independently a single bond or an oxygen atom. L¹⁰³ to L¹⁰⁵ are each independently a single bond, —CO—, or —SO₂—. m is an integer of 1 or more, and M^{′m+} is an m-valent onium cation.

{Anion Part}

Anion Part of Ingredient b-1

R¹⁰¹ of Formula (b-1) is a cyclic group that may include a substituent, a chain-type alkyl group that may include a substituent, or a chain-type alkenyl group that may include a substituent.

Cyclic group that may have substituent:

The cyclic group is preferably a cyclic hydrocarbon group. The cyclic hydrocarbon group may be an aromatic hydrocarbon group or an aliphatic hydrocarbon group. The aliphatic hydrocarbon group is a non-aromatic hydrocarbon group. In addition, the aliphatic hydrocarbon group may be saturated or unsaturated. In general, the saturated aliphatic hydrocarbon group is preferred.

The aromatic hydrocarbon group of R¹⁰¹ is a hydrocarbon group having an aromatic ring. The aromatic hydrocarbon group has a carbon number of preferably 3 to 30, more preferably 5 to 30, even more preferably 5 to 20, particularly preferably 6 to 15, most preferably 6 to 10. However, the carbon number does not include the number of carbon atoms of a substituent.

The aromatic ring having an aromatic hydrocarbon group of R¹⁰¹ may be particularly benzene, fluorene, naphthalene, anthracene, phenanthrene, biphenyl, a heterocyclic aromatic ring formed by substituting a portion of carbon atoms constituting an aromatic ring thereof with a heteroatom, or the like. The heteroatom of the heterocyclic aromatic ring may be an oxygen atom, a sulfur atom, a nitrogen atom, or the like.

The aromatic hydrocarbon group of R¹⁰¹ may be particularly a group formed by removing one hydrogen atom from the aromatic ring (aryl group: e.g., phenyl group, a naphthyl group, etc.), a group formed by substituting one hydrogen atom of the aromatic ring with an alkylene group (e.g., arylalkyl group such as benzyl group, phenethyl group, 1-naphthylmethyl group, 2-naphthylmethyl group, 1-naphthylethyl group, 2-naphthylethyl group, or the like), or the like. The alkylene group (alkyl chain of the arylalkyl group) has a carbon number of preferably 1 to 4, more preferably 1 to 2, particularly preferably 1.

The cyclic aliphatic hydrocarbon group of R¹⁰¹ may be an aliphatic hydrocarbon group including a ring in a structure thereof.

The aliphatic hydrocarbon group including a ring in a structure thereof may be an alicyclic hydrocarbon group (a group formed by removing one hydrogen atom from an aliphatic hydrocarbon ring), a group formed by combining an alicyclic hydrocarbon group with a terminal of a straight chain or branched aliphatic hydrocarbon group, a group formed by inserting an alicyclic hydrocarbon group in the middle of a straight chain or branched aliphatic hydrocarbon group, etc.

The alicyclic hydrocarbon group has a carbon number of preferably 3 to 20, more preferably 3 to 12.

The alicyclic hydrocarbon group may be polycyclic or monocyclic. The monocyclic alicyclic hydrocarbon group is preferably a group formed by removing one or more hydrogen atoms from a monocycloalkane. The monocycloalkane has a carbon number of preferably 3 to 6. Particularly, the monocycloalkane may be cyclopentane, cyclohexane, etc. The polycyclic alicyclic hydrocarbon group is preferably a group formed by removing one or more hydrogen atoms from the polycycloalkane. The polycycloalkane has a carbon number of preferably 7 to 30. Thereamong, the polycycloalkane is preferably a polycycloalkane having a crosslinked ring-based polycyclic backbone such as adamantane, norbornane, isobomane, tricyclodecane, or tetracyclododecane; or a polycycloalkane having a condensed ring-based polycyclic backbone such as a cyclic group having a steroid backbone.

Thereamong, the cyclic aliphatic hydrocarbon group of R¹⁰¹ is preferably a group formed by removing one or more hydrogen atoms from monocycloalkane or polycycloalkane, more preferably a group formed by removing a hydrogen atom from polycycloalkane, particularly preferably an adamantyl group or a norbomyl group, most preferably an adamantyl group.

The straight chain or branched aliphatic hydrocarbon group that may bond to the alicyclic hydrocarbon group has a carbon number of preferably 1 to 10, more preferably 1 to 6, even more preferably 1 to 4, most preferably 1 to 3.

The straight chain aliphatic hydrocarbon group is preferably a straight chain alkylene group and may be particularly a methylene group [—CH₂—], an ethylene group [—(CH₂)₂—], a trimethylene group [—(CH₂)₃—], a tetramethylene group [—(CH₂)₄—], a pentamethylene group [—(CH₂)₅—], or the like.

The branched aliphatic hydrocarbon group is preferably a branched alkylene group and may be particularly an alkylalkylene group such as an alkylmethylene group, such as —CH(CH₃)—, —CH(CH₂CH₃)—, —C(CH₃)₂—, —C(CH₃)(CH₂CH₃)—, —C (CH₃)(CH₂CH₂CH₃)—, —C(CH₂CH₃)₂—; an alkylethylene group, such as —CH (CH₃)CH₂—, —CH(CH₃)CH(CH₃)—, —C(CH₃)₂CH₂—, —CH(CH₂CH₃)CH₂—, or —C (CH₂CH₃)₂—CH₂—; an alkyltrimethylene group, such as —CH(CH₃)CH₂CH₂—, or —CH₂CH(CH₃)CH₂—; or an alkyltetramethylene group, such as —CH (CH₃)CH₂CH₂CH₂— or —CH₂CH(CH₃)CH₂CH₂—. The alkyl group of the alkylalkylene group is preferably a C₁ to C₅ straight chain alkyl group.

In addition, the cyclic hydrocarbon group of R¹⁰¹ may include a heteroatom such as a heteroring. Particularly, the cyclic hydrocarbon group may be a lactone-containing cyclic group represented by each of Formulas (a2-r-1)″ to (a2-r-7)″, a —SO₂— containing cyclic group represented by each of Formulas (a5-r-1)″ to (a5-r-4)″, and the following heterocyclic groups:

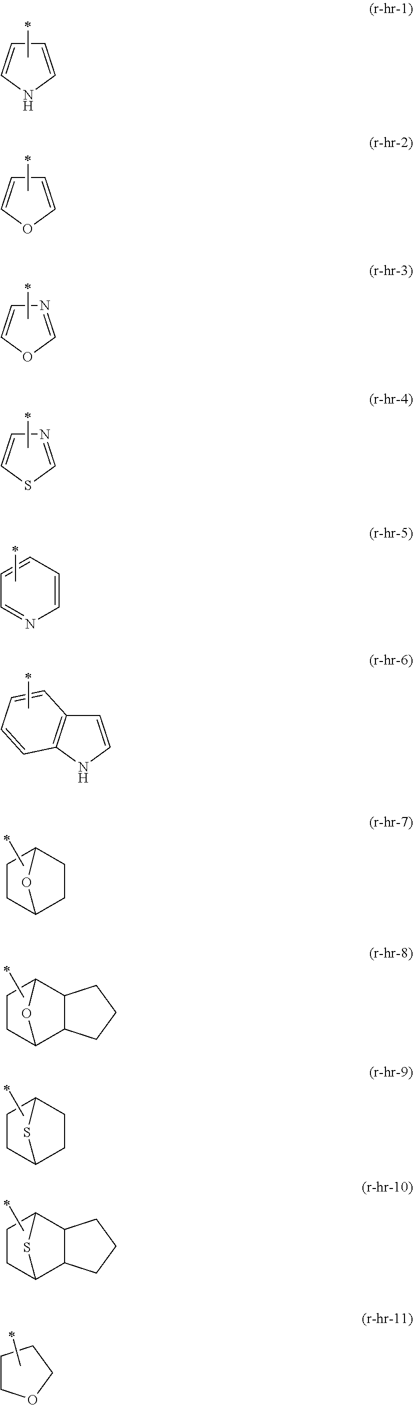

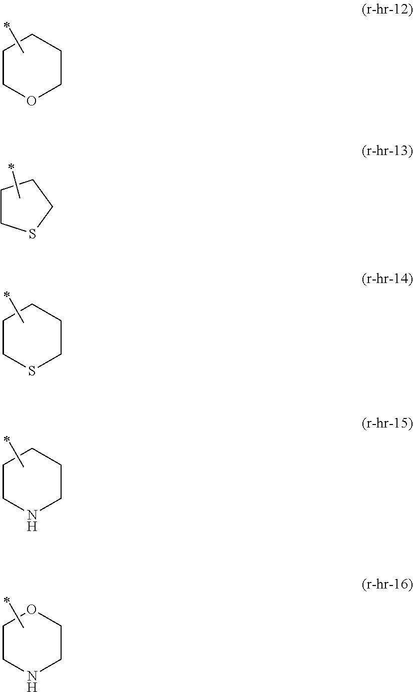

A substituent of the cyclic group of R¹⁰¹ may be, for example, an alkyl group, an alkoxy group, a halogen atom, a halogenated alkyl group, a hydroxyl group, a carbonyl group, a nitro group, or the like.

The alkyl group, as a substituent, is preferably a C₁ to C₅ alkyl group, most preferably a methyl group, an ethyl group, a propyl group, an n-butyl group, or a tert-butyl group.

The alkoxy group, as a substituent, is preferably a C₁ to C₅ alkoxy group, more preferably a methoxy group, an ethoxy group, an n-propoxy group, an iso-propoxy group, an n-butoxy group, or a tert-butoxy group, most preferably a methoxy group or an ethoxy group.

The halogen atom, as a substituent, may be a fluorine atom, a chlorine atom, a bromine atom, an iodine atom, or the like. The halogen atom is preferably a fluorine atom, or the like.

The halogenated alkyl group, as a substituent, may be a C₁ to C₅ alkyl group, e.g., a group formed by substituting a portion or all of hydrogen atoms of a methyl group, an ethyl group, a propyl group, an n-butyl group, a tert-butyl group, or the like with the halogen atom.

The carbonyl group, as a substituent, is a group that substitutes a methylene group (—CH₂—) constituting a cyclic hydrocarbon group.

The chain-type alkyl group that may include a substituent is described below:

The chain-type alkyl group of R¹⁰¹ may be a straight chain or branched.

The straight chain alkyl group has a carbon number of preferably 1 to 20, more preferably 1 to 15, most preferably 1 to 10. Particularly, the straight chain alkyl group may be, for example, a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group, a docosyl group, or the like.

The branched alkyl group has a carbon number of preferably 3 to 20, more preferably 3 to 15, most preferably 3 to 10. Particularly, the branched alkyl group may be, for example, a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, a 4-methylpentyl group, or the like.

The chain-type alkenyl group that may include a substituent is described below:

The chain-type alkenyl group of R¹⁰¹ may be a straight chain type or a branched chain type. The chain-type alkenyl group of R¹⁰¹ has a carbon number of preferably 2 to 10, more preferably 2 to 5, more preferably 2 to 4, particularly preferably 3. The straight chain alkenyl group may be, for example, a vinyl group, a propenyl group (an allyl group), a butynyl group, etc. The branched alkenyl group may be, for example, a 1-methylvinyl group, a 2-methylvinyl group, a 1-methylpropenyl group, a 2-methylpropenyl group, etc.

The chain-type alkenyl group is preferably the straight chain alkenyl group, more preferably a vinyl group or a propenyl group, particularly preferably a vinyl group, among the aforementioned groups.

A substituent of the chain-type alkyl group or alkenyl group of R¹⁰¹ may be, for example, an alkoxy group, a halogen atom, a halogenated alkyl group, a hydroxyl group, a carbonyl group, a nitro group, an amino group, the cyclic group of R¹⁰¹, or the like.

Thereamong, R¹⁰¹ is preferably a cyclic group that may include a substituent, more preferably a cyclic hydrocarbon group that may include a substituent. More particularly, R¹⁰¹ is preferably a group formed by removing one or more hydrogen atoms from a phenyl group, a naphthyl group, or a polycycloalkane; a lactone-containing cyclic group represented by each of Formulas (a2-r-1)″ to (a2-r-7)″; a —SO₂— containing cyclic group represented by each of Formulas (a5-r-1)″ to (a5-r-4)″; or the like.

Y¹⁰¹ of Formula (b-1) is a single bond or a divalent linking group including an oxygen atom.

When Y¹⁰¹ is a divalent linking group including an oxygen atom, Y¹⁰¹ may include other atoms, other than the oxygen atom. The other atoms, other than the oxygen atom, may be, for example, a carbon atom, a hydrogen atom, a sulfur atom, a nitrogen atom, or the like.

The divalent linking group including an oxygen atom may be, for example, an oxygen atom-containing non-hydrocarbon-based linking group such as an oxygen (ether linkage: —O—), an ester bond (—C(═O)—O—), an oxycarbonyl group (—O—C(═O)—), an amide linkage (—C(═O)—NH—), a carbonyl group (—C(═O)—), or a carbonate linkage (—O—C(═O)—O—); a combination of the oxygen atom-containing non-hydrocarbon-based linking group and an alkylene group; or the like. The combination may additionally include a sulfonyl group (—SO₂—) connected thereto. Examples of the divalent linking group including an oxygen atom include, for example, linking groups represented by Formulas (y-a1-1) to (y-a1-7) below:

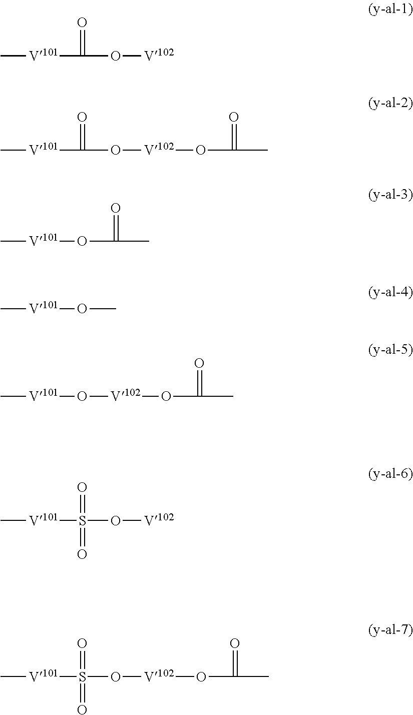

wherein V^{′101} is a single bond or a C₁ to C₅ alkylene group, and V^{′102} is a bivalent saturated hydrocarbon group having a carbon number of 1 to 30.

The bivalent saturated hydrocarbon group of V^{′102} is preferably a C₁ to C₃₀ alkylene group, more preferably a C₁ to C₁₀ alkylene group, even more preferably a C₁ to C₅ alkylene group.

The alkylene groups of V^{′01} and V^{′102} may be a straight chain alkylene group or a branched alkylene group. Preferably, the alkylene group is a straight chain alkylene group.

The alkylene groups of V^{′101} and V^{′102} may be particularly a methylene group [—CH₂—]; an alkyl methylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH (CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH (CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH (CH₃)CH₂CH₂—; a pentamethylene group [—CH₂CH₂CH₂CH₂CH₂—]; or the like.

In addition, a portion of the methylene groups among the alkylene groups of V^{′101} or V^{′102} may be substituted with a divalent alicyclic group having a carbon number of 5 to 10. The alicyclic group is preferably a divalent group formed by additionally removing one hydrogen atom from the cyclic aliphatic hydrocarbon group (the monocyclic aliphatic hydrocarbon group, the polycyclic aliphatic hydrocarbon group) of Ra^{′3} of Formula (a1-r-1)″, more preferably a cyclohexylene group, a 1,5-adamantylene group, or a 2,6-adamantylene group.

Y¹⁰¹ is preferably a divalent linking group including an ester linkage or a divalent linking group including an ether linkage, more preferably a linking group represented by each of Formulas (y-a1-1) to (y-a1-5).

V¹⁰¹ of Formula (b-1) is a single bond, an alkylene group, or a fluorinated alkylene group. The alkylene group and the fluorinated alkylene group of V¹⁰¹ preferably have a carbon number of 1 to 4. The fluorinated alkylene group of V¹⁰¹ may be a group formed by substituting a portion or all of hydrogen atoms of the alkylene group of V¹⁰¹ with a fluorine atom. Thereamong, V¹⁰¹ is preferably a single bond or a C₁ to C₄ fluorinated alkylene group.

R¹⁰² of Formula (b-1) is a fluorine atom or a C₁ to C₅ fluorinated alkyl group. R¹⁰² is preferably a fluorine atom or a C₁ to C₅ perfluoroalkyl group, more preferably a fluorine atom.

As specific examples of the anion part of ingredient b-1, when Y¹⁰¹ is a single bond, the anion part may be a fluorinated alkyl sulfonate anion such as a trifluoromethanesulfonate anion or a perfluorobutane sulfonate anion, etc.; and when Y¹⁰¹ is a divalent linking group including an oxygen atom, the anion part may be an anion represented by any one of Formulas (an-1) to (an-3) below:

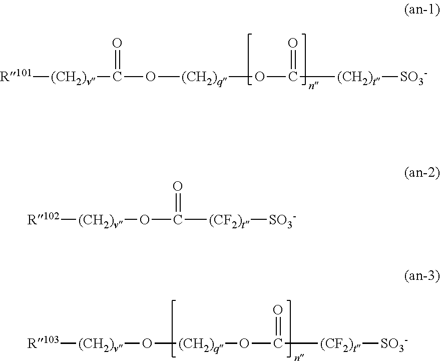

wherein R^{″101} is an alicyclic group that may include a substituent, a group represented by each of Formulas (r-hr-1) to (r-hr-6), or a chain-type alkyl group that may include a substituent; R^{″102} is an alicyclic group that may include a substituent, a lactone-containing cyclic group represented by each of Formulas (a2-r-1)″ to (a2-r-7)″, or a —SO₂— containing cyclic group represented by each of Formula (a5-r-1)″ to (a5-r-4)″; R^{″103} is an aromatic cyclic group that may include a substituent, an alicyclic group that may include a substituent, or a chain-type alkenyl group that may include a substituent; and v″ is an integer of 0 to 3, q″ is an integer of 1 to 20, t″ is an integer of 1 to 3, and n″ is 0 or 1.

Examples of the alicyclic group which may include a substituent, of R^{″101}, R^{″102} and R^{″103} are preferably the same as the examples of the cyclic aliphatic hydrocarbon group of R¹⁰¹. Examples of the substituent may be the same as the examples of the substituents of the cyclic aliphatic hydrocarbon group of R¹⁰¹.

Examples of the aromatic cyclic group which may include a substituent, of R^{″103} are preferably the same as the examples of aromatic hydrocarbon groups of the cyclic hydrocarbon group of R¹⁰¹. Examples of the substituent may be the same as the examples of the substituents of the aromatic hydrocarbon group of R¹⁰¹.

Examples of the chain-type alkyl group which may include a substituent, of R^{″101} are preferably the same as the examples of the chain-type alkyl group of R¹⁰¹. Examples of the chain-type alkenyl group which may have a substituent, of R^{″103} are preferably the same as the examples of the chain-type alkenyl group of R¹⁰¹.

Anion Part of Ingredient (b-2)

R¹⁰⁴ and R¹⁰⁵ of Formula (b-2) are each independently a cyclic group that may have a substituent, a chain-type alkyl group that may have a substituent, a chain-type alkenyl group that may have a substituent. In addition, examples of each of R¹⁰⁴ and R¹⁰⁵ of Formula (b-2) may be the same as the examples of R¹⁰¹ of Formula (b-1). However, R¹⁰⁴ and R¹⁰⁵ may bond together to form a ring.

R¹⁰⁴ and R¹⁰⁵ are preferably a chain-type alkyl group that may have a substituent, more preferably a straight chain or branched alkyl group, or a straight chain or branched fluorinated alkyl group.

The chain-type alkyl group has a carbon number of preferably 1 to 10, more preferably a carbon number of 1 to 7, even more preferably a carbon number of 1 to 3. Within this range, the less the carbon number of the chain-type alkyl group of each of R¹⁰⁴ and R¹⁰⁵, the more preferable it is in terms of satisfaction of the solubility in a resist solvent, etc. In addition, in the chain-type alkyl group of each of R¹⁰⁴ and R¹⁰⁵, acidity increases with an increasing number of hydrogen atoms substituted with a fluorine atom. In addition, transparency to light having a high energy of 200 nm or less or electron beams improves with an increasing number of hydrogen atoms substituted with a fluorine atom. Thus, the more hydrogen atoms are substituted with a fluorine atom, the more preferable it is. A proportion of the fluorine atoms in the chain-type alkyl group, i.e., a fluorination rate, is preferably 70 to 100%, more preferably 90 to 100%. Most preferably, the chain-type alkyl group is a perfluoroalkyl group, all hydrogen atoms of which are substituted with fluorine atoms.

V¹⁰² and V¹⁰³ of Formula (b-2) each independently are a single bond, an alkylene group or a fluorinated alkylene group. Examples of each of V¹⁰² and V¹⁰³ may be the same as the examples of V¹⁰¹ of Formula (b-1).

L¹⁰³ and L¹⁰⁵ of Formula (b-2) each independently are a single bond or an oxygen atom.

Anion Part of Ingredient (b-3)

R¹⁰⁶ to R¹⁰⁸ of Formula (b-3) may each independently be a cyclic group that may have a substituent, a chain-type alkyl group that may have a substituent, or a chain-type alkenyl group that may have a substituent. In addition, examples of each of R¹⁰⁶ to R¹⁰⁸ of Formula (b-3) may be the same as the examples of R¹⁰¹ of Formula (b-1).

L¹⁰³ to L¹⁰⁵ each independently are a single bond, —CO— or —SO₂—.

{Cation Part}

In Formulas (b-1), (b-2), and (b-3), m is an integer of 1 or more, and M^{′m+} is an m-valent onium cation, preferably a sulfonium cation or an iodonium cation, particularly preferably an organic cation represented by each of Formulas (ca-1) to (ca-4) below:

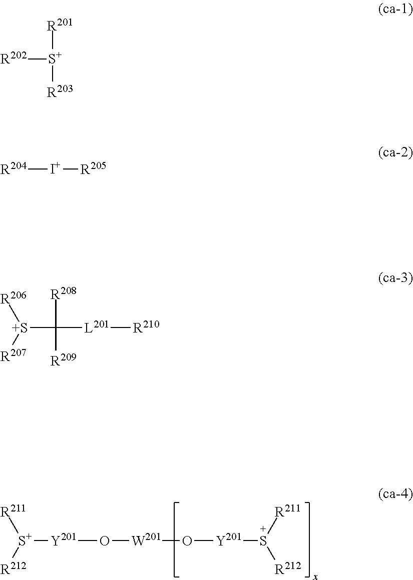

wherein R²⁰¹ to R²⁰⁷, and R²¹¹ to R²¹² each independently represent an aryl group, an alkyl group, or an alkenyl group which may include a substituent, R²⁰¹ to R²⁰³, R²⁰⁶ to R²⁰⁷, and R²¹¹ to R²¹² may bond together to form a ring with a sulfur atom present in the formula. R²⁰⁸ to R²⁰⁹ each independently represent a hydrogen atom or a C₁ to C₅ alkyl group, R²¹⁰ represents an aryl group that may include a substituent, an alkyl group that may include a substituent, an alkenyl group that may include a substituent, or a —SO₂— containing cyclic group that may include a substituent, L²⁰¹ represents —C(═O)— or —C(═O)—O—, Y²⁰¹ each independently represents an arylene group, an alkylene group, or an alkenylene group, x is 1 or 2, and W²⁰¹ represents an (x+1)-valent linking group.

An aryl group of each of R²⁰¹ to R²⁰⁷, and R²¹¹ to R²¹² may be a C₆ to C₂₀ unsubstituted aryl group and is preferably a phenyl group or a naphthyl group.

The alkyl group of each of R²⁰¹ to R²⁰⁷, and R²¹¹ to R²¹² is a chain-type or cyclic alkyl group, preferably a C₁ to C₃₀ chain-type or cyclic alkyl group.

The alkenyl group of each of R²⁰¹ to R²⁰⁷, and R²¹¹ to R²¹² preferably has a carbon number of 2 to 10.

Examples of substituents that may be included in R²⁰¹ to R²⁰⁷ and R²¹⁰ to R²¹² include an alkyl group, a halogen atom, a halogenated alkyl group, a carbonyl group (the carbonyl group is formed by substituting a hydrogen atom bonded to carbon constituting an aryl group with an oxygen atom, or a group that substitutes a methylene group (—CH₂—) constituting an alkyl group or an alkenyl group), a cyano group, an amino group, an aryl group, and a group represented by each of Formulas (ca-r-1) to (ca-r-7) below:

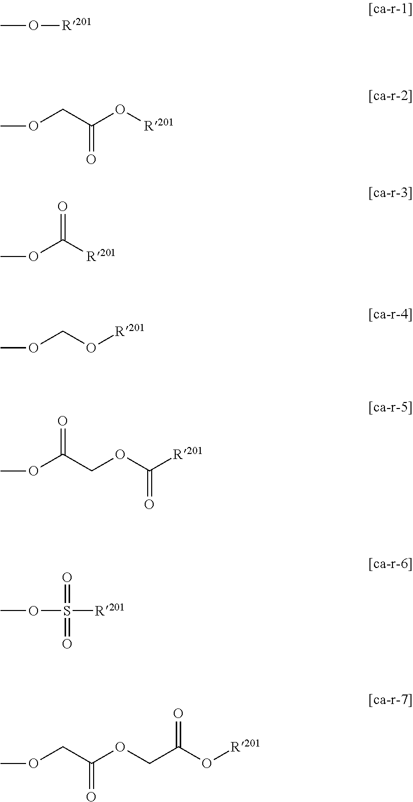

wherein R^{′201} is each independently, a hydrogen atom, a cyclic group that may have a substituent, a chain-type alkyl group that may have a substituent, or a chain-type alkenyl group that may have a substituent.

Examples of the cyclic group which may have a substituent, the chain-type alkyl group which may have a substituent, or the chain-type alkenyl group which may have a substituent, of R^{′201} may be the same as the examples of R¹⁰¹ of Formula (b-1). Also examples of the cyclic group that may include a substituent or the chain-type alkyl group that may have a substituent may be the same as the examples of the acid-dissociative group represented by Formula (a1-r-2)″ described above.

When R²⁰¹ to R²⁰³, R²⁰⁶ to R²⁰⁷, and R²¹¹ to R²¹² bond together to form rings with sulfur atoms included in the formulas, a heteroatom such as a sulfur atom, an oxygen atom, or nitrogen atom or a functional group such as a carbonyl group, —SO—, —SO₂—, —SO₃—, —COO—, —CONH—, or —N(R_{N})—(R_{N} is a C₁ to C₅ alkyl group), etc. may be included therebetween. Each of the formed rings has preferably 3 to 10 atoms, particularly preferably 5 to 7 atoms, including one sulfur atom that is included in a backbone of the ring. The specific examples of the formed rings include a thiophene ring, a thiazole ring, a benzothiophene ring, a thianthrene ring, a dibenzothiophene ring, a 9H-thioxanthene ring, a thioxanthone ring, a phenoxathiin ring, a tetrahydrothiophenium ring, a tetrahydrothiopyranium ring, and the like.

R²⁰⁸ to R²⁰⁹ each independently represent a hydrogen atom or a C₁ to C₅ alkyl group, preferably a hydrogen atom or a C₁ to C₃ alkyl group. When each of R²⁰⁸ to R²⁰⁹ is an alkyl group, it may bond together to form a ring.

R²¹⁰ is an aryl group that may include a substituent, an alkyl group that may include a substituent, an alkenyl group that may include a substituent, or a —SO₂— containing cyclic group that may include a substituent.

The aryl group of R²¹⁰ is a C₆ to C₂₀ unsubstituted aryl group, preferably a phenyl group or a naphthyl group.

The alkyl group of R²¹⁰ is a chain-type or cyclic alkyl group, preferably a C₁ to C₃₀ alkyl group.

The alkenyl group of R²¹⁰ is preferably a C2 to C10 alkenyl group.

Examples of the —SO₂— containing cyclic group which may include a substituent, of R²¹⁰ may be the same as the examples of the aforementioned “—SO₂— containing cyclic group”. Thereamong, the —SO₂— containing polycyclic group is preferable and the group represented by Formula (a5-r-1)″ is more preferable.

Y²⁰¹ each independently represents an arylene group, an alkylene group, or an alkenylene group.

The arylene group of Y²⁰¹ may be a group formed by removing one hydrogen atom from the aryl group which was exemplified as an aromatic hydrocarbon group of R¹⁰¹ of the aforementioned Formula (b-1).

Each of the alkylene group and the alkenylene group of Y²⁰¹ may be formed by removing one hydrogen atom from each of the groups which are examples of a chain-type alkyl group and a chain-type alkenyl group of R¹⁰¹ of the aforementioned Formula (b-1).

In Formula (ca-4), x is 1 or 2.

W²⁰¹ is an (x+1)-valent linking group, i.e., a divalent or trivalent linking group.

The divalent linking group of W²⁰¹ is preferably a divalent hydrocarbon group that may include a substituent. In addition, examples of the divalent linking group of W²⁰¹ may be the same as the examples of the divalent hydrocarbon group, which may include a substituent, of Ya²¹ of the aforementioned Formula (a2-1)″. The divalent linking group of W²⁰¹ may be straight chain, branched, or cyclic. Preferably, the divalent linking group is cyclic. Particularly, an arylene group including carbonyl groups connected to both ends thereof is preferable. The arylene group may be a phenylene group or a naphthylene group. Particularly preferably, the arylene group is a phenylene group.

Examples of the trivalent linking group of W²⁰¹ include a group formed by removing one hydrogen atom from the divalent linking group of W²⁰¹, a group formed by additionally combining the divalent linking group with the divalent linking group, or the like. The trivalent linking group of W²⁰¹ is preferably a group formed by combining an arylene group with two carbonyl groups.

A preferable cation represented by Formula (ca-1) is particularly a cation represented by each of Formulas (ca-1-1) to (ca-1-67):

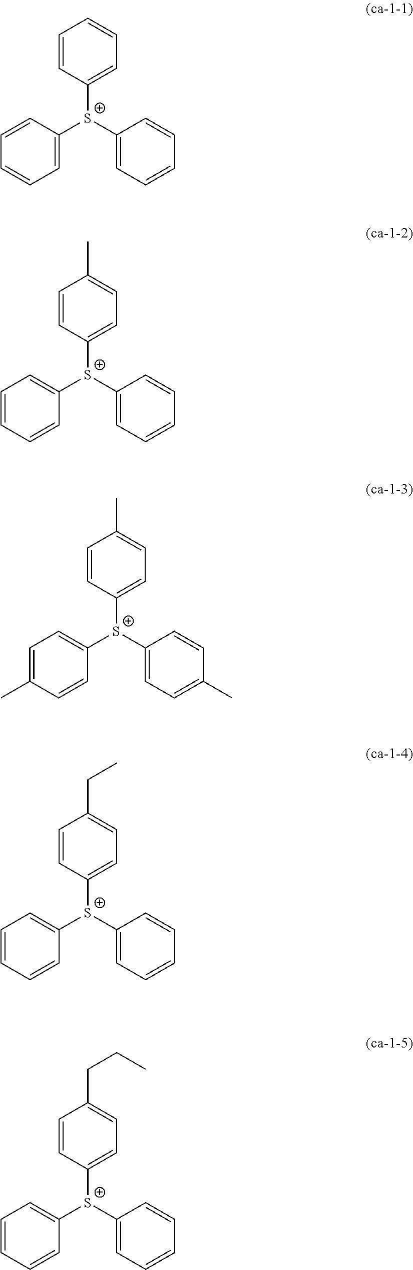

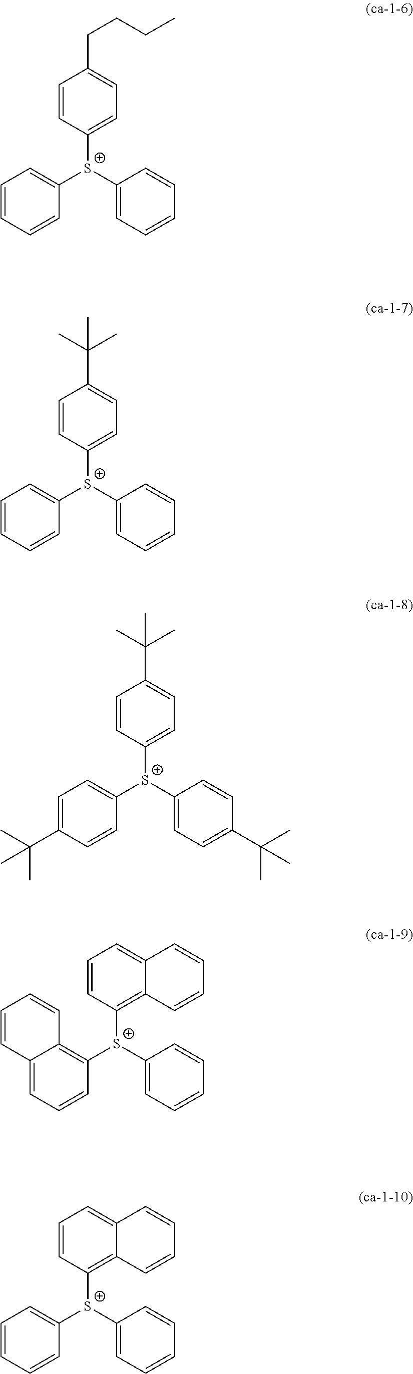

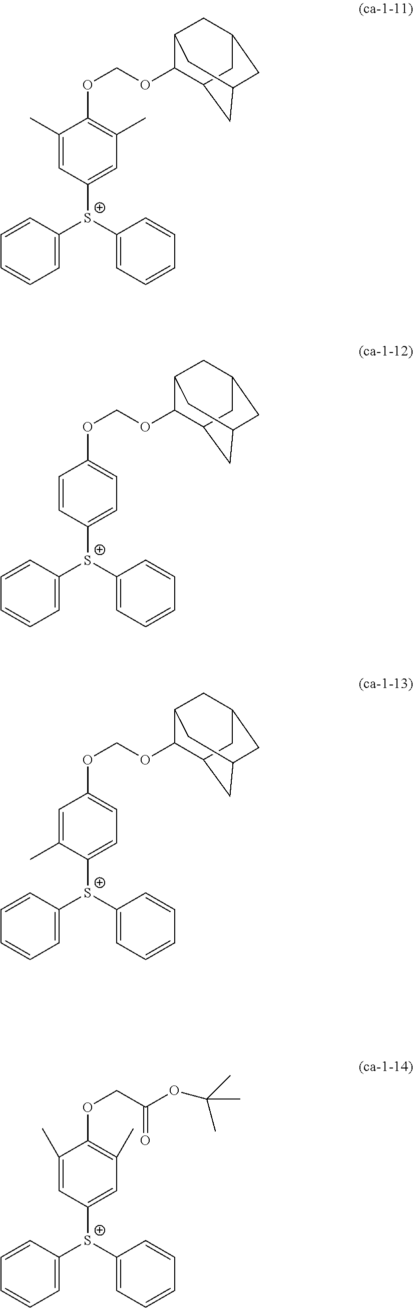

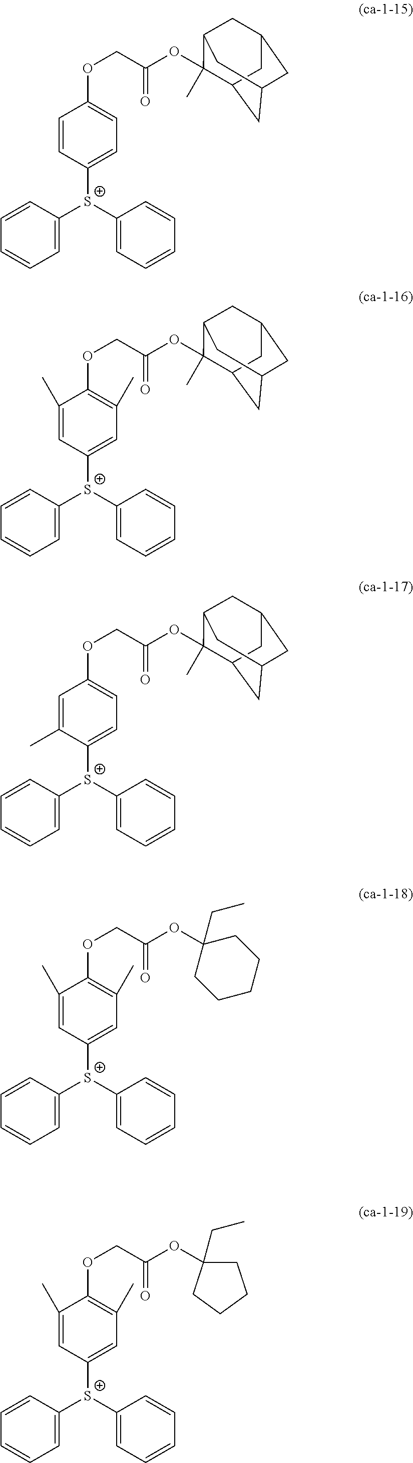

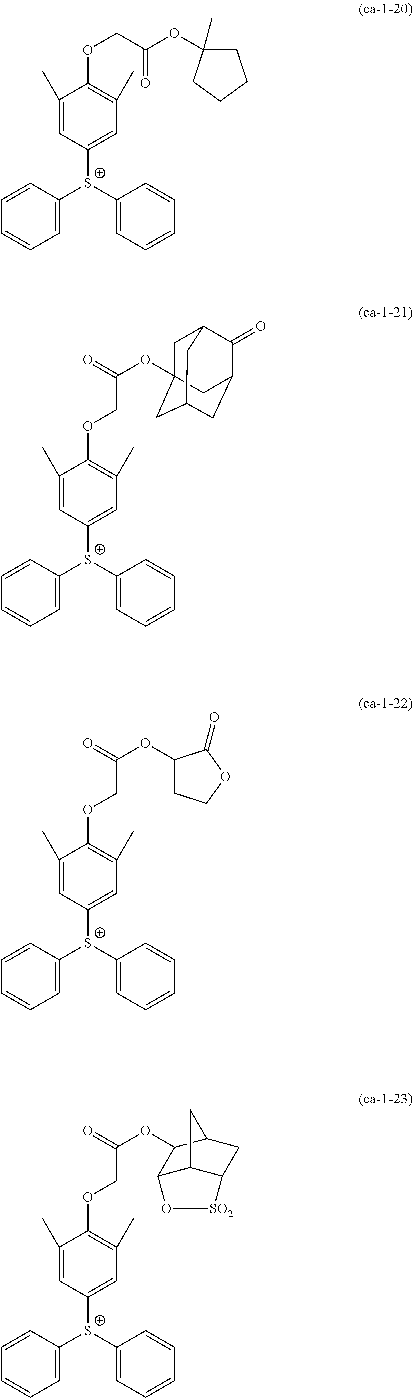

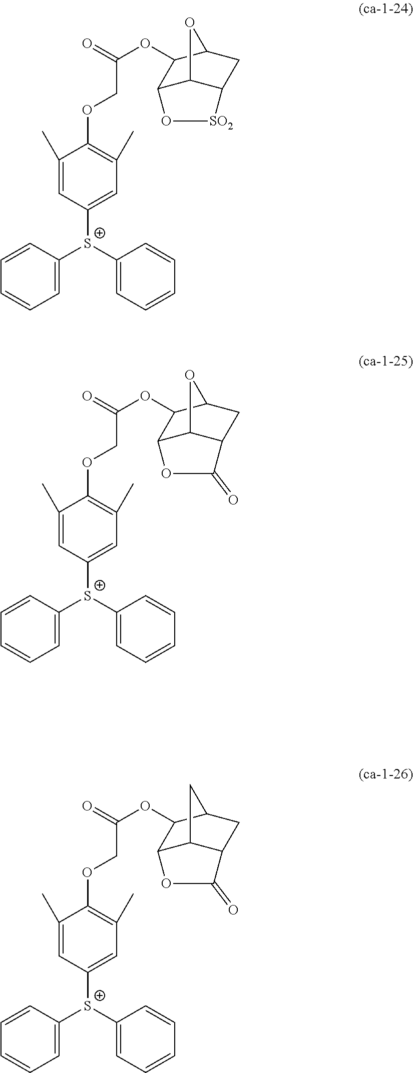

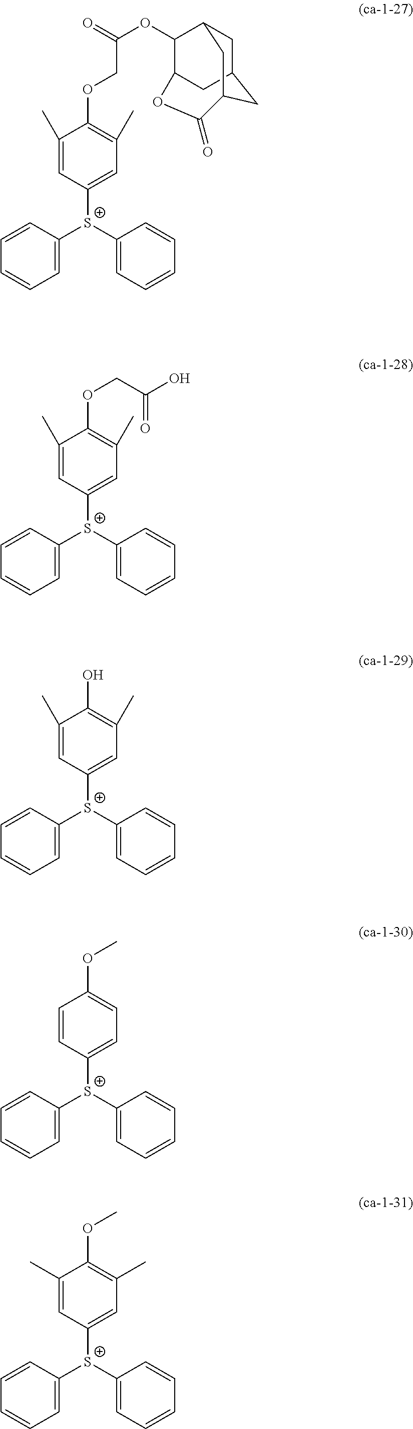

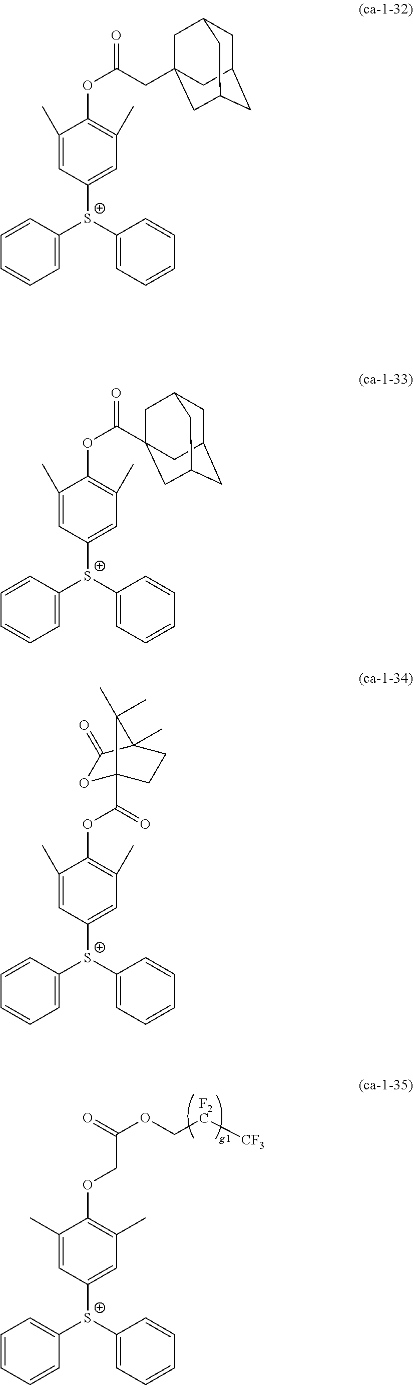

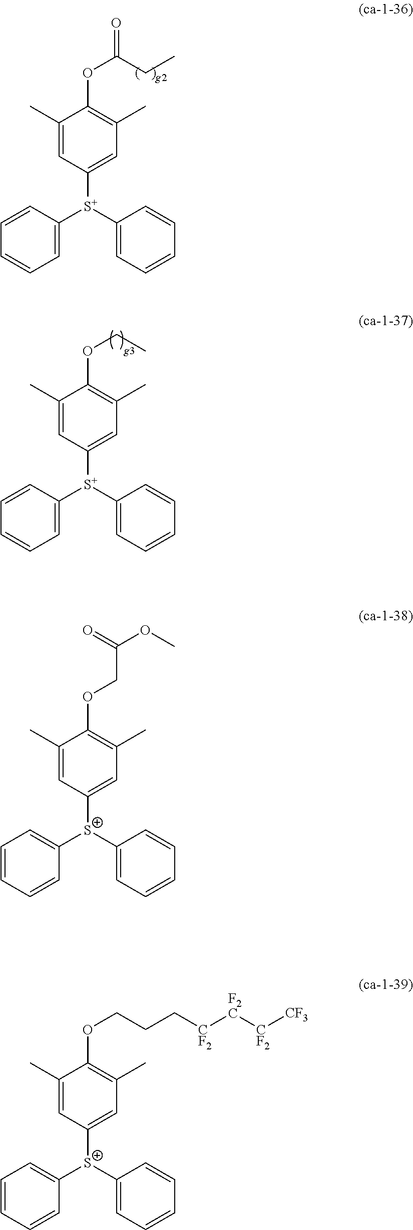

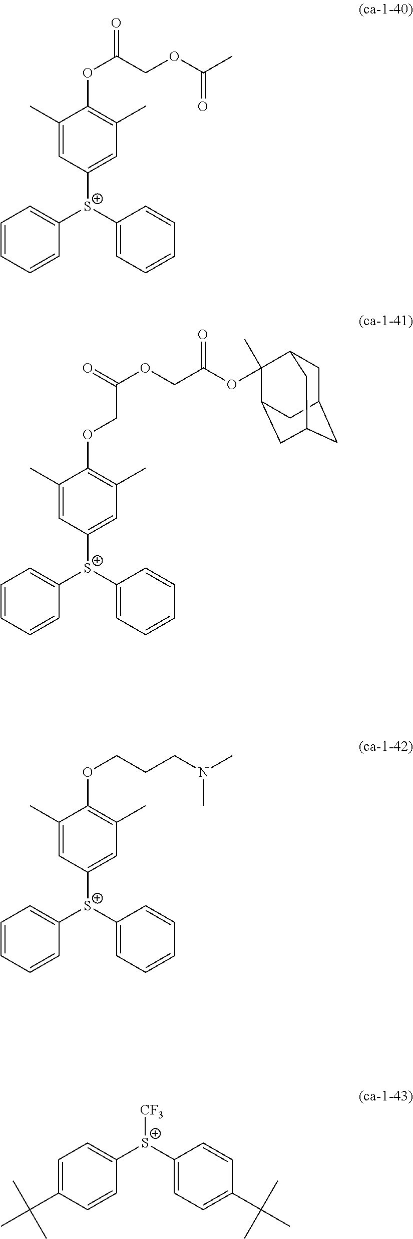

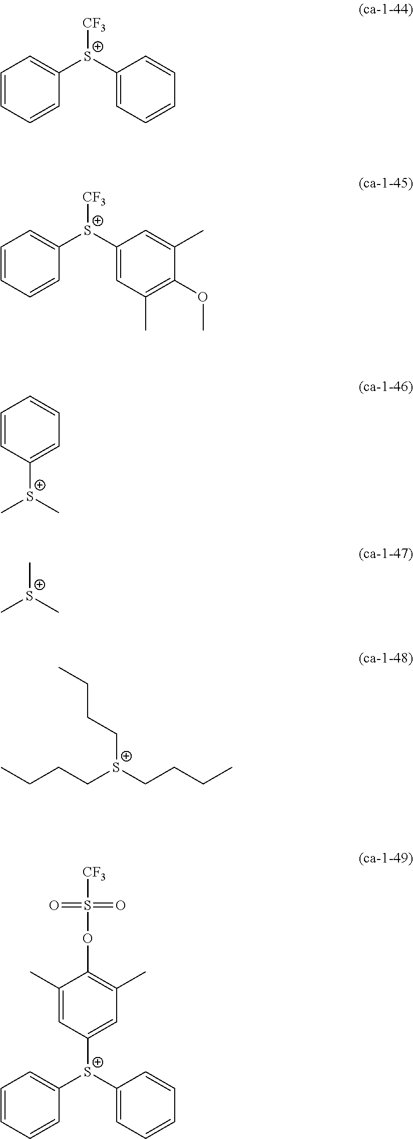

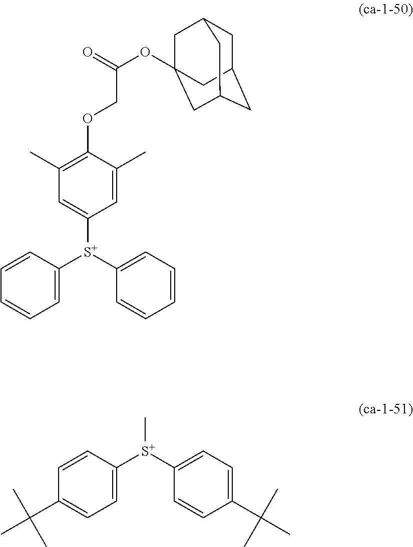

wherein g1, g2, and g3 represent a number of repeats, g1 is an integer of 1 to 5, g2 is an integer of 0 to 20, and g3 is an integer of 0 to 20.

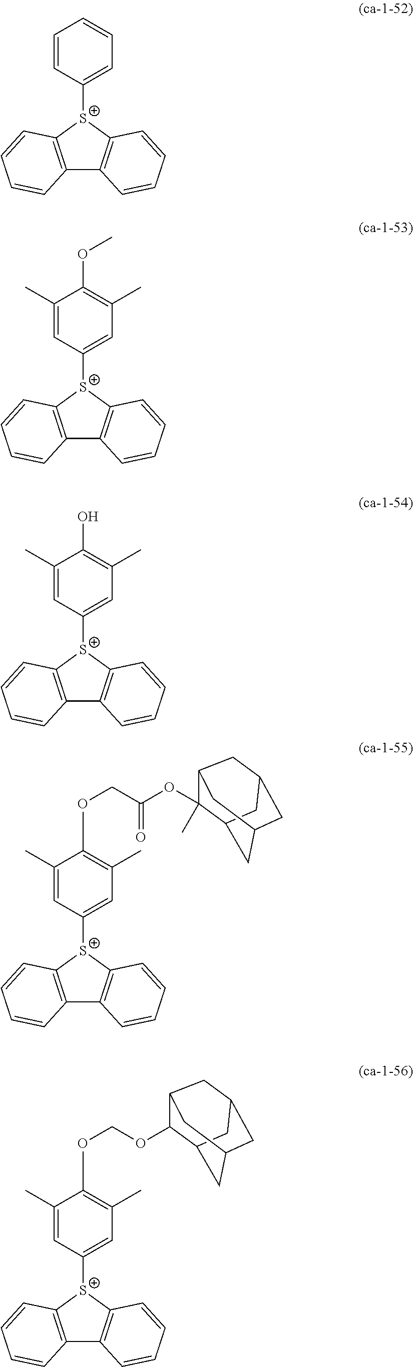 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3 ; Cc1cc(-[s+]2c3ccccc3c3ccccc32)cc(C)c1OCOC1C2CC3CC(C2)CC1C3]

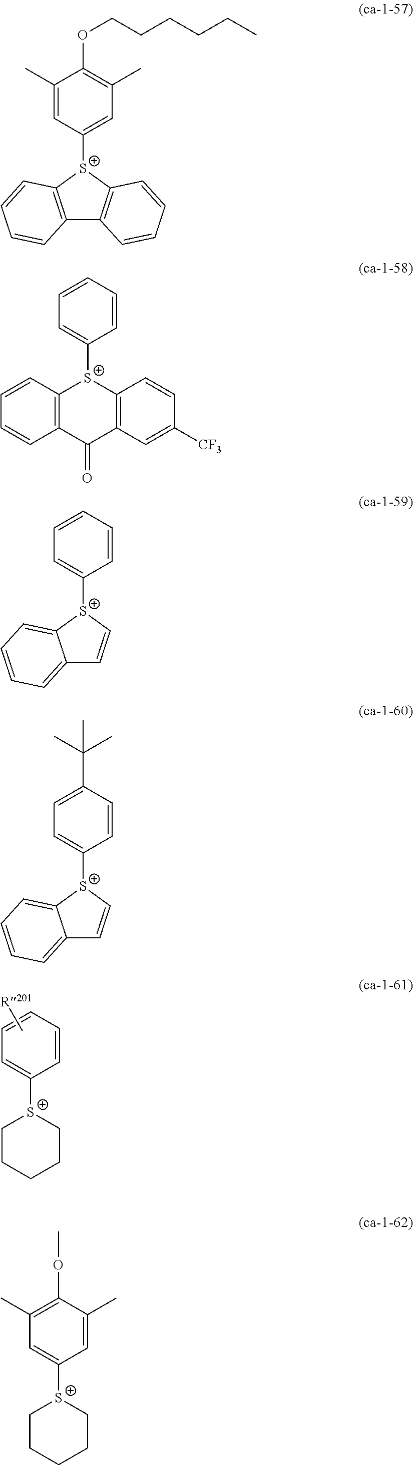

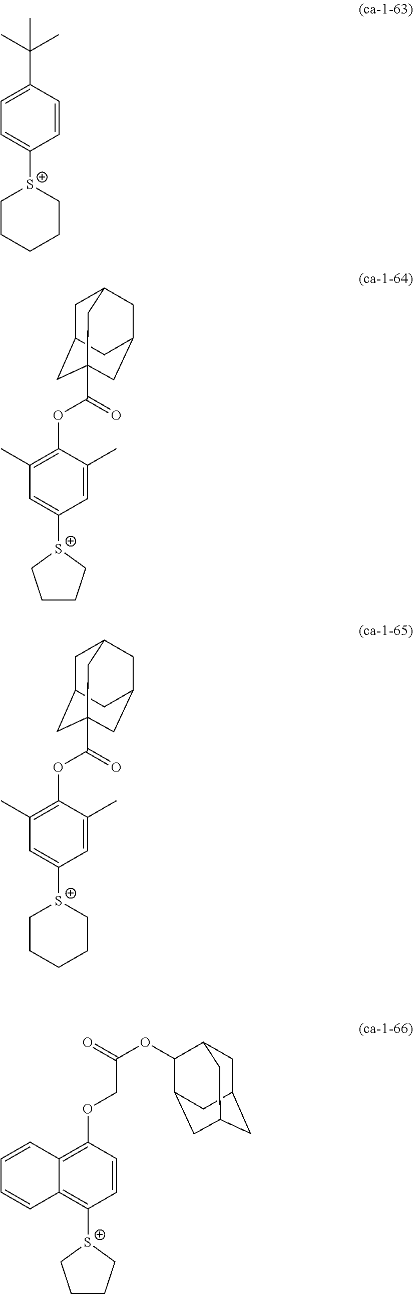 [SMILES: CC(C)(C)c1ccc([S+]2CCCCC2)cc1 ; Cc1cc([S+]2CCCC2)cc(C)c1OC(=O)C12CC3CC(CC(C3)C1)C2 ; Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3]

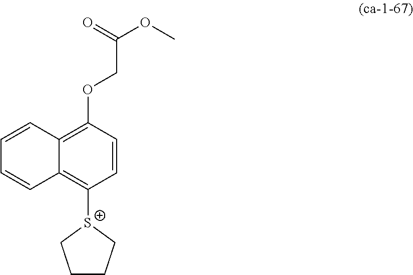 [SMILES: COC(=O)COc1ccc([S+]2CCCC2)c2ccccc12]

wherein R^{″201} is a hydrogen atom or a substituent. Examples of the substituent are the same as the examples of the substituents which may be included in R²⁰¹ to R²⁰⁷ and R²¹⁰ to R²¹².

The preferable cation represented by Formula (ca-2) may be particularly a diphenyliodonium cation, a bis(4-tert-butylphenyl)iodonium cation, etc.

The preferable cation represented by Formula (ca-3) may be particularly a cation represented by each of Formulas (ca-3-1) to (ca-3-6) below:

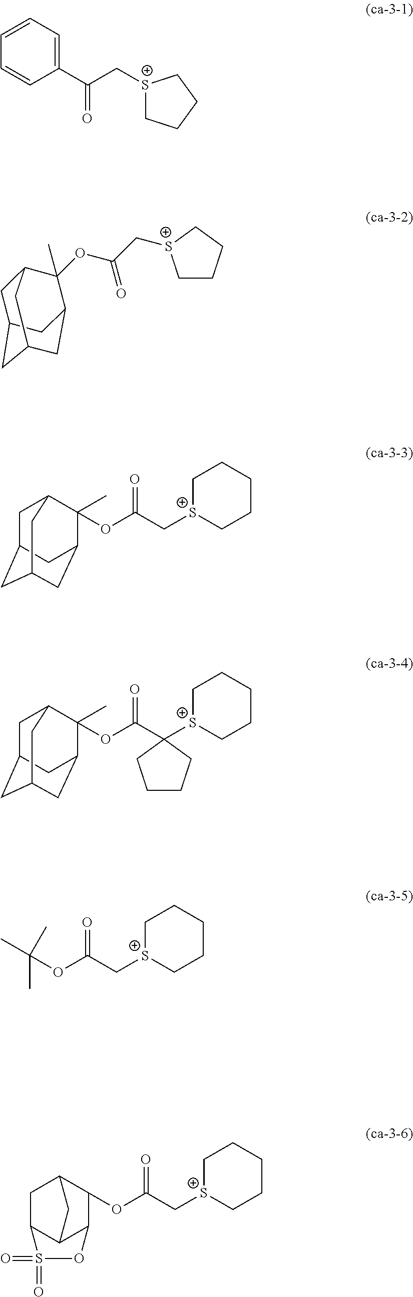

The preferable cation represented by Formula (ca-4) may be particularly a cation represented by each of Formulas (ca-4-1) to (ca-4-2) below:

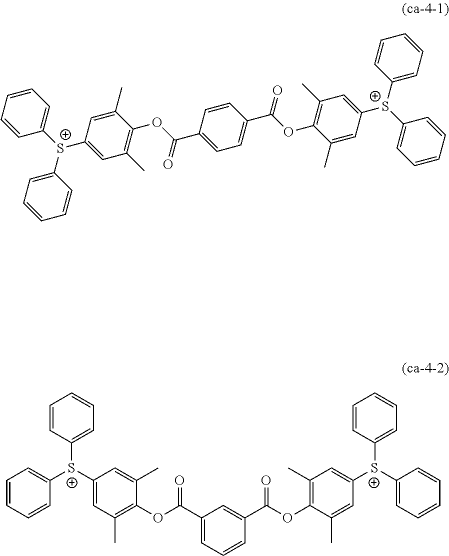 [SMILES: Cc1cc([S+](c2ccccc2)c2ccccc2)cc(C)c1OC(=O)c1ccc(C(=O)Oc2c(C)cc([S+](c3ccccc3)c3ccccc3)cc2C)cc1 ; Cc1cc([S+](c2ccccc2)c2ccccc2)cc(C)c1OC(=O)c1cccc(C(=O)Oc2c(C)cc([S+](c3ccccc3)c3ccccc3)cc2C)c1]

Thereamong, cation part [(M^{′m+})_{1/m}] is preferably a cation represented by Formula (ca-1), more preferably a cation represented by each of Formulas (ca-1-1) to (ca-1-67).

Ingredient (B) may be one type or a combination of two or more types selected from the examples of the aforementioned acid generator.

When the resist composition includes ingredient B, the content of ingredient B is preferably 0.5 to 60 parts by mass, more preferably 1 to 50 parts by mass, even more preferably 1 to 40 parts by mass, based on 100 parts by mass of ingredient A.

When ingredient B is included within this content range, pattern formation is sufficiently carried out. In addition, when each ingredient of the resist composition is solubilized in an organic solvent, it is easy to obtain a uniform solution and storage stability of the resist composition increases.

<Basic Compound Ingredient: Ingredient D>

The resist composition of the present invention may additionally include an acid diffusion controller (hereinafter, referred to as “ingredient D”), in addition to ingredient A or a combination of ingredients A and B.

Ingredient D functions as a quencher (acid diffusion controller) for trapping an acid generated from the ingredient B, etc. due to exposure.

Ingredient D may be a photodegradable base (D1) (hereinafter, referred to as “ingredient D1”) losing acid diffusion controllability upon degradation due to exposure, or a nitrogen-containing organic compound (D2) (hereinafter, referred to as “ingredient D2”) which does not correspond to ingredient D1.

[Ingredient D1]

When a resist pattern is formed using a resist composition including ingredient D1, a contrast between an exposed portion and an unexposed portion may be enhanced.

Ingredient D1 is not specifically limited so long as it is degraded by exposure and, accordingly, loses acid diffusion controllability thereof. Preferably, ingredient D1 is at least one compound selected from the group consisting of a compound represented by Formula (dl-1) below (hereinafter, referred to as ingredient dl-1), a compound represented by Formula (dl-2) below (hereinafter, referred to as “ingredient dl-2”), and a compound represented by Formula (dl-3) below (hereinafter, referred to as “ingredient dl-3”).

Ingredients dl-1 to dl-3 do not function as a quencher at an exposed portion of a resist film, at which they are degraded and, accordingly, lose acid diffusion controllability (basicity) thereof, and function as a quencher at an unexposed portion of the resist film.

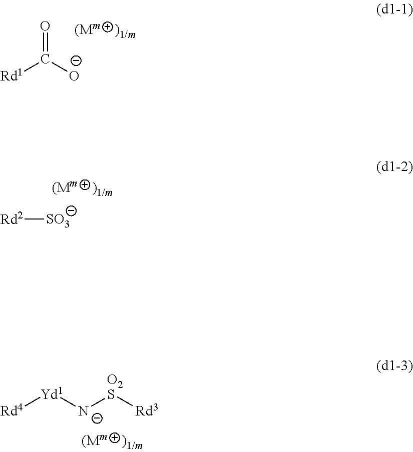

wherein Rd¹ to Rd⁴ are a cyclic group that may have a substituent, a chain-type alkyl group that may have a substituent, or a chain-type alkenyl group that may have a substituent. However, in the Rd² of Formula (dl-2), a fluorine atom does not bond to a carbon atom adjacent to an S atom. Yd¹ is a single bond or a divalent linking group. m is an integer of 1 or more, and M^{m+} is an m-valent organic cation.

{Ingredient Dl-1}

Anion Part

Rd¹ of Formula (dl-1) is a cyclic group that may have a substituent, a chain-type alkyl group that may have a substituent, or a chain-type alkenyl group that may have a substituent. In addition, examples of Rd¹ may be the same as the examples of R¹⁰¹ of Formula (b-1).

Particularly, Rd¹ is preferably an aromatic hydrocarbon group that may include a substituent, an alicyclic group that may include a substituent, or a chain-type hydrocarbon group that may include a substituent. Here, the substituent is preferably a hydroxyl group, a fluorine atom, or a fluorinated alkyl group.

The aromatic hydrocarbon group is more preferably a phenyl group or a naphthyl group.

The alicyclic group is more preferably a group formed by removing one or more hydrogen atoms from a polycycloalkane such as adamantane, norbomane, isobomane, tricyclodecane, or tetracyclododecane.

The chain-type hydrocarbon group is preferably a chain-type alkyl group. The chain-type alkyl group is preferably a C₁ to C₁₀ chain-type alkyl group. Particularly, the chain-type alkyl group may be a straight chain alkyl group such as a methyl group, an ethyl group, a propyl group, a butyl group, a pentyl group, a hexyl group, a heptyl group, an octyl group, a nonyl group, or a decyl group; or branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

When the chain-type alkyl group is a fluorinated alkyl group including a fluorine atom or a fluorinated alkyl group as a substituent, the fluorinated alkyl group has a carbon number of preferably 1 to 11, more preferably 1 to 8, even more preferably 1 to 4. The fluorinated alkyl group may include other atoms, other than the fluorine atom. The other atoms, other than the fluorine atom, may be, for example, an oxygen atom, a sulfur atom, a nitrogen atom, or the like.

Rd¹ is preferably a fluorinated alkyl group formed by substituting a portion or all of hydrogen atoms constituting a straight chain alkyl group with a fluorine atom, particularly preferably a fluorinated alkyl group (straight chain perfluoroalkyl group) formed by substituting all of hydrogen atoms constituting a straight chain alkyl group with a fluorine atom.

Hereinafter, preferred specific examples of the anion part of ingredient dl-1 are shown:

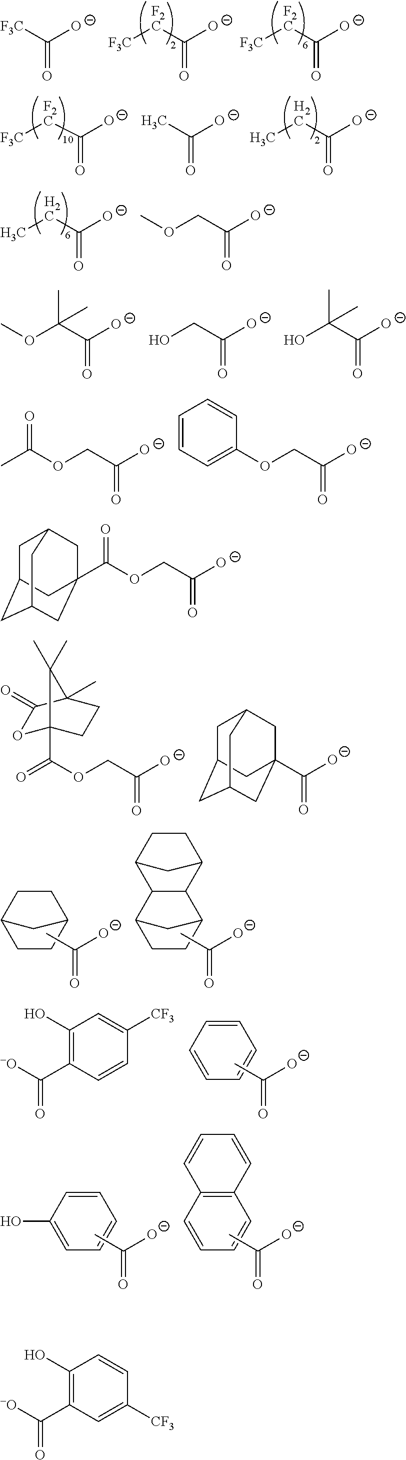

Cation Part

In Formula (dl-1), M^{m+} is an m-valent organic cation.

Examples of the organic cation of M^{μ+} are preferably the same as the examples of the cation represented by each of Formulas (ca-1) to (ca-4). The organic cation of M^{μ+} is more preferably the cation represented by Formula (ca-1), even more preferably the cation represented by each of Formulas (ca-1-1) to (ca-1-67).

Ingredient dl-1 may be one type or a combination of two or more types.

{Ingredient Dl-2}

Anion Part

Rd² of Formula (dl-2) may be a cyclic group that may have a substituent, a chain-type alkyl group that may have a substituent, or a chain-type alkenyl group that may have a substituent. In addition, examples of Rd² may be the same as the examples of R¹⁰¹ of Formula (b-1).

However, in Rd², a carbon atom adjacent to S atom is not coupled with a fluorine atom (not substituted with fluorine). Accordingly, an anion of ingredient dl-2 is a properly weak acidic anion, and ingredient dl-2, as ingredient D, has improved quenching ability.

Rd² is preferably a chain-type alkyl group that may have a substituent or an alicyclic group that may include a substituent. The chain-type alkyl group has a carbon number of preferably 1 to 10, more preferably 3 to 10. The alicyclic group is more preferably a group (may include a substituent) formed by removing one or more hydrogen atoms from adamantane, norbomane, isobomane, tricyclodecane, or tetracyclododecane; or a group formed by removing one or more hydrogen atoms from camphor, or the like.

The hydrocarbon group of Rd² may have a substituent. Examples of the substituent may be the same as the examples of the substituent that may be included in the hydrocarbon group (aromatic hydrocarbon group, alicyclic group, chain-type alkyl group) of Rd¹ of Formula (dl-1).

Hereinafter, preferred specific examples of the anion part of ingredient dl-2 are shown:

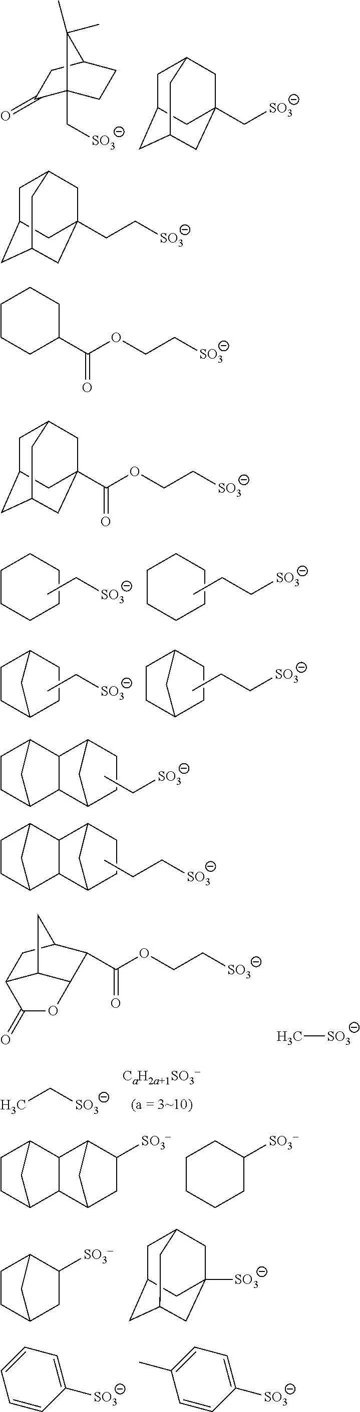

Cation Part

In Formula (dl-2), M^{m+} is an m-valent organic cation and the same as M^{μ+} of Formula (dl-1).

Ingredient dl-2 may be one type or a combination of two or more types.

{Ingredient d1-3}

Anion Part

Rd³ of Formula (dl-3) may be a cyclic group that may have a substituent, a chain-type alkyl group that may have a substituent, or a chain-type alkenyl group that may have a substituent. In addition, examples of Rd³ may be the same as the examples of R¹⁰¹ of Formula (b-1). Preferably, Rd³ is a cyclic group, chain-type alkyl group, or a chain-type alkenyl group which includes a fluorine atom. Thereamong, the fluorinated alkyl group is preferred. More preferably, examples of Rd³ are the same as the examples of the fluorinated alkyl group of Rd¹.

Rd⁴ of Formula (dl-3) is a cyclic group that may have a substituent, a chain-type alkyl group that may have a substituent, or a chain-type alkenyl group that may have a substituent. In addition, examples of Rd⁴ may be the same as the examples of R¹⁰¹ of Formula (b-1).

Thereamong, an alkyl group, an alkoxy group, an alkenyl group, and a cyclic group which may include a substituent are preferred.

The alkyl group of Rd⁴ is preferably a C₁ to C₅ straight chain or branched alkyl group, and may be particularly a methyl group, an ethyl group, a propyl group, an isopropyl group, a n-butyl group, an isobutyl group, a tert-butyl group, a pentyl group, an isopentyl group, a neopentyl group, or the like. Some hydrogen atoms of an alkyl group of Rd⁴ may be substituted with hydroxyl groups, cyano groups, or the like.

The alkoxy group of Rd⁴ is preferably a C₁ to C₅ alkoxy group. The C₁ to C₅ alkoxy group may be particularly a methoxy group, an ethoxy group, an n-propoxy group, an iso-propoxy group, an n-butoxy group, or a tert-butoxy group. Thereamong, the methoxy group and the ethoxy group are preferred.

Examples of the alkenyl group of Rd⁴ may be the same as the examples of R¹⁰¹ of Formula (b-1). Preferably, the alkenyl group is a vinyl group, a propenyl group (allyl group), a 1-methylpropenyl group, or a 2-methylpropenyl group. These groups may additionally include a C₁ to C₅ alkyl group or a C₁ to C₅ halogenated alkyl group, as a substituent.

Examples of the cyclic group of Rd⁴ may be the same as the examples of R¹⁰¹ of Formula (b-1). Preferably, the cyclic group is an alicyclic group formed by removing one or more hydrogen atoms from a cycloalkane such as cyclopentane, cyclohexane, adamantane, norbomane, isobomane, tricyclodecane, or tetracyclododecane, or an aromatic group such as a phenyl group or a naphthyl group. When Rd⁴ is an alicyclic group, the resist composition is satisfactorily solubilized in an organic solvent, and thus, lithographic characteristics are enhanced. In addition, when Rd⁴ is an aromatic group, superior light absorption efficiency of a resist composition is exhibited and satisfactory sensitivity or lithographic characteristics are provided in lithography in which EUV or the like is used as an exposure light source.

In Formula (dl-3), Yd¹ is a single bond or a divalent linking group.

The divalent linking group of Yd¹, which is not specifically limited, may be a divalent hydrocarbon group that may have a substituent (aliphatic hydrocarbon group, aromatic hydrocarbon group), a divalent linking group including a heteroatom, or the like. Examples of the divalent hydrocarbon group and the divalent linking group may be respectively the same as the examples of the divalent linking groups, i.e., the divalent hydrocarbon group which may have a substituent, and the divalent linking group which may include a heteroatom, of Ya²¹ of Formula (a2-1)″.

Yd¹ is preferably a carbonyl group, an ester bond, an amide linkage, an alkylene group, or a combination thereof. The alkylene group is preferably a straight chain or branched alkylene group, even more preferably a methylene group or an ethylene group.

Hereinafter, preferred specific examples of the anion part of ingredient dl-3 are shown:

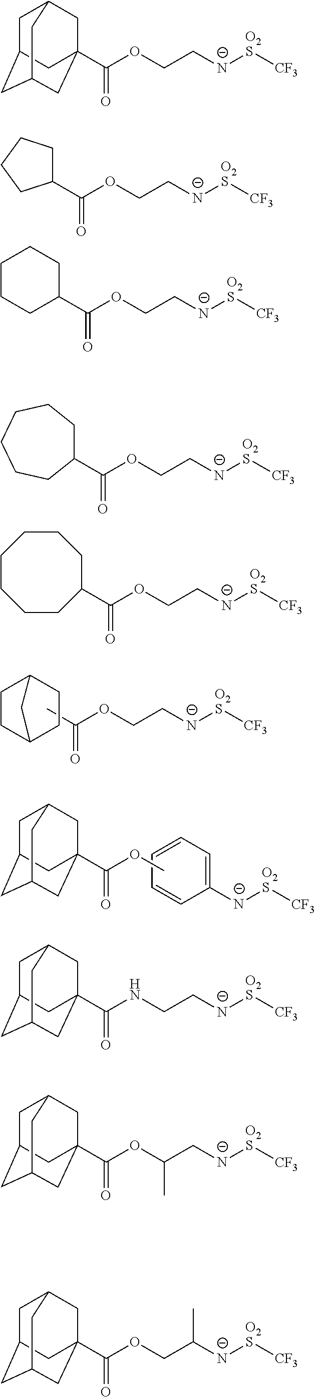

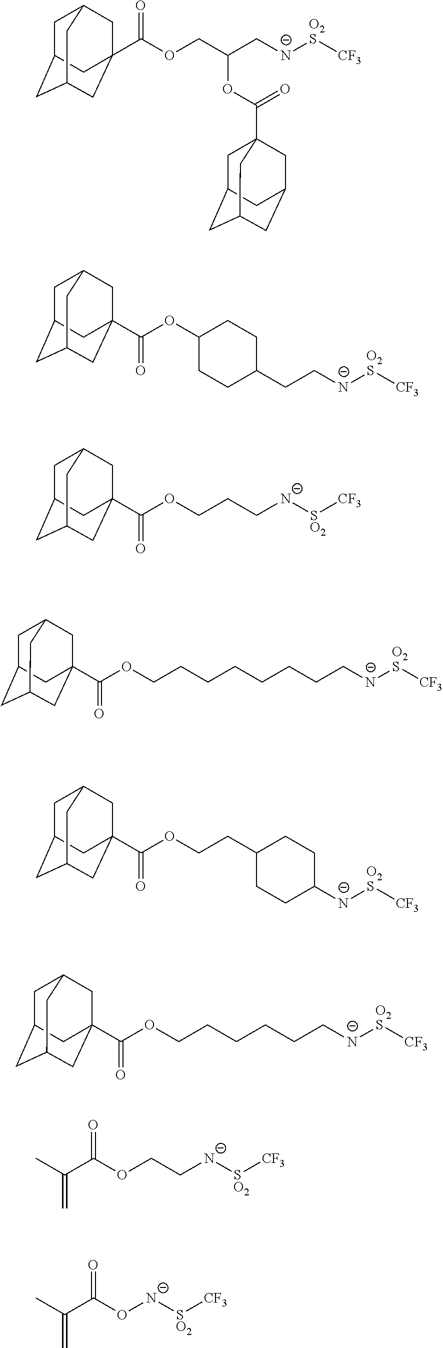

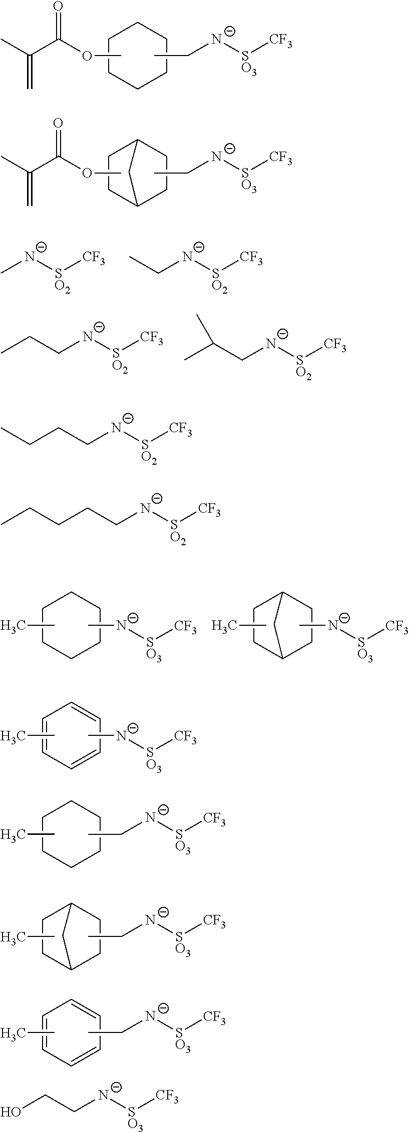

Cation Part

In Formula (dl-3), M^{m+} is an m-valent organic cation and is the same as M^{μ+} of Formula (dl-1).

Ingredient dl-3 may be one type or a combination of two or more types.

Ingredient D1 may be any one or a combination of two or more of ingredients (dl-1) to (dl-3).

When a resist composition includes ingredient D1, the content of ingredient D1 is preferably 0.5 to 10 parts by mass, more preferably 0.5 to 8 parts by mass, even more preferably 1 to 8 parts by mass, based on 100 parts by mass of ingredient A.

When the content of ingredient D1 is equal to or more than the lowest content, particularly satisfactory lithographic characteristics and resist pattern are easily obtained. Meanwhile, when the content of ingredient D1 is equal to or lower than the highest content, sensitivity may be satisfactorily maintained and superior throughput is provided.

A method of preparing ingredients dl-1 and dl-2 is not specifically limited and they may be a publicly known method.

In addition, a method of preparing ingredient dl-3 is not specifically limited and it may be the same as, for example, a method disclosed in US Patent No. 2012-0149916.

(Ingredient D2)

Ingredient D may include a nitrogen-containing organic compound (hereinafter, referred to as “ingredient D2”) that does not correspond to ingredient D1.

Ingredient D2 is not specifically limited so long as it functions as an acid diffusion controller and does not correspond to ingredient D1, and may be randomly selected from publicly known ingredients. Thereamong, an aliphatic amine is preferred. In particular, a secondary aliphatic amine or a tertiary aliphatic amine is more preferred.

Aliphatic amine refers to an amine having at least one aliphatic group. Here, the aliphatic group has preferably a carbon number of 1 to 12.

The aliphatic amine may be an amine (alkylamine or alkylalcoholamine) or a cyclic amine formed by substituting at least one of hydrogen atoms of ammonia (NH₃) with an alkyl or hydroxy alkyl group having a carbon number of 12 or less.

Specific examples of the alkylamine and the alkylalcoholamine include monoalkylamines such as n-hexylamine, n-heptylamine, n-octylamine, n-nonylamine, and n-decylamine; dialkylamines such as diethylamine, di-n-propylamine, di-n-heptylamine, di-n-octylamine, and dicyclohexylamine; trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, and tri-n-dodecylamine; and alkylalcoholamines such as diethanolamine, triethanolamine, diisopropanolamine, triisopropanolamine, di-n-octanolamine, and tri-n-octanolamine. Thereamong, a trialkylamine having a carbon number of 5 to 10 is most preferable, and tri-n-pentylamine or tri-n-octylamine is particularly preferable.

The cyclic amine may be, for example, a heteroring compound including a nitrogen atom as a heteroatom. The heteroring compound may be a monocyclic compound (aliphatic monocyclic amine) or a polycyclic compound (aliphatic polycyclic amine).

The aliphatic monocyclic amine may be particularly piperidine, piperazine, or the like.

The aliphatic polycyclic amine preferably has a carbon number of 6 to 10. Particularly, the aliphatic polycyclic amine may be 1,5-diazabicyclo[4.3.0]-5-nonene, 1,8-diazabicyclo[5.4.0]-7-undecene, hexamethylenetetramine, 1,4-diazabicyclo[2.2.2]octane, or the like.

As other examples, the aliphatic amine may be tris(2-methoxymethoxyethyl)amine, tris {2-(2-methoxyethoxy)ethoxy)ethyl}amine, tris {2-(2-methoxyethoxymethoxy)ethyl}amine, tris{2-(1-methoxyethoxy)ethyl}amine, tris {2-(1-ethoxyethoxy)ethyl}amine, tris {2-(1-ethoxypropoxy)ethyl}amine, tris[2-{2-(2-hydroxyethoxy)ethoxy}ethyl]amine, triethanolamine triacetate, or the like. Preferably, the aliphatic amine is triethanolaminetriacetate.

In addition, ingredient D2 may be an aromatic amine.

The aromatic amine may be 4-dimethylaminopyridine, pyrrole, indole, pyrazole, or imidazole or a derivative thereof, tribenzylamine, 2,6-diisopropylaniline, N-tert-butoxycarbonylpyrrolidine, or the like.

Ingredient D2 may be used alone or in a combination of two or more types.

When the resist composition includes ingredient D2, ingredient D2 is generally used in an amount of 0.01 to 5 parts by mass based on 100 parts by mass of ingredient A. Within this range, a resist pattern, stability over time after exposure, etc. are enhanced.

[Ingredient E]

The resist composition according to the present invention may include, as an optional ingredient, at least one compound E (hereinafter, referred to as “ingredient E”) selected from the group consisting of an organic carboxylic acid, an oxo acid of phosphorus, and a derivative of the oxo acid in order to prevent deterioration of sensitivity and enhance a resist pattern, stability over time after exposure, etc.

The organic carboxylic acid is preferably, for example, acetic acid, malonic acid, citric acid, malic acid, succinic acid, benzoic acid, salicylic acid, or the like.

The oxo acid of phosphorus may be phosphoric acid, phosphonic acid, phosphinic acid, or the like. Thereamong, phosphonic acid is preferred.

The derivative of the oxo acid of phosphorus may be, for example, an ester formed by substituting a hydrogen atom of the oxo acid with a hydrocarbon group, or the like. The hydrocarbon group may be a C₁ to C₅ alkyl group, a C₆ to C₁₅ aryl group, or the like.

A derivative of phosphoric acid may be phosphoric acid ester such as phosphoric acid di-n-butyl ester, phosphoric acid diphenyl ester, etc.

A derivative of phosphonic acid may be a phosphonic acid ester such as phosphonic acid dimethyl ester, phosphonic acid-di-n-butyl ester, phenyl phosphonic acid, phosphonic acid diphenyl ester, phosphonic acid dibenzyl ester, or the like.

A derivative of phosphinic acid may be phosphinic acid ester, phenylphosphinic acid, or the like.

Ingredient E may be used alone or in a combination of two or more types.

When the resist composition includes ingredient E, ingredient E is generally included in an amount of 0.01 to 5 parts by mass, based on 100 parts by mass of ingredient A.

[Ingredient F]

The resist composition according to the present invention may include a fluorine-containing ingredient (hereinafter, referred to as “ingredient F”) to provide water repellency to a resist film.

Ingredient F may be, for example, a fluorine-containing polymer compound disclosed in Japanese Patent Laid-Open Publication Nos. 2010-002870, 2010-032994, 2010-277043, 2011-13569, and 2011-128226.

More particularly, ingredient F may be a polymer having constituent unit fl represented by Formula (fl-1). The polymer is preferably a polymer (homopolymer) composed of only constituent unit fl represented by Formula (fl-1) below; a copolymer of constituent unit fl and constituent unit (a1)″; or a copolymer of constituent unit fl, a constituent unit derived from acrylic acid or methacrylic acid, and constituent unit (a1)″. Here, constituent unit (a1)″ copolymerized with constituent unit fl is preferably a constituent unit derived from 1-ethyl-1-cyclooctyl (meth)acrylate.

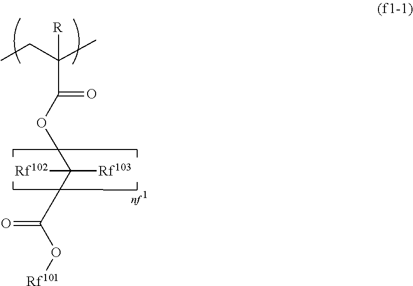

wherein R is the same as R of Formula (a1-1)″, Rf¹⁰² and Rf¹⁰³ each independently represent a hydrogen atom, a halogen atom, a C₁ to C₅ alkyl group, or a C₁ to C₅ halogenated alkyl group, and Rf¹⁰² and Rf¹⁰³ may be the same or different. nf¹ is an integer of 1 to 5, and Rf¹⁰¹ is an organic group including a fluorine atom.

R coupling with a carbon atom at an α position of Formula (fl-1) is the same as the aforementioned R. R is preferably a hydrogen atom or a methyl group.

The halogen atom at each of Rf¹⁰² and Rf¹⁰³ of Formula (fl-1) may be a fluorine atom, a chlorine atom, a bromine atom, an iodine atom, or the like. In particular, the fluorine atom is preferred. Examples of the C₁ to C₅ alkyl group of each of Rf¹⁰² and Rf¹⁰³ may be the same as the examples of the C₁ to C₅ alkyl group of R. The C₁ to C₅ alkyl group is preferably a methyl group or an ethyl group. The C₁ to C₅ halogenated alkyl group of each of Rf¹⁰² and Rf¹⁰³ may be particularly a group formed by substituting a portion or all of hydrogen atoms of C₁ to C₅ alkyl group with a halogen atom.

The halogen atom may be a fluorine atom, a chlorine atom, a bromine atom, an iodine atom, or the like. In particular, the fluorine atom is preferred. Each of Rf¹⁰² and Rf¹⁰³ is preferably a hydrogen atom, a fluorine atom, or a C₁ to C₅ alkyl group. In particular, a hydrogen atom, a fluorine atom, a methyl group, or an ethyl group is preferred.

In Formula (fl-1), nf¹ is an integer of 1 to 5, preferably an integer of 1 to 3, more preferably 1 or 2.

In Formula (fl-1), Rf¹⁰¹ is an organic group including a fluorine atom, preferably a hydrocarbon group including a fluorine atom.

The hydrocarbon group including a fluorine atom may be a straight chain, branched, or cyclic group. The hydrocarbon group has a carbon number of preferably 1 to 20, more preferably 1 to 15, particularly preferably 1 to 10.

In addition, in the hydrocarbon group including a fluorine atom, preferably 25% or more of hydrogen atoms of the hydrocarbon group are fluorinated. More preferably, 50% or more of the hydrogen atoms are fluorinated. Particularly preferably, 60% or more of the hydrogen atoms are fluorinated since, in this case, hydrophobicity of a resist film increases during immersion exposure.

Thereamong, Rf¹⁰¹ is more preferably a C₁ to C₅ fluorinated hydrocarbon group, particularly preferably a trifluoromethyl group, —CH₂—CF₃, —CH₂—CF₂—CF₃, —CH(CF₃)₂, —CH₂—CH₂—CF₃, or —CH₂—CH₂—CF₂—CF₂—CF₂—CF₃.

The mass-average molecular weight (Mw) (calibrated with polystyrene through gel permeation chromatography) of ingredient F is preferably 1000 to 50000, more preferably 5000 to 40000, most preferably 10000 to 30000. When the Mw is equal to or lower than the highest value, ingredient F used as a resist has sufficient solubility in a solvent for a resist. When the Mw is equal to or higher than the lowest value, satisfactory dry etching resistance or satisfactory sectional shape of a resist pattern is exhibited.

The dispersion degree (Mw/Mn) of ingredient F is preferably 1.0 to 5.0, more preferably 1.0 to 3.0, most preferably 1.2 to 2.5.

Ingredient F may be one type or a combination of two or more types.

When the resist composition includes ingredient F, the content of ingredient F is generally 0.5 to 10 parts by mass based on 100 parts by mass of ingredient A.

In the present invention, the resist composition may suitably, additionally include an additive having miscibility, for example, an additional resin for enhancing performance of a resist film, a dissolution inhibitor, a plasticizer, a stabilizer, a coloring agent, a halation inhibitor, a dye, etc., as needed.

A method of forming the resist pattern of the present invention includes a process of forming a resist film on a support using the resist composition of the present invention, a process of exposing the resist film, and a process of developing the resist film after the exposure to form a resist pattern.

The method of forming the resist pattern of the present invention may be carried out according to, for example, the following method.

First, the resist composition of the present invention is coated on a support through spin coating by means of a spinner, etc., and baking (post-apply baking (PAB)) is performed, for example, at 80 to 150° C. for 40 to 120 sec, preferably 60 to 90 sec, such that a desired resist film having a thickness of 5 μm or more is formed.

Next, the resist film is exposed by means of an exposure device such as, for example, a KrF exposure device, an ArF exposure device, an electron beam lithography device, or an EUV exposure device, etc. in a state in which a mask having a predetermined pattern (mask pattern) is interposed, or selectively exposed through writing, etc. such as direct irradiation of electron beams without the mask pattern. Subsequently, baking (post-exposure baking (PEB)) is performed, for example, at 80 to 150° C. for 40 to 120 sec, preferably 60 to 90 sec.

After the exposing and the baking (PEB), the resist film is subjected to development. With regard to the development, an alkali developer is used in an alkali development process, and a developer (organic developer) including an organic solvent is used in a solvent development process.

After the development, rinsing is preferably carried out. With regard to the rinsing, rinsing is carried out using preferably pure water in an alkali development process, and rinsing is carried out using preferably a rinse solution including an organic solvent in a solvent development process.

In the case of the solvent development process, after the development or the rinsing, the developer or the rinse solution attached to the pattern may be removed using a supercritical fluid.

After the development or the rinsing, drying is carried out. In addition, as needed, baking (post-baking) may be carried out after the development. As a result, a resist pattern may be obtained.

In the present invention, the support is not specifically limited and may be an existing publicly known support. For example, the support may be a substrate for electronic components, a substrate having predetermined lines formed thereon, or the like. More particularly, the support may be a silicone wafer, a metal substrate such as copper, chromium, iron, or aluminium, a glass substrate, or the like. A material of the line pattern may be, for example, copper, aluminium, nickel, gold, or the like.

In addition, the support may be prepared by forming an inorganic and/or organic film on the aforementioned substrate. The inorganic film may be an inorganic bottom anti-reflective coating (inorganic BARC) film. The organic film may be an organic bottom anti-reflective coating (organic BARC) film, a lower-layer organic film used in a multi-layer resist, or the like.

A wavelength used in the exposure is not specifically limited and may be applied using radiation sources such as ArF excimer lasers, KrF excimer lasers, F₂ excimer lasers, extreme ultraviolet (EUV) sources, vacuum ultraviolet (VUV) sources, electron beam (EB) sources, X-ray sources, or soft X-ray sources, etc. The resist pattern formation method of the present invention is very useful upon application of KrF excimer laser beams, ArF excimer laser beams, EB,s or EUV rays. In particular, the resist pattern formation method is useful upon application of KrF excimer laser beams.

A method of exposing the resist film may be a general exposure method performed under an atmosphere or in the presence of an inert gas such as a nitrogen gas (dry lithography), or liquid immersion lithography.

Liquid immersion lithography is performed by previously filling a solvent (immersion medium) which has a greater refractive index than air between a resist film and a lens at a lowest part of an exposure device and, in this state, performing exposure (immersion exposure).

The immersion medium is preferably a solvent having a refractive index greater than air and smaller than the resist film. The refractive index of the solvent is not specifically limited so long as it is within this range.

The solvent having a refractive index greater than air and smaller than the resist film may be, for example, water, a fluorine-based inert liquid, a silicone-based solvent, a hydrocarbon-based solvent, or the like.

Specific examples of the fluorine-based inert liquid include a liquid including a fluorine-based compound such as C₃HCl₂F₅, C₄F₉OCH₃, C₄F₉OC₂H₅, or C₅H₃F₇, as a main ingredient, and the like. Preferably, the fluorine-based inert liquid has a boiling point of 70 to 180′C., more preferably 80 to 160′C. When the boiling point of the fluorine-based inert liquid is within this range, the medium used in the immersion may be simply removed after terminating the exposure.

The fluorine-based inert liquid is preferably a perfluoroalkyl compound formed by substituting all hydrogen atoms of an alkyl group with fluorine atoms. The perfluoroalkyl compound may be particularly a perfluoroalkylether compound or a perfluoroalkylamine compound.

Additionally, the perfluoroalkylether compound may particularly be perfluoro(2-butyl-tetrahydrofuran) (boiling point: 102′C), and the perfluoroalkylamine compound may be perfluorotributylamine (boiling point: 174° C.).

As the immersion medium, water is preferred in terms of cost, safety, environmental problems, versatility, etc.

The alkali developer used in the development of the alkali development process may be, for example, an aqueous 0.1 to 10% w/w tetramethylammonium hydroxide (TMAH) solution.

An organic solvent included in the organic developer used in the solvent development process is not specifically limited so long as it may solubilize ingredient A (ingredient A before exposure), and may be suitably selected from publicly known organic solvents. Particularly, the organic solvent may be a polar solvent such as a ketone based solvent, an ester based solvent, an alcohol based solvent, a nitrile based solvent, an amide based solvent, or an ether based solvent, a hydrocarbon based solvent, or the like.

The organic developer may include a publicly known additive, as needed. The additive may be, for example, a surfactant. The surfactant is not specifically limited and may, for example, be an ionic or nonionic fluorine based surfactant and/or an ionic or nonionic silicone based surfactant.

When the surfactant is included, the content of the surfactant is generally 0.001 to 5% by mass, preferably 0.005 to 2% by mass, more preferably 0.01 to 0.5% by mass based on a total mass of the organic developer.

The development may be carried out according to a publicly known development method. For example, the development may be carried out by a method of immersing a support in a developer for a predetermined time (dip method), a method of mounting a developer on a surface of a support using surface tension and maintaining this state for a certain time (paddle method), a method of spraying a developer on a surface of a support (spray method), a method of continuously discharging a developer over a support rotating at a constant rate while scanning a developer discharge nozzle at a constant rate (dynamic dispensing method), or the like.

The rinsing (washing) using a rinse solution may be carried out according to a publicly known rinsing method. The method may be, for example, a method of continuously discharging a rinse solution onto a support rotating at a constant rate (rotation coating method), a method of immersing a support in a rinse solution for a predetermined time (dip method), a method of spraying a rinse solution onto a surface of a support (spray method), or the like.

By using the chemical for photolithography of the present invention and the resist composition including the same, the viscosity of the composition is lowered enough to be used in existing equipment, thus enhancing a liquid transfer property, and at the same time, a desired thick film having a sufficient thickness may be uniformly formed. Particularly, by using the chemical for photolithography of the present invention and the resist composition including the same, a uniformly thick film having a thickness of 5 μm or more, preferably 7 μm or more and 20 μm or less, more preferably 7 μm or more and 15 μm or less may be formed even while lowering the viscosity of the chemical or the resist composition to 130 cP or less.

### Examples

Hereinafter, the present invention will be described in more detail with reference to the following examples. The scope of the present invention is not limited to the following examples and covers modifications of the technical spirit substantially equivalent thereto.

### First Experiment

### Preparation of Chemical for Photolithography

As summarized in Table 1 below, resins and organic solvents were mixed to prepare compositions for photolithography. These compositions were uniformly solubilized and filtered through a membrane filter having a pore diameter of 0.1 μm. As a result, chemicals for photolithography were obtained.

TABLE 1

| | | SOLVENT | | | COMPOSITION | | |
|---|---|---|---|---|---|---|---|
| | | TYPES | SATURATED | | | LIQUID | |
| | | (MASS | VAPOR | | | TRANSFER | CONCENTRATION |
| No. | RESIN | RATIO) | PRESSURE | VISCOSITY | VISCOSITY | PROPERTY | (% BY WEIGHT) |
| 1 (COMPARATIVE | (A-1) | PM | 0.49 | 1.07 | 354 | × | 34.6 |
| EXAMPLE) | | | | | | | |
| 2 (COMPARATIVE | (A-1) | PE | 0.89 | 1.66 | 201 | × | 33.3 |
| EXAMPLE) | | | | | | | |
| 3 (COMPARATIVE | (A-1) | HP | 0.3 | 0.78 | 185 | × | 40.7 |
| EXAMPLE) | | | | | | | |
| 4 (EXAMPLE) | (A-1) | BA | 1.3 | 0.68 | 104 | ⊚ | 34.6 |
| 5 (COMPARATIVE | (A-1) | PE/BA:7/3 | 1.01 | 1.16 | 147 | × | 33.8 |
| EXAMPLE) | | | | | | | |
| 6 (EXAMPLE) | (A-1) | PE/BA:6/4 | 1.05 | 1.05 | 128 | ∘ | 33.7 |
| 7 (EXAMPLE) | (A-1) | PE/BA:5/5 | 1.10 | 0.96 | 122 | ∘ | 34.1 |
| 8 (EXAMPLE) | (A-1) | PE/BA:4/6 | 1.14 | 0.89 | 114 | ⊚ | 34.3 |
| 9 (EXAMPLE) | (A-1) | PE/BA:3/7 | 1.18 | 0.83 | 115 | ⊚ | 34.8 |
| 10 (COMPARATIVE | (A-1) | HP/BA:7/3 | 0.60 | 0.76 | 172 | × | 37.8 |
| EXAMPLE) | | | | | | | |
| 11 (COMPARATIVE | (A-1) | HP/BA:6/4 | 0.70 | 0.75 | 147 | × | 37.1 |
| EXAMPLE) | | | | | | | |
| 12 (COMPARATIVE | (A-1) | HP/BA:5/5 | 0.80 | 0.75 | 140 | Δ | 37.4 |
| EXAMPLE) | | | | | | | |
| 13 (COMPARATIVE | (A-1) | HP/BA:4/6 | 0.90 | 0.74 | 135 | Δ | 36.5 |
| EXAMPLE) | | | | | | | |
| 14 (EXAMPLE) | (A-1) | HP/BA:3/7 | 1.00 | 0.72 | 125 | ∘ | 36.0 |
| 15 (COMPARATIVE | (A-2) | PE | 0.89 | 1.66 | 244 | × | 30.6 |
| EXAMPLE) | | | | | | | |
| 16 (COMPARATIVE | (A-3) | HP | 0.3 | 0.78 | 172 | × | 40.7 |
| EXAMPLE) | | | | | | | |
| 17 (EXAMPLE) | (A-3) | PE/BA:4/6 | 1.14 | 0.89 | 83 | ⊚ | 42.3 |

In the examples and comparative examples, the following resins were used. In the following formula representing the structure of a resin, a number at a lower right of each constituent unit refers to a mole ratio (mol %) of each constituent unit to total constituent units.

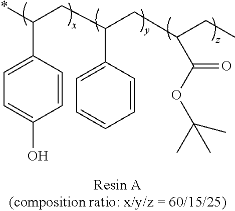

Resin (A-1): Resin A having a mass-average molecular weight of 12000 and a dispersion degree of 1.8
Resin (A-2): Resin A having a mass-average molecular weight of 20000 and a dispersion degree of 1.9
Resin (A-3): Resin A having a mass-average molecular weight of 5000 and a dispersion degree of 1.8

In the examples and the comparative examples, the following solvents were used. Viscosities shown in Table 1 were measured at 1 atm, 20° C. by means of a Cannon Fenske viscometer (viscosity unit: cP). In addition, saturated vapor pressures shown in Table 1 are saturated vapor pressures, as referenced values, at 1 atm, 20° C. (saturated vapor pressure unit: kPa).
PM=PGMEA (propylene glycol monomethyl ether acetate)
PE=PGME (propylene glycol monomethyl ether acetate)
HP=2-heptanone
BA=Butyl acetate

(Evaluation of Liquid Transfer Property)

The viscosity of each of the chemicals for photolithography obtained in the above manner was measured and a liquid transfer property thereof was measured according to the following standard. When the viscosity of the chemical for photolithography is 130 cP or less, a load was not added to pump pressure, thus not affecting production.
When viscosity of composition is 120 cP or less: ⊚
When viscosity of composition is greater than 120 cP and 130 cP or less: ∘
When viscosity of composition is greater than 130 cP and 140 cP or less: Δ
When viscosity of composition is greater than 140 cP: X

(Formation of Thick Film for Lithography)

Each of the chemicals for photolithography of Experiment Nos. 4, 6 to 9, 14 and 17, obtained in the above manner, was coated onto a Si substrate using a spinner at 1200 rpm. The coated chemical was dried, thereby obtaining a film for lithography having a thickness of about 10 μm. Subsequently, the film for lithography was disposed on a hot plate and pre-baked at 120° C. for 60 sec. As a result, all of the chemicals were obtained as films having a satisfactorily uniform surface.

### Second Experiment

### Preparation of Chemical for Photolithography

As summarized in Table 2 below, resins and organic solvents were mixed to prepare compositions for photolithography. These compositions were uniformly solubilized and filtered through a membrane filter having a pore diameter of 0.1 μm. As a result, chemicals for photolithography were obtained.

TABLE 2

| | | SOLVENT | | COMPOSITION | | |
|---|---|---|---|---|---|---|
| | | | | | LIQUID | |
| | | TYPES | | | TRANSFER | CONCENTRATION |
| No. | RESIN | (PM/PE/BA) | VISCOSITY | VISCOSITY | PROPERTY | (% BY WEIGHT) |
| 18 (EXAMPLE) | C | 27.4/44.2/28.4 | 1.004 | 75.38 | ⊚ | 31.84 |
| 19 (EXAMPLE) | C | 25/30/45 | 0.879 | 68.05 | ⊚ | 31.35 |
| 20 (EXAMPLE) | D | 25/30/45 | 0.879 | 70.88 | ⊚ | 30.22 |
| 21 (EXAMPLE) | D | 27.5/44/28.5 | 1.004 | 79.54 | ⊚ | 31.14 |
| 22 (EXAMPLE) | D | 25/45/30 | 1.012 | 78.02 | ⊚ | 31.12 |
| 23 (EXAMPLE) | D | 40/30/30 | 0.945 | 80.66 | ⊚ | 31.40 |
| 24 (EXAMPLE) | D | 35/40/25 | 1.004 | 82.07 | ⊚ | 31.20 |

In Examples 18 to 24, the following resins were used. In the following formula representing the structure of a resin, a number at a lower right of each constituent unit refers to a mole ratio (mol %) of each constituent unit to total constituent units.

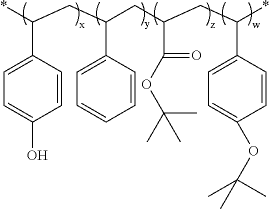

| | x | y | z | w |
|---|---|---|---|---|
| | PHS | St | tBu-Acryl | tbutoxy-St |
| Resin C | 61.5 | 4.5 | 23.5 | 10.5 |
| Resin D | 69.5 | 19.5 | 11 | |

Resin C: a mass-average molecular weight of 10000 and a dispersion degree of 1.4
Resin D: a mass-average molecular weight of 10000 and a dispersion degree of 1.9
PHS = polyhydroxystyrene
St = styrene
tBu-Acryl = tert-butyl acrylate
tbutoxy-St = tert-butoxy styrene

In Examples 18 to 24, the following solvents were used. Viscosities shown in Table 2 were measured at 1 atm, 20° C. by means of a Cannon Fenske viscometer (viscosity unit: cP). In addition, saturated vapor pressures shown in Table 2 are saturated vapor pressures, as referenced values, at 1 atm, 20° C. (saturated vapor pressure unit: kPa).
PM=PGMEA (propylene glycol monomethyl ether acetate)
PE=PGME (propylene glycol monomethyl ether)
BA=Butyl acetate

(Evaluation of Liquid Transfer Property)

The viscosity of each of the chemicals for photolithography obtained in the above manner was measured and a liquid transfer property thereof was measured according to the standard in the First Experiment above. When the viscosity of the chemical for photolithography is 130 cP or less, a load was not added to pump pressure, thus not affecting production.

(Formation of Thick Film for Lithography)

Each of the compositions for photolithography of Experiment Nos. 18 to 24, obtained in the above manner, was coated onto a Si substrate using a spinner at 1200 rpm. The coated composition was dried, thereby obtaining a film for lithography having a thickness of about 10 μm. Subsequently, the film for lithography was disposed on a hot plate and pre-baked at 120° C. for 50 sec. As a result, all of the compositions were obtained as films having a satisfactorily uniform surface.

As described above, by using the chemical for photolithography of the present invention and the resist composition including the same, the viscosity of the composition is lowered enough to be used in existing equipment, thus enhancing a liquid transfer property, and at the same time, a desired film having a sufficient thickness may be uniformly formed. Particularly, by using the chemical for photolithography of the present invention and the resist composition including the same, a uniformly thick film having a thickness of 5 μm or more, preferably 7 μm or more and 20 μm or less, more preferably 7 μm or more and 15 μm or less may be formed even while lowering the viscosities of the chemical and the resist composition to 130 cP or less.

What is claimed is:

1. A chemical for photolithography coated through spin coating, comprising a resin ingredient having a mass-average molecular weight (Mw) of 2000 to 50000 and an organic solvent having a saturated vapor pressure of 1 kPa or more (1 atm, 20° C.) and a viscosity of 1.1 cP (1 atm, 20° C.) or less.

2. The chemical according to claim 1, wherein a thickness of a film coated through the spin coating is 5 μm or more and 20 μm or less.

3. The chemical according to claim 1 or 2, wherein a viscosity of the chemical is 130 cP (1 atm, 20° C.) or less.

4. The chemical according to claim 1 or 2, wherein the organic solvent is selected from the group consisting of an aromatic solvent, halogenated aromatic solvent, ketone-based solvent and ester based solvent.

5. The chemical according to claim 4, wherein the organic solvent is an ester-based solvent.

6. The chemical according to claim 5, wherein the organic solvent is butyl acetate.

7. The chemical according to claim 1 or 2, wherein the resin ingredient is a polyhydroxystyrene resin, and the chemical is exposed to KrF excimer laser beams.

8. A photolithographed film formed to a thickness of 5 μm or more and 20 μm or less by coating the chemical for photolithography according to claim 1 or 2 on a substrate.

9. A resist composition coated through spin coating, comprising:
a resin ingredient having a mass-average molecular weight (Mw) of 2000 to 50000;
an organic solvent having a saturated vapor pressure of 1 kPa or more (1 atm, 20° C.) and a viscosity of 1.1 cP (1 atm, 20° C.) or less; and
an acid generator.

10. The resist composition according to claim 9, wherein a thickness of a film coated through the spin coating is 5 μm or more and 20 μm or less.

11. The resist composition according to claim 9 or 10, wherein a viscosity of the composition is 130 cP (1 atm, 20° C.) or less.

12. The resist composition according to claim 9 or 10, wherein the organic solvent is selected from the group consisting of an aromatic solvent, halogenated aromatic solvent, ketone-based solvent and ester-based solvent.

13. The resist composition according to claim 12, wherein the organic solvent is an ester-based solvent.

14. The resist composition according to claim 13, wherein the organic solvent is butyl acetate.

15. The resist composition according to claim 9 or 10, wherein the resin ingredient is a polyhydroxystyrene resin, and the composition is exposed to KrF excimer laser beams.

16. A resist film formed to a thickness of 5 μm or more and 20 μm or less by coating the resist composition according to claim 9 or 10 on a substrate.
